(19) United States
(12) Patent Application Publication
(10) Pub. No.: US 2022/0206387 A1
(43) Pub. Date: Jun. 30, 2022

(54) PHOTOSENSITIVE COMPOSITION, CURED FILM, COLOR FILTER, LIGHT SHIELDING FILM, OPTICAL ELEMENT, SOLID-STATE IMAGING ELEMENT, INFRARED SENSOR, AND HEADLIGHT UNIT

(71) Applicant: FUJIFILM Corporation, Tokyo (JP)

(72) Inventors: Daisuke HAMADA, Shizuoka (JP); Tatsuo ISHIKAWA, Shizuoka (JP)

(73) Assignee: FUJIFILM Corporation, Tokyo (JP)

(21) Appl. No.: 17/696,880

(22) Filed: Mar. 17, 2022

Related U.S. Application Data
(63) Continuation of application No. PCT/JP2020/032553, filed on Aug. 28, 2020.

(30) Foreign Application Priority Data
Sep. 27, 2019 (JP) 2019-177354

(51) Int. Cl. G03F 7/075; C08K 3/36; C08K 3/22; C08K 3/28; C08K 9/02; G03F 7/00; C08K 7/18; G03F 7/027; G03F 7/028

(52) U.S. Cl. CPC G03F 7/0755; C08K 3/36; C08K 3/22; C08K 3/28; C08K 2003/2227; G03F 7/0007; C08K 7/18; G03F 7/027; G03F 7/028; C08K 9/02

(57) ABSTRACT

A photosensitive composition contains a black pigment, a resin, a polymerizable compound, and a photopolymerization initiator, in which the black pigment includes a coated particle which includes a metal-containing particle consisting of a nitride or oxynitride of one or more metals selected from the group consisting of zirconium, vanadium, and niobium, and a metal oxide coating layer consisting of a metal oxide, with which the metal-containing particle is coated.

### CROSS-REFERENCE TO RELATED APPLICATIONS

This application is a Continuation of PCT International Application No. PCT/JP2020/032553 filed on Aug. 28, 2020, which claims priority under 35 U.S.C § 119(a) to Japanese Patent Application No. 2019-177354 filed on Sep. 27, 2019. Each of the above application(s) is hereby expressly incorporated by reference, in its entirety, into the present application.

### BACKGROUND OF THE INVENTION

### 1. Field of the Invention

The present invention relates to a photosensitive composition, a cured film, a color filter, a light shielding film, an optical element, a solid-state imaging element, an infrared sensor, and a headlight unit.

### 2. Description of the Related Art

A light shielding film called a black matrix is provided in a color filter that is used in a liquid crystal display device for the purpose of, for example, shielding light between colored pixels to enhance contrast.

In addition, currently, a compact and thin imaging unit is mounted on a mobile terminal of electronic apparatus such as a mobile phone and a personal digital assistant (PDA). A light shielding film is provided in a solid-state imaging element such as a charge coupled device (CCD) image sensor and a complementary metal-oxide semiconductor (CMOS) image sensor for the purpose of, for example, preventing the generation of noise and improving image quality.

For example, WO2019/059359A discloses a coloring resin composition containing (A) an alkali-soluble resin, (B) a coloring material, (C) an organic solvent, and (D) a photosensitive agent, which is a black resin composition for a light shielding film, containing at least zirconia compound particles as the (B) coloring material and satisfies predetermined conditions.

### SUMMARY OF THE INVENTION

The inventors of the present invention examined a cured film (a light shielding film) formed from the black resin composition for a light shielding film disclosed in WO2019/059359A, and as a result of the examination, it was found that the optical characteristics of the cured film change in a high-temperature and high-humidity environment, and thus there is room for improvement in the moisture resistance of the cured film.

Accordingly, an object of the present invention is to provide a photosensitive composition with which a cured film having excellent moisture resistance can be formed. In addition, another object of the present invention is to provide a cured film, a color filter, a light shielding film, an optical element, a solid-state imaging element, an infrared sensor, and a headlight unit, in which the photosensitive composition is used.

As a result of carrying out extensive investigations, the inventors of the present invention have found that the above objects can be achieved by the following configuration and have completed the present invention.

[1] A photosensitive composition comprising a black pigment; a resin; a polymerizable compound; and a photopolymerization initiator,

in which the black pigment includes a coated particle, and

the coated particle includes a metal-containing particle consisting of a nitride or oxynitride of one or more metals selected from the group consisting of zirconium, vanadium, and niobium, and a metal oxide coating layer consisting of a metal oxide, with which the metal-containing particle is coated.

[2] The photosensitive composition according to [1], in which the metal oxide includes silica or alumina.

[3] The photosensitive composition according to [1] or [2], in which the metal oxide includes alumina.

[4] The photosensitive composition according to any one of [1] to [3], in which the black pigment is a black pigment different from the coated particle and includes a pigment that is a nitride or oxynitride of one or more metals selected from the group consisting of titanium, zirconium, vanadium, and niobium.

[5] The photosensitive composition according to any one of [1] to [4], in which the photopolymerization initiator includes an oxime compound.

[6] The photosensitive composition according to any one of [1] to [5], in which a content of the black pigment is 40% to 70% by mass with respect to a total solid content of the photosensitive composition.

[7] The photosensitive composition according to any one of [1] to [6], in which the resin includes at least one of a resin that contains a structural unit containing a graft chain and contains an acid group or a resin that contains a radial structure and contains an acid group.

[8] The photosensitive composition according to any one of [1] to [7], in which a content of the metal oxide coating layer is 3% to 7% by mass with respect to a total mass of the coated particle.

[9] The photosensitive composition according to any one of [1] to [8], further comprising water, in which a content of the water is 0.01% to 3.0% by mass with respect to a total mass of the photosensitive composition.

[10] The photosensitive composition according to any one of [1] to [9], further comprising a silica particle.

[11] A cured film that is formed from the photosensitive composition according to any one of [1] to [10].

[12] Alight shielding film that is the cured film according to [11].

[13] A color filter comprising the cured film according to [11].

[14] An optical element comprising the cured film according to [11].

[15] A solid-state imaging element comprising the cured film according to [11].

[16] An infrared sensor comprising the cured film according to [11].

[17] A headlight unit for a vehicle, comprising: a light source; and

a light shielding unit that shields at least a part of light emitted from the light source,

in which the light shielding unit includes the cured film according to [11].

According to the present invention, it is possible to provide a photosensitive composition with which a cured film having excellent moisture resistance can be formed. In addition, the present invention also provides a photosensitive composition, a cured film, a color filter, a light shielding film, an optical element, a solid-state imaging element, an infrared sensor, and a headlight unit, in which the photosensitive composition is used.

### BRIEF DESCRIPTION OF THE DRAWINGS

FIG. 1 is a schematic cross-sectional view illustrating an example of a configuration of a solid-state imaging device.

FIG. 2 is a schematic cross-sectional view illustrating an imaging unit included in the solid-state imaging device illustrated in FIG. 1 in an enlarged manner.

FIG. 3 is a schematic cross-sectional view illustrating an example of a configuration of an infrared sensor.

FIG. 4 is a schematic view illustrating an example of a configuration of a headlight unit.

FIG. 5 is a schematic perspective view illustrating an example of a configuration of a light shielding unit of the headlight unit.

FIG. 6 is a schematic view illustrating an example of a light distribution pattern formed by the light shielding unit of the headlight unit.

FIG. 7 is a schematic view illustrating another example of the light distribution pattern formed by the light shielding unit of the headlight unit.

### DESCRIPTION OF THE PREFERRED EMBODIMENTS

Hereinafter, the present invention will be described in detail.

The description of the following configuration requirements is made based on representative embodiments of the present invention in some cases; however, the present invention is not limited to the embodiments.

It is noted that in the present specification, a numerical value range expressed using “to” means a range including numerical values described before and after “to” as a lower limit value and an upper limit value.

In the present specification, regarding the description of a group (an atomic group), in a case where whether the group is substituted or unsubstituted is not described, the group includes a group which has a substituent as well as a group which does not have a substituent. For example, an “alkyl group” includes not only an alkyl group (an unsubstituted alkyl group) which does not have a substituent but also an alkyl group (a substituted alkyl group) which has a substituent.

In addition, in the present specification, “actinic rays” or “radiation” refers to, for example, far ultraviolet rays, extreme ultraviolet rays (EUV), X-rays, electron beams. In addition, in the present specification, light refers to actinic rays and radiation. In the present specification, unless otherwise specified, “exposure” includes not only exposure with far ultraviolet rays, X-rays, EUV light, or the like, but also drawing by particle beams such as electron beams and ion beams.

In the present specification, “(meth)acrylate” represents acrylate and methacrylate. In the present specification, “(meth)acryl” represents acryl and methacryl. In the present specification, “(meth)acryloyl” represents acryloyl and methacryloyl. In the present specification, “(meth)acrylamide” represents acrylamide and methacrylamide. In the present specification, a “monomeric substance” and a “monomer” have the same definition.

In the present specification, “ppm” means “parts per million (10⁻⁶)”, “ppb” means “parts per billion (10⁻⁹)”, and “ppt” means “parts per trillion (10⁻¹²)”.

In addition, in the present specification, a weight-average molecular weight (Mw) is a value in terms of polystyrene, which is measured by gel permeation chromatography (GPC).

In the present specification, the GPC method is based on a method in which HLC-8020 GPC (manufactured by TOSOH CORPORATION) is used, TSKgel SuperHZM-H, TSKgel SuperHZ4000, and TSKgel SuperHZ2000 (manufactured by TOSOH CORPORATION, 4.6 mm ID×15 cm) are used as columns, and tetrahydrofuran (THF) is used as an eluent.

A bonding direction of a divalent group (for example, —COO—) described in the present specification is not limited, unless otherwise specified. For example, in a case where Y is —COO— in a compound represented by the general formula of “X—Y—Z”, the compound may be “X—O—CO—Z” or “X—CO—O—Z”.

[Photosensitive Composition (Composition)]

The photosensitive composition according to the embodiment of the present invention (hereinafter, also simply referred to as the “composition”) is a photosensitive composition containing a black pigment, a resin, a polymerizable compound, and a photopolymerization initiator,

in which the black pigment includes a coated particle, and

the coated particle includes a metal-containing particle consisting of a nitride or oxynitride of one or more metals selected from the group consisting of zirconium, vanadium, and niobium, and a metal oxide coating layer consisting of a metal oxide, with which the metal-containing particle is coated.

The mechanism by which the objects of the present invention are achieved with the composition having the constitution described above is not necessarily clear; however, the inventors of the present invention conceives as follows. That is, since the coated particle has a configuration in which the metal-containing particle is coated with the metal oxide coating layer, the stability against moisture is good, and thus it is conceived that the use of such a coated particle also improves the moisture resistance of the cured film formed from the composition.

In addition, the composition according to the embodiment of the present invention has good dispersibility and patterning properties. Further, the light shielding film (the cured film) formed from the composition according to the embodiment of the present invention has good light shielding properties against visible light and infrared light, and also has good alignment mark visibility.

Hereinafter, it is also referred to as that the effects of the present invention are excellent in a case where any one of the following properties is excellent; the moisture resistance, the light shielding properties against visible light, the light shielding properties against infrared rays, the alignment mark visibility of the cured film formed from the composition, and the dispersibility and the patterning properties of the composition.

Hereinafter, components contained in the composition according to the embodiment of the present invention will be described.

[Black Pigment]

The composition according to the embodiment of the present invention contains a black pigment.

In the present specification, the black pigment refers to a pigment which has absorption over the entire wavelength range of 400 to 700 nm.

It is noted that a plurality of pigments, each of which cannot be used as a black pigment, are combined and adjusted to be black as a whole and may be used as a black pigment.

For example, a plurality of pigments, each of which has a color other than the black color, are combined and may be used as a black pigment.

More specifically, for example, a black pigment, which conforms to an evaluation standard Z described below, is preferable.

First, a composition, which contains a pigment, a transparent resin matrix (acrylic resin or the like), and a solvent, and in which the content of the pigment with respect to the total solid content is 60% by mass, is prepared. A coating film is formed by applying the obtained composition onto a glass substrate so that the film thickness of the coating film after drying is 1 μm. The light shielding properties of the coating film after drying are evaluated using a spectrophotometer (UV-3600 manufactured by Shimadzu Corporation, or the like). In a case where the maximum value of the light transmittance of the coating film after drying is less than 10% at wavelengths of 400 to 700 nm, the pigment can be determined to be a black pigment conforming to the evaluation standard Z.

In a case where the black pigment contains a plurality of kinds of pigments, it is preferable that each of the contained pigments conforms to the evaluation standard Z.

The content of the black pigment is preferably 20% to 90% by mass, more preferably 40% to 70% by mass, and still more preferably more than 40% and less than 70% by mass, with respect to the total solid content of the composition, from the viewpoint that the effects of the present invention are more excellent.

In a case where two or more kinds of black pigments are used, the total content thereof is preferably within the above range.

It is noted that the “light shielding” using a cured film formed from the composition according to the embodiment of the present invention as the light shielding film is a concept that also includes light attenuation in which light passes through the cured film (the light shielding film) while being attenuated. In a case where the cured film (the light shielding film) is used as a light attenuating film having such a function, it is also preferable that the content of the black pigment in the composition is less than the above suitable range.

<Coated Particle>

The black pigment contains at least a coated particle.

The coated particle is a particle including a metal-containing particle and a metal oxide coating layer with which the metal-containing particle is coated.

The content of the coated particle is preferably 5% to 100% by mass and more preferably 50% to 90% by mass with respect to the total mass of the black pigment.

The content of the coated particle is preferably 5% to 90% by mass, and more preferably 25% to 55% by mass with respect to the total solid content of the composition.

(Metal-Containing Particle)

The coated particle includes a metal-containing particle.

The metal-containing particle consists of a nitride or oxynitride of one or more metals selected from the group consisting of zirconium, vanadium, and niobium.

Among them, the metal-containing particle more preferably consists of a nitride or oxynitride of zirconium.

In addition, the metal-containing particle may contain both the nitride and the oxynitride.

The average primary particle diameter of the metal-containing particles is preferably 0.5 to 400 nm, more preferably 5 to 170 nm, and still more preferably 10 to 100 nm, from the viewpoint that a balance between the improvement in each characteristic of the cured film and the handleability is more excellent.

The average primary particle diameter of the metal-containing particles is the average primary particle diameter calculated from the specific surface area that is obtained based on the BET method.

The description that the metal-containing particle consists of a nitride or oxynitride of one or more metals selected from the group consisting of zirconium, vanadium, and niobium means that the metal-containing particle substantially consists of only a material (hereinafter, also referred to as a “specific material”) selected from the group consisting of the nitride and the oxynitride.

The description that the metal-containing particle substantially consists of only the specific material means, for example, that the content of the specific material in the metal-containing particle is 90% to 100% by mass (preferably 95% to 100% by mass and more preferably 99% to 100% by mass) with respect to the mass of the metal-containing particle.

(Metal Oxide Coating Layer)

The coated particle includes a metal oxide coating layer consisting of a metal oxide.

The metal oxide coating layer is a layer with which the above-described metal-containing particle is coated.

The coating with the metal oxide coating layer may be the coating of the entire surface of the metal-containing particle or may be the coating of a part of the surface. That is, in a case where the metal oxide coating layer is disposed on at least a part of the surface of the metal-containing particle, a part of the metal-containing particle may be exposed on the surface.

The metal oxide coating layer may be disposed (used for coating) directly on the metal-containing particle or may be disposed (used for coating) on the metal-containing particle through another layer.

The presence or absence of coating can be determined using, for example, a field emission scanning transmission electron microscope with an energy dispersive X-ray spectrometer (FE-STEM/EDS).

The coating amount can be determined using electron spectroscopy for chemical analysis (ESCA).

The metal in the metal oxide that constitutes the metal oxide coating layer is not limited, it and may be a typical element metal or a transition metal. In addition, the metal may be a semimetal such as silicon.

Examples of the metal include aluminum (Al), silicon (Si), zinc (Zn), germanium (Ge), hafnium (Hf), gallium (Ga), molybdenum (Mo), titanium (Ti), zirconium (Zr), vanadium (V), tantalum (Ta), niobium (Nb), cobalt (Co), chromium (Cr), copper (Cu), manganese (Mn), ruthenium (Ru), iron (Fe), nickel (Ni), tin (Sn), and silver (Ag).

Among them, the metal is preferably Al or Si and more preferably Al.

The metal oxide may be an oxide of a single metal (for example, the above-described metal) or may be a complex oxide of a plurality of metals.

Examples of the metal oxide include alumina (Al₂O₃), silica (SiO₂), ZnO, GeO₂, TiO₂, ZrO₂, HfO₂, Sn₂O₃, Mn₂O₃, Ga₂O₃, Mo₂O₃, Ta₂O₅, V₂O₅, and Nb₂O₅.

Among them, the metal oxide preferably includes alumina or silica and more preferably includes alumina.

One kind of the metal oxide may be used alone or, two or more kinds thereof may be used. However, in a case where two or more metal oxides are used, the content of the metal oxide having the highest content is preferably 50% by mass or more and more preferably 80% by mass or more with respect to the total mass of the two or more metal oxides. The upper limit thereof is less than 100% by mass.

The description that the metal oxide coating layer consists of a metal oxide is intended to mean that the metal oxide coating layer substantially consists of only a metal oxide.

The description that the metal oxide coating layer substantially consists of only a metal oxide means, for example, that the content of the metal oxide (preferably, one or both of alumina and silica and more preferably alumina) in the metal oxide coating layer is 90% to 100% by mass (preferably 95% to 100% by mass and more preferably 99% to 100% by mass) with respect to the total mass of the metal oxide coating layer.

In addition, the content of the metal oxide coating layer is preferably 0.1% to 15% by mass, more preferably 1% to 10% by mass, and still more preferably 3% to 7% by mass, with respect to the total mass of the coated particle.

The content of the metal oxide coating layer can be determined by ESCA.

The production method for the coated particle is not particularly limited, and examples thereof include a method in which, in the production method for a black titanium oxynitride powder that is a powder base of black titanium oxynitride coated with a silica film described in paragraphs 0018, 0019, and 0025 of JP2015-117302A or the like, the powder base of black titanium oxynitride is replaced with the above-described metal-containing particle.

Other examples of the production method for the coated particle include a method in which, in the inorganic treatment step in the surface treatment of titanium dioxide described in paragraph 0059 and the like of JP2017-014522A, a step in which the titanium dioxide is replaced with the above-described metal-containing particle is carried out.

Further, other examples of the production method for the coated particle include a method in which, in JP1996-059240A (JP-H08-059240A) (JP3314542B), a gas barrier thin film is formed on the surface of the above-described metal-containing particle instead of the particles of lower titanium oxide.

<Another Black Pigment>

The composition may contain, as the black pigment, a black pigment different from the above-described coated particle (hereinafter, also simply referred to as “another black pigment”).

The content of the other black pigment is preferably 0% to 95% by mass and more preferably 10% to 50% by mass with respect to the total mass of the black pigment.

The content of the coated particle is preferably 2% to 60% by mass, and more preferably 5% to 35% by mass with respect to the total solid content of the composition.

The other black pigment may be any black pigment other than the coated particle and may be an inorganic pigment or an organic pigment.

The other black pigment is preferably a pigment which singly develops a black color, and more preferably a pigment which singly develops a black color and absorbs infrared rays.

Here, the other black pigment which absorbs infrared rays has absorption, for example, in a wavelength range of an infrared range (preferably, wavelengths of 650 to 1,300 nm). The other black pigment having a maximal absorption wavelength in a wavelength range of wavelengths of 675 to 900 nm is also preferable.

The average primary particle diameter of the other black pigment is not particularly limited; however, it is preferably 5 to 100 nm, more preferably 5 to 50 nm, and still more preferably 5 to 30 nm, from the viewpoint that a balance between handleability and the temporal stability (the other black pigment is not sedimented) of the composition is more excellent.

The average primary particle diameter of the other black pigment is measured by the following method. The average primary particle diameter can be measured using a transmission electron microscope (TEM). As the transmission electron microscope, it is possible to use, for example, a transmission microscope HT7700 manufactured by Hitachi High-Tech Corporation.

A maximum length (Dmax: a maximum length between two points on a contour of the particle image) and a length vertical to the maximum length (DV-max: in a case where an image is sandwiched between two straight lines parallel to the maximum length, the shortest length that vertically connects the two straight lines) of a particle image obtained using the transmission electron microscope are measured, and a geometric mean value thereof (Dmax×DV-max)^{1/2} shall be taken as the primary particle diameter. Primary particle diameters of 100 particles are measured by this method, and an arithmetic average value thereof shall be taken as the average primary particle diameter of the particles.

(Inorganic Pigment)

The inorganic pigment is not particularly limited, for example, as long as the inorganic pigment has light shielding properties and is a particle containing an inorganic compound, and a known inorganic pigment can be used.

The inorganic pigment is preferably a particle (a metal particle) which contains a metallic element of Group 4 such as titanium (Ti) and zirconium (Zr), a metallic element of Group 5 such as vanadium (V) and niobium (Nb), or one or more metallic elements selected from the group consisting of cobalt (Co), chromium (Cr), copper (Cu), manganese (Mn), ruthenium (Ru), iron (Fe), nickel (Ni), tin (Sn), and silver (Ag), and more preferably particles (metal particles) containing titanium and/or zirconium.

In addition, the inorganic pigment is preferably a metal oxide, a metal nitride, or a metal oxynitride, which contains the above-described metallic element.

As the metal oxide, the metal nitride, and the metal oxynitride, for example, a particle in which other atoms are further mixed may be used. For example, a metal nitride-containing particle, which further contains an atom (preferably, an oxygen atom and/or a sulfur atom) selected from elements of Groups 13 to 17 of the periodic table, can be used.

The production method for the metal nitride, the metal oxide, or the metal oxynitride is not particularly limited as long as the other black pigment having desired physical properties can be obtained, and a known production method such as a gas-phase reaction method can be used. Examples of the gas-phase reaction method include an electric furnace method and a thermal plasma method; however, a thermal plasma method is preferable from the viewpoint that few impurities are mixed in, the average primary particle diameter is likely to be uniform, and productivity is high.

The metal nitride, the metal oxide, or the metal oxynitride may be subjected to a surface modification treatment. For example, the surface modification treatment can be carried out with a surface-treating agent having both a silicone group and an alkyl group. Examples of such an inorganic particle include “KTP-09” series (manufactured by Shin-Etsu Chemical Co., Ltd.).

The other black pigment is preferably a nitride or oxynitride of one or more metals selected from the group consisting of titanium, zirconium, vanadium, and niobium, and more preferably a nitride or oxynitride of one or more metals selected from the group consisting of titanium, zirconium, and vanadium. These black pigments may contain both the above-described nitride and the above-described oxynitride.

Titanium-based black pigment such as titanium oxynitride is also referred to as titanium black. The surface of the titanium black can be modified as necessary, for example, for the purpose of improving dispersibility or suppressing aggregating properties. The titanium black can be coated with silicon oxide, titanium oxide, germanium oxide, aluminum oxide, magnesium oxide, or zirconium oxide, and can also be treated with a water-repellent substance such as the substance described in JP2007-302836A.

Examples of the production method for the titanium black include a method (JP1974-5432A (JP-S49-5432A)) for heating and reducing a mixture of titanium dioxide and titanium metal in a reduction atmosphere, a method (JP1982-205322A (JP-S57-205322A)) for reducing ultrafine titanium dioxide obtained by hydrolyzing titanium tetrachloride at a high temperature in a reduction atmosphere containing hydrogen, a method (JP1985-65069A (JP-S60-65069A) and JP1986-201610A (JP-S61-201610A)) for reducing titanium dioxide or titanium hydroxide at a high temperature in the presence of ammonia, and a method (JP1986-201610A (JP-S61-201610A)) for attaching a vanadium compound to titanium dioxide or titanium hydroxide, and reducing the resultant at a high temperature in the presence of ammonia, but the production method is not limited to these examples.

The average primary particle diameter of the titanium black is not particularly limited; however, it is preferably 10 to 45 nm and more preferably 12 to 20 nm. The specific surface area of the titanium black is not particularly limited; however, the value measured by the Brunauer-Emmett-Teller (BET) method is preferably 5 to 150 m²/g and more preferably 20 to 100 m²/g so that the water repellency after the surface treatment with a water repelling agent has a predetermined performance.

Examples of the commercially available product of the titanium black include TITANIUM BLACK 10S, 125, 13R, 13M, 13M-C, 13R, 13R-N, and 13M-T (product names, manufactured by Mitsubishi Materials Corporation), Tilack D (product name, manufactured by AKO KASEI CO., LTD.), and MT-150A (product name, manufactured by TAYCA CORPORATION).

It is also preferable that the composition contains titanium black in a form of a substance to be dispersed, which contains the titanium black and the Si atom. In this form, the titanium black is contained as a substance to be dispersed in the composition. The content ratio (Si/Ti) of the Si atom to the Ti atom in the substance to be dispersed is preferably 0.05 to 0.5 and more preferably 0.07 to 0.4, in terms of mass. Here, the substance to be dispersed includes both titanium black which is in a state of primary particles and titanium black which is in a state of an aggregate (secondary particles).

In addition, in a case where the Si/Ti of the substance to be dispersed is too small, residues are likely to remain in a removal part in a case where a coating film using the substance to be dispersed is patterned by optical lithography or the like, and in a case where the Si/Ti of the substance to be dispersed is too large, a light shielding ability tends to be decreased.

In order to change the Si/Ti of the substance to be dispersed (for example, in order to change to be 0.05 or more), the following means can be used. First, a dispersion is obtained by dispersing titanium oxide and silica particles using a disperser, this mixture is subjected to a reduction treatment at a high temperature (for example, 850° C. to 1,000° C.), and thus a substance to be dispersed, which has titanium black particles as a main component and contains Si and Ti, can be obtained. The titanium black having the adjusted Si/Ti can be produced, for example, by the method described in paragraphs 0005 and 0016 to 0021 of JP2008-266045A.

It is noted the content ratio (Si/Ti) of the Si atom to the Ti atom in the substance to be dispersed can be measured, for example, using the method (2-1) or the method (2-3) described in paragraphs 0054 to 0056 of WO2011/049090A.

In the substance to be dispersed, which contains the titanium black and the Si atom, the above-described titanium black can be used as titanium black. In addition, in this substance to be dispersed, for the purpose of adjusting dispersibility, colorability, or the like, one black pigment, which consists of a complex oxide of a plurality of metals selected from Cu, Fe, Mn, V, Ni, and the like, cobalt oxide, iron oxide, carbon black, aniline black, and the like, or a combination of two or more of the other black pigments may be used as a substance to be dispersed in combination with the titanium black. In this case, it is preferable that a substance to be dispersed consisting of titanium black accounts for 50% by mass or more of the total substance to be dispersed.

Examples of the inorganic pigment also include carbon black.

Examples of the carbon black include furnace black, channel black, thermal black, acetylene black, and lamp black.

As the carbon black, for example, carbon black manufactured by a known method such as an oil furnace method may be used, or a commercially available product may be used. Specific examples of the commercially available product of the carbon black include an organic pigment such as C. I. Pigment Black 1 and an inorganic pigment such as C. I. Pigment Black 7.

The carbon black is preferably carbon black subjected to a surface treatment. The surface treatment can reform the particle surface state of the carbon black and improve the dispersion stability in the composition. Examples of the surface treatment include a coating treatment with a resin, a surface treatment for introducing an acidic group, and a surface treatment with a silane coupling agent.

The carbon black is preferably carbon black subjected to a coating treatment with a resin. The light shielding properties and the insulating properties of the cured film can be improved by coating the particle surface of carbon black with an insulating resin. In addition, the reliability or the like of the image display device can be improved by reducing the leakage current or the like. As a result, the above-described carbon black is suitable for a case where a cured film is used in use applications which require insulating properties.

Examples of the coating resin include an epoxy resin, polyamide, polyamide imide, a novolak resin, a phenol resin, a urea resin, a melamine resin, polyurethane, a diallyl phthalate resin, an alkylbenzene resin, polystyrene, polycarbonate, polybutylene terephthalate, and a modified polyphenylene oxide.

From the viewpoint that the light shielding properties and the insulating properties of the cured film are more excellent, the content of the coating resin is preferably 0.1% to 40% by mass and more preferably 0.5% to 30% by mass with respect to the total of the carbon black and the coating resin.

(Organic Pigment)

The organic pigment is not particularly limited, for example, as long as the organic pigment has light shielding properties and is a particle containing an organic compound, and a known organic pigment can be used.

In the present invention, examples of the organic pigment include a bisbenzofuranone compound, an azomethine compound, a perylene compound, and an azo-based compound, and a bisbenzofuranone compound or a perylene compound is preferable.

Examples of the bisbenzofuranone compound include the compounds described in JP2010-534726A, JP2012-515233A, and JP2012-515234A. As the bisbenzofuranone compound, “Irgaphor Black” (product name) series such as Irgaphor Black S 0100 CF manufactured by BASF SE can be used.

Examples of the perylene compound include the compounds described in JP1987-1753A (JP-S62-1753A) and JP1988-26784B (JP-S63-26784B). The perylene compound is available as C. I. Pigment Black 21, 30, 31, 32, 33, and 34.

[Another Coloring Material]

The composition may contain another coloring material that is a coloring material other than the black pigment.

<Black Dye>

The composition may include, for example, a black dye.

As the black dye, it is possible to use, for example, a dye which singly develops a black color, and it is possible to use, for example, a pyrazole azo compound, a pyrromethene compound, an anilino azo compound, a triphenylmethane compound, an anthraquinone compound, a benzylidene compound, an oxonol compound, a pyrazolotriazole azo compound, a pyridone azo compound, a cyanine compound, a phenothiazine compound, or a pyrrolopyrazole azomethine compound.

In addition, regarding the black dye, reference can be made to, for example, the compounds described in JP1989-90403A (JP-S64-90403A), JP1989-91102A (JP-S64-91102A), JP1989-94301A (JP-H01-94301A), JP1994-11614A (JP-H06-11614A), JP2592207B, U.S. Pat. Nos. 4,808,501A, 5,667,920A, 505,950A, JP1993-333207A (JP-H05-333207A), JP1994-35183A (JP-H06-35183A), JP1994-51115A (JP-H06-51115A), JP1994-194828A (JP-H06-194828A), and the like, the contents of which are incorporated into the present specification.

Examples of these black dyes include dyes specified by Color Index (C. I.) of SOLVENT BLACK 27 to 47, and a dye specified by C. I. of SOLVENT BLACK 27, 29, or 34 is preferable.

In addition, examples of commercially available products of these black dyes include dyes such as SPILON Black MH and Black BH (all manufactured by Hodogaya Chemical Co., Ltd.), VALIFAST Black 3804, 3810, 3820, and 3830 (all manufactured by Orient Chemical Industries Co., Ltd.), Savinyl Black RLSN (all manufactured by Clariant), and KAYASET Black K-R and K-BL (all manufactured by Nippon Kayaku Co., Ltd.). In addition, a polymerizable dye having polymerizability in a molecule may be used, and examples of the commercially available product thereof include RDW series manufactured by FUJIFILM Wako Pure Chemical Corporation.

In addition, a dye multimer may be used as the black dye. Examples of the dye multimer include the compounds described in JP2011-213925A and JP2013-041097A.

Furthermore, as described above, a combination of a plurality of dyes, each of which has a color other than the black color, may be used as the black dye. As such a coloring dye, for example, the dye described in paragraphs 0027 to 0200 of JP2014-42375A can also be used in addition to a dye (chromatic dye) having a chromatic color such as red (R), green (G), and blue (B).

<Coloring Agent>

The composition according to the embodiment of the present invention may contain a coloring agent having a color other than the black color. The light shielding characteristics of the cured film (the light shielding film) can be adjusted by using both a black coloring material (including the above-described black pigment) having a black color and one or more kinds of coloring agents. In addition, for example, in a case where the cured film is used as a light attenuating film, each of wavelengths of light containing a wide wavelength component is likely to be uniformly attenuated.

Examples of the coloring agent include a pigment and a dye other than the black coloring material.

A chromatic colorant or a white colorant may be contained as the coloring agent. Examples of the chromatic colorant include a red coloring agent, a green coloring agent, a blue coloring agent, a yellow coloring agent, a purple coloring agent, and an orange coloring agent. The chromatic colorant or the white colorant may be a pigment or a dye. The pigment and the dye may be used in combination. In addition, the pigment may be any one of an inorganic pigment or an organic pigment. In addition, as the pigment, a material in which a part of an inorganic pigment or an organic-inorganic pigment is replaced with an organic chromophore can also be used. The color tone design can be facilitated by replacing the inorganic pigment or the organic-inorganic pigment with the organic chromophore.

In a case where the composition contains the coloring agent, the total content of the black coloring material and the coloring agent is preferably 10% to 90% by mass more preferably 30% to 70% by mass, and still more preferably 40% to 60% by mass with respect to the total mass of the solid contents in the composition.

It is noted that in a case where a cured film formed from the composition according to the embodiment of the present invention is used as the light attenuating film, it is also preferable that the total content of the black coloring material and the coloring agent is less than the above suitable range.

In addition, the mass ratio of the content of the coloring agent to the content of the black coloring material (the content of the coloring agent/the content of the black coloring material) is preferably 0.1 to 9.0.

<Infrared Absorbing Agent>

The composition may further contain an infrared absorbing agent.

The infrared absorbing agent refers to a compound having absorption in a wavelength range of an infrared range (preferably, wavelengths of 650 to 1,300 nm). The infrared absorbing agent is preferably a compound having a maximal absorption wavelength in a wavelength range of wavelengths of 675 to 900 nm.

Examples of the coloring agent having such spectral characteristics include a pyrrolo pyrrole compound, a copper compound, a cyanine compound, a phthalocyanine compound, an iminium compound, a thiol complex-based compound, a transition metal oxide-based compound, a squarylium compound, a naphthalocyanine compound, a quaterrylene compound, a dithiol metal complex-based compound, and a croconium compound.

As the phthalocyanine compound, the naphthalocyanine compound, the iminium compound, the cyanine compound, the squarylium compound, and the croconium compound, the compounds disclosed in paragraphs 0010 to 0081 of JP2010-111750A may be used, the content of which is incorporated into the present specification. Regarding the cyanine compound, reference can be made to, for example, “Functional Dyes, written by Makoto OKAWARA, Masaru MATSUOKA, Teijiro KITAO, and Tsuneaki HIRASHIMA, Kodansha Scientific Ltd.”, the content of which is incorporated into the present specification.

As the coloring agent having the spectral characteristics, the compound disclosed in paragraphs 0004 to 0016 of JP1995-164729A (JP-H07-164729A) and/or the compound disclosed in paragraphs 0027 to 0062 of JP2002-146254A, and the near-infrared absorption particles which are disclosed in paragraphs 0034 to 0067 of JP2011-164583A, consist of crystallites of an oxide containing Cu and/or P, and have a number-average aggregated particle diameter of 5 to 200 nm can also be used.

The compound having a maximal absorption wavelength in a wavelength range of wavelengths of 675 to 900 nm is preferably at least one selected from the group consisting of a cyanine compound, a pyrrolo pyrrole compound, a squarylium compound, a phthalocyanine compound, and a naphthalocyanine compound.

In addition, the infrared absorbing agent is preferably a compound which is dissolved in an amount of 1% by mass or more in water at 25° C., and more preferably a compound which is dissolved in an amount of 10% by mass or more in water at 25° C. In a case where such a compound is used, solvent resistance is improved.

Regarding the pyrrolo pyrrole compound, reference can be made to paragraphs 0049 to 0062 of JP2010-222557A, the content of which is incorporated into the present specification. Regarding the cyanine compound and the squarylium compound, reference can be made to paragraphs 0022 to 0063 of WO2014/088063A, paragraphs 0053 to 0118 of WO2014/030628A, paragraphs 0028 to 0074 of JP2014-59550A, paragraphs 0013 to 0091 of WO2012/169447A, paragraphs 0019 to 0033 of JP2015-176046A, paragraphs 0053 to 0099 of JP2014-63144A, paragraphs 0085 to 0150 of JP2014-52431A, paragraphs 0076 to 0124 of JP2014-44301A, paragraphs 0045 to 0078 of JP2012-8532A, paragraphs 0027 to 0067 of JP2015-172102A, paragraphs 0029 to 0067 of JP2015-172004A, paragraphs 0029 to 0085 of JP2015-40895A, paragraphs 0022 to 0036 of JP2014-126642A, paragraphs 0011 to 0017 of JP2014-148567A, paragraphs 0010 to 0025 of JP2015-157893A, paragraphs 0013 to 0026 of JP2014-095007A, paragraphs 0013 to 0047 of JP2014-80487A, paragraphs 0007 to 0028 of JP2013-227403A, and the like, the contents of which are incorporated into the present specification.

[Resin]

The composition according to the embodiment of the present invention contains a resin.

The molecular weight of the resin is preferably more than 3,000. It is noted that in a case where the molecular weight of the resin is polydisperse, the weight-average molecular weight thereof is preferably more than 3,000. The resin is preferably dissolved in the composition.

The resin preferably includes a resin (an acid group-containing resin) containing an acid group (for example, a carboxyl group, a sulfo group, a monosulfate ester group, —OPO(OH)₂, a monophosphate ester group, a borate group, and/or a phenolic hydroxyl group).

For example, a part or all of the dispersing agent (the dispersing agent will be described later) that can be contained as a resin in the composition may be an acid group-containing resin, or a part or all of the alkali-soluble resin (the alkali-soluble resin will be described later) that can be contained as a resin in the composition may be an acid group-containing resin.

The content of the resin in the composition is preferably 3% to 60% by mass, more preferably 7% to 40% by mass, and still more preferably 10% to 35% by mass, with respect to the total solid content of the composition.

The content of the acid group-containing resin is preferably 10% to 100% by mass, more preferably 60% to 100% by mass, and still more preferably 80% to 100% by mass, with respect to the total mass of the resin.

In a case where two or more resins are used in combination, the total content thereof is preferably within the above range.

In addition, the resin preferably includes, as will be described later, a resin (preferably, an acid group-containing resin containing a structural unit containing a graft chain) which contains a structural unit containing a graft chain and/or a resin (preferably, an acid group-containing resin containing a radial structure) which contains a radial structure.

<Dispersing Agent>

The composition preferably contains a dispersing agent. It is noted that in the present specification, the dispersing agent refers to a polymer compound (a resin) different from the alkali-soluble resin which will be described later.

The dispersing agent preferably contains an acid group (for example, a carboxyl group, a sulfo group, a monosulfate ester group, —OPO(OH)₂, a monophosphate ester group, a borate group, and/or a phenolic hydroxyl group).

The content of the dispersing agent in the composition is not particularly limited; however, it is preferably 3% to 60% by mass, more preferably 7% to 40% by mass, and still more preferably 13% to 20% by mass, with respect to the total solid content of the composition.

The dispersing agent may be used alone, or two or more kinds thereof may be used in combination. In a case where two or more kinds of dispersing agents are used in combination, the total content thereof is preferably within the above range.

In addition, in the composition, the mass ratio of the content of the dispersing agent (preferably, a graft type polymer compound and/or a radial polymer compound, described later) to the content of the black pigment (the content of the dispersing agent/the content of the black pigment) is preferably 0.05 to 1.00, more preferably 0.05 to 0.65, and still more preferably 0.15 to 0.35.

Examples of the dispersing agent include polyamidoamine and a salt thereof, a polycarboxylic acid and a salt thereof, a high-molecular-weight unsaturated acid ester, a modified polyurethane, a modified polyester, a modified poly(meth)acrylate, a (meth)acrylic copolymer, a naphthalenesulfonic acid-formalin condensate, a polyoxyethylene alkyl phosphoric acid ester, a polyoxyethylene alkylamine, and a pigment derivative.

Dispersing agents can be further classified, based on their structures, into a linear polymer compound, a terminal modification type polymer compound, a graft type polymer compound, a block type polymer compound, and a radial polymer compound.

The dispersing agent adsorbs onto the surface of substances to be dispersed, such as the black pigment and the other pigments (hereinafter, the black pigment and the other pigments are also described collectively and simply as the “pigment”) that is used in combination as desired, and acts to prevent the reaggregation of the substances to be dispersed. For this reason, a terminal modification type polymer compound, a graft type (polymer chain-containing) polymer compound, a block type polymer compound, or a radial polymer compound, which contains a moiety anchored to the pigment surface, is preferable.

The graft type polymer compound corresponds to a resin containing a structural unit containing a graft chain, and the radial polymer compound corresponds to a resin containing a radial structure.

Further, it is also preferable that this dispersing agent is a dispersing agent further containing an acid group (an acid group-containing resin).

That is, for example, it is also preferable that the resin contains a structural unit containing a graft chain and contains a dispersing agent (a resin) containing an acid group, and it is also preferable that the resin contains an acid group and contains a dispersing agent (a resin) containing a radial structure and containing an acid group.

The dispersing agent may contain a curable group.

Examples of the curable group include, which are not limited thereto, an ethylenic unsaturated group (for example, a (meth)acryloyl group, a vinyl group, a styryl group, and the like), and a cyclic ether group (for example, an epoxy group, an oxetanyl group, and the like).

Among them, from the viewpoint that polymerization can be controlled by a radical reaction, the curable group is preferably an ethylenic unsaturated group and more preferably a (meth)acryloyl group.

The dispersing agent containing a curable group preferably has at least one selected from the group consisting of a polyester structure and a polyether structure. In this case, the polyester structure and/or the polyether structure may be contained in the main chain, and as will be described later, in a case where the dispersing agent contains a structural unit containing a graft chain, the graft chain may have a polyester structure and/or a polyether structure.

The resin is more preferably a resin in which the polymer chain contains a polyester structure.

The dispersing agent is preferably a dispersing agent (a graft type polymer compound) containing a structural unit containing a graft chain. It is noted that in the present specification, the “structural unit” is synonymous with the “repeating unit”.

Such a dispersing agent (a graft type polymer compound) containing a structural unit containing a graft chain has a compatibility with a solvent due to the graft chain, and thus it is excellent in the dispersibility of the pigment or the like and the dispersion stability (the temporal stability) after the lapse of time. In addition, due to the presence of the graft chain, the dispersing agent containing the structural unit containing a graft chain has compatibility with a polymerizable compound or another resin which can be used in combination. As a result, residues are less likely to be generated in the alkali development.

In a case where the graft chain is prolonged, a steric repulsion effect is enhanced, and thus the dispersibility of the pigment or the like is improved. On the other hand, in a case where the graft chain is too long, adsorptive power to the pigment or the like is reduced, and thus the dispersibility of the pigment or the like tends to be reduced. As a result, the number of atoms excluding hydrogen atoms in the graft chain is preferably 40 to 10,000, more preferably 50 to 2,000, and still more preferably 60 to 500.

Herein, the graft chain refers to a portion from the base (an atom bonded to the main chain, in a group which is branched off from the main chain) of the main chain of the copolymer to the terminal of a group branched off from the main chain.

The graft chain preferably has a polymer structure, and examples of such a polymer structure include a poly(meth)acrylate structure (for example, a poly(meth)acrylic structure), a polyester structure, a polyurethane structure, a polyurea structure, a polyamide structure, and a polyether structure.

In order to improve interactive properties between the graft chain and the solvent, and thus enhance the dispersibility of the pigment or the like, the graft chain is preferably a graft chain having at least one selected from the group consisting of a polyester structure, a polyether structure, and a poly(meth)acrylate structure, and more preferably a graft chain having at least one of a polyester structure or a polyether structure.

As the macromonomer (the monomer which has a polymer structure and constitutes a graft chain by being bonded to the main chain of a copolymer) containing such a graft chain, for example, a macromonomer containing a reactive double bond group can be suitably used.

As a commercial macromonomer, which corresponds to the structural unit containing a graft chain contained in the dispersing agent and is suitably used for synthesizing the dispersing agent, for example, AA-6, AA-10, AB-6, AS-6, AN-6, AW-6, AA-714, AY-707, AY-714, AK-5, AK-30, and AK-32 (all are product names, manufactured by TOAGOSEI CO., LTD.), and BLEMMER PP-100, BLEMMER PP-500, BLEMMER PP-800, BLEMMER PP-1000, BLEMMER 55-PET-800, BLEMMER PME-4000, BLEMMER PSE-400, BLEMMER PSE-1300, and BLEMMER 43PAPE-600B (all are product names, manufactured by NOF CORPORATION) are used. Among them, AA-6, AA-10, AB-6, AS-6, AN-6, or BLEMMER PME-4000 is preferable.

The dispersing agent preferably has at least one structure selected from the group consisting of polymethyl acrylate, polymethyl methacrylate, and cyclic or chain-like polyester, more preferably has at least one structure selected from the group consisting of polymethyl acrylate, polymethyl methacrylate, and chain-like polyester, and still more preferably has at least one structure selected from the group consisting of a polymethyl acrylate structure, a polymethyl methacrylate structure, a polycaprolactone structure, and a polyvalerolactone structure. The dispersing agent may be a dispersing agent containing the above structure alone or a dispersing agent containing a plurality of the above structures.

Herein, the polycaprolactone structure refers to a structure containing a structure, which is obtained by ring opening of ε-caprolactone, as a repeating unit. The polyvalerolactone structure refers to a structure containing a structure, which is obtained by ring opening of δ-valerolactone, as a repeating unit.

Specific examples of the dispersing agent having a polycaprolactone structure include dispersing agents in which j and k in Formula (1) and Formula (2) are each 5. In addition, specific examples of the dispersing agent having a polyvalerolactone structure include dispersing agents in which j and k in Formula (1) and Formula (2) are each 4.

Examples of the dispersing agent having a polymethyl acrylate structure include dispersing agents in which, in Formula (4), X⁵ is a hydrogen atom and R⁴ is a methyl group. In addition, examples of the dispersing agent having a polymethyl methacrylate structure include dispersing agents in which, in Formula (4), X⁵ is a methyl group and R⁴ is a methyl group.

Structural Unit Containing Graft Chain

The structural unit containing the graft chain in the dispersing agent preferably includes a structural unit represented by any of Formulae (1) to (4).

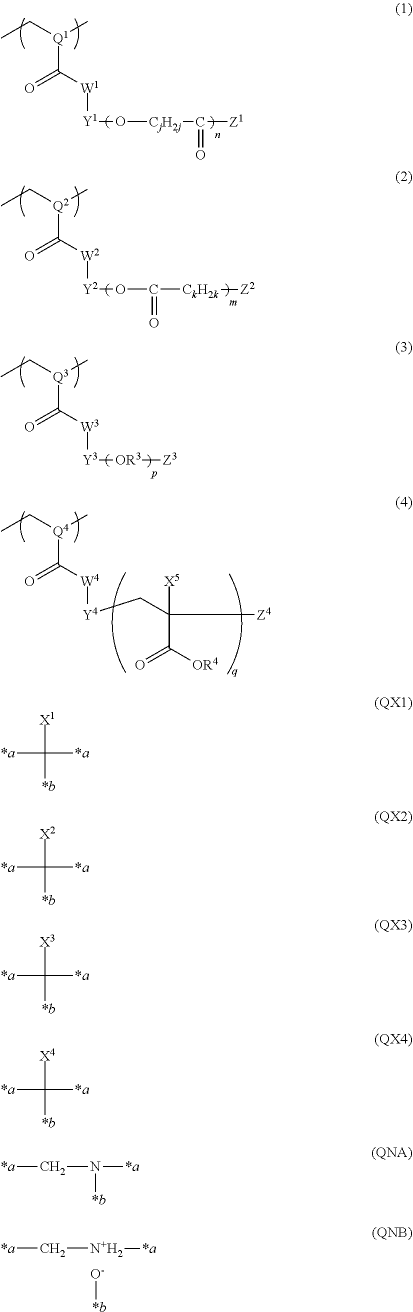

In Formulae (1) to (4), Q¹ is a group represented by any one of Formulae (QX1), (QNA), and (QNB), Q² is a group represented by any one of Formulae (QX2), (QNA), and (QNB), Q³ is a group represented by any one of Formulae (QX3), (QNA), and (QNB), and Q⁴ is a group expressed by any of Formulae (QX4), (QNA), and (QNB).

In Formulae (QX1) to (QX4), (QNA), and (QNB), *a represents a bonding position on the main chain side, and *b represents a bonding position on the side chain side.

In Formulae (1) to (4), W¹, W², W³, and W⁴ each independently represent a single bond, an oxygen atom, or NH.

In Formulae (1) to (4) and (QX1) to (QX4), X¹, X², X³, X⁴, and X⁵ each independently represent a hydrogen atom or a monovalent organic group. From the viewpoint of the restriction on synthesis, X¹, X², X³, X⁴, and X⁵ are each independently preferably a hydrogen atom or an alkyl group having 1 to 12 carbon atoms (the number of carbon atoms), each independently more preferably a hydrogen atom or a methyl group, and each independently still more preferably a methyl group.

In Formulae (1) to (4), Y¹, Y², Y³, and Y⁴ each independently represent a single bond or a divalent linking group, and the linking group is not particularly limited regarding the structure. Specific examples of the divalent linking groups represented by Y¹, Y², Y³, and Y⁴ include linking groups represented by the following (Y-1) to (Y-23).

In the linking group shown below, A represents a bonding position to any one of W¹ to W⁴ in Formulae (1) to (4). B represents a bonding position to a group on a side opposite to any one of W¹ to W⁴, to which A is bonded.

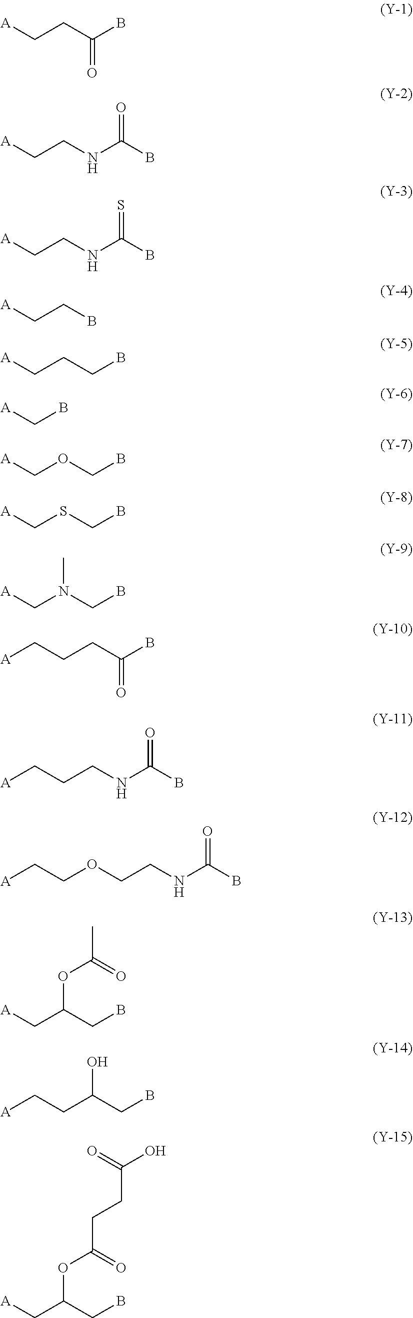

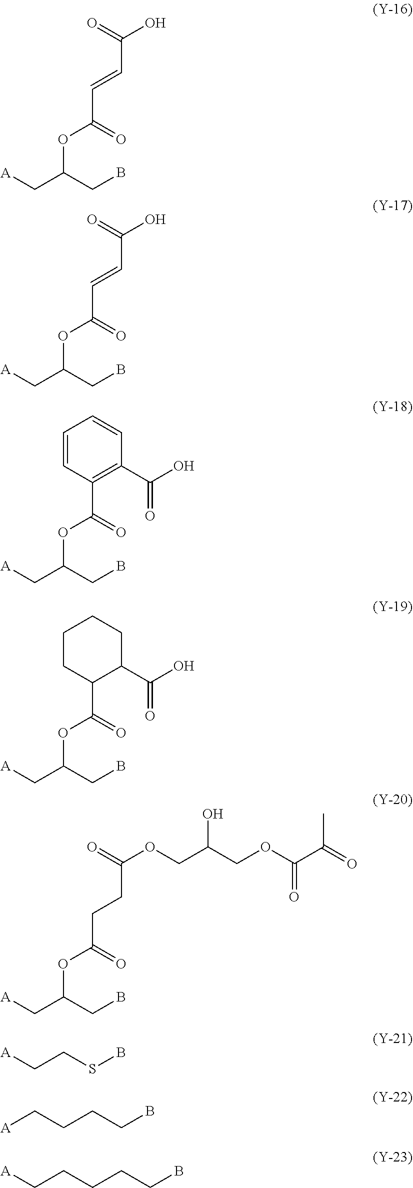

In Formulae (1) to (4), Z¹, Z², Z³, and Z⁴ each independently represent a monovalent substituent. The structure of the substituent is not particularly limited; however, specific examples thereof include an alkyl group, a hydroxyl group, an alkoxy group, an aryloxy group, a heteroaryloxy group, an alkylthio group, an arylthio group, a heteroarylthio group, and an amino group.

Among them, particularly from the viewpoint of improvement in the dispersibility, the substituents represented by Z¹, Z², Z³, and Z⁴ are each independently preferably a group that exhibits a steric repulsion effect, and each independently more preferably an alkyl group or alkoxy group having 5 to 24 carbon atoms, and, among them, in particular, each independently still more preferably a branched alkyl group having 5 to 24 carbon atoms, a cyclic alkyl group having 5 to 24 carbon atoms, or an alkoxy group having 5 to 24 carbon atoms. It is noted that the alkyl group contained in the alkoxy group may be linear, branched, or cyclic.

In addition, it is also preferable that the substituents represented by Z¹, Z², Z³, and Z⁴ are each a group containing a curable group such as a (meth)acryloyl group. Examples of the group containing a curable group include an “—O-alkylene group-(—O-alkylene group-)_{AL}-(meth)acryloyloxy group”. AL represents an integer of 0 to 5 and is preferably 1. The alkylene groups each independently preferably have 1 to 10 carbon atoms. In a case where the alkylene group has a substituent, the substituent is preferably a hydroxyl group.

The substituent may be a group containing an onium structure.

The group containing an onium structure is a group having an anionic moiety and a cationic moiety. Examples of the anionic moiety include a partial structure containing an oxygen anion (—O⁻). Among them, the oxygen anion (—O⁻) is preferably directly bonded to a terminal of a repeating structure attached with n, m, p, or q in the repeating units represented by Formulae (1) to (4), and more preferably directly bonded to a terminal (that is, a right end in -(—O—CⱼH₂ⱼ—CO—)ₙ-) of a repeating structure attached with n in the repeating unit represented by Formula (1).

Examples of the cation of the cationic moiety of the group containing an onium structure include an ammonium cation. In a case where the cationic moiety is the ammonium cation, the cationic moiety is a partial structure containing the cationic nitrogen atom (>N⁺<). The cationic nitrogen atom (>N⁺<) is preferably bonded to four substituents (preferably, organic groups), and it is preferable that one to four among the substituents are each an alkyl group having 1 to 15 carbon atoms. In addition, it is also preferable that one or more (preferably, one) among the four substituents are each a group containing a curable group. Examples of the group containing a curable group, which can serve as a substituent, include the above-described “—O-alkylene group-(—O-alkylene group-)_{AL}-(meth)acryloyloxy group”.

In Formulae (1) to (4), n, m, p, and q are each independently an integer of 1 to 500.

In addition, in Formulae (1) and (2), j and k each independently represent an integer of 2 to 8. From the viewpoints of the temporal stability and developability of the composition, j and k in Formulae (1) and (2) are preferably an integer of 4 to 6 and more preferably 5.

In addition, in Formulae (1) and (2), n and m are preferably an integer of 1 more, more preferably an integer of 2 or more, and still more preferably an integer of 6 or more. In addition, in a case where the dispersing agent has a polycaprolactone structure and a polyvalerolactone structure, the sum of the number of repetitions of the polycaprolactone structure and the number of repetitions of the polyvalerolactone structure is preferably an integer of 2 or more.

In Formula (3), R³ represents a branched or linear alkylene group, and it is preferably an alkylene group having 1 to 10 carbon atoms and more preferably an alkylene group having 2 or 3 carbon atoms. In a case where p is 2 to 500, a plurality of R³'s may be the same or different from each other.

In Formula (4), R⁴ represents a hydrogen atom or a monovalent organic group, and the structure of the monovalent organic group is not particularly limited. R⁴ is preferably a hydrogen atom, an alkyl group, an aryl group, or a heteroaryl group, and more preferably a hydrogen atom or an alkyl group. In a case where R⁴ is an alkyl group, the alkyl group is preferably a linear alkyl group having 1 to 20 carbon atoms, a branched alkyl group having 3 to 20 carbon atoms, or a cyclic alkyl group having 5 to 20 carbon atoms, more preferably a linear alkyl group having 1 to 20 carbon atoms, and still more preferably a linear alkyl group having 1 to 6 carbon atoms. In a case where q in Formula (4) is 2 to 500, a plurality of X⁵'s and a plurality of R⁴'s in the graft copolymer may be respectively the same or different from each other.

In addition, the dispersing agent may have a structural unit which contains two or more different structures and contains a graft chain. That is, the structural units which are represented by Formulae (1) to (4) and have structures different from one another may be included in a molecule of the dispersing agent, and in a case where n, m, p, and q in Formulae (1) to (4) each represent an integer of 2 or more, in Formulae (1) and (2), structures in which j and k are different from each other may be included in the side chain, and in Formulae (3) and (4), a plurality of R³'s, a plurality of R⁴'s, and a plurality of X⁵'s in the molecule may be respectively the same or different from each other.

In addition, from the viewpoints of the temporal stability and developability of the composition, the structural unit represented by Formula (3) is more preferably a structural unit represented by Formula (3A) or Formula (3B).

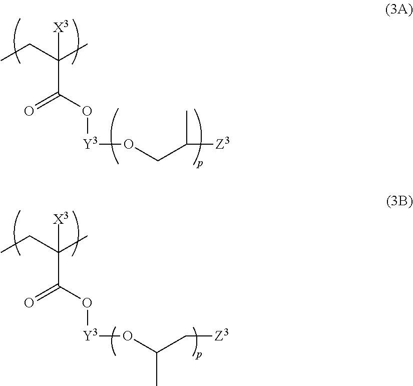

X³, Y³, Z³, and p in Formula (3A) or (3B) are synonymous with X³, Y³, Z³, and p in Formula (3), respectively, and the same applies to the preferred ranges thereof.

The content of the structural unit (for example, the structural units represented by Formulae (1) to (4)) containing a graft chain in the dispersing agent is preferably 2% to 100% by mass and more preferably 6% to 100% by mass in terms of mass, with respect to all the repeating units of the dispersing agent. Among the above, the total content of the structural unit which is represented by Formula (1) and in which n is an integer of 6 or more and the structural unit which is represented by Formula (2) and in which m is an integer of 6 or more is preferably 2% to 100% by mass and more preferably 6% to 100% by mass with respect to all the repeating units of the dispersing agent.

In a case where the content of the structural unit containing a graft chain is within the above range, the dispersibility of the pigment is high and the developability in a case of forming a light shielding film is favorable.

Hydrophobic Structural Unit

In addition, it is also preferable that the dispersing agent contains a hydrophobic structural unit which is different from the structural unit containing a graft chain (that is, does not correspond to the structural unit containing a graft chain). However, in the present specification, the hydrophobic structural unit is a structural unit that does not have an acid group (for example, a carboxyl group, a sulfo group, a monosulfate ester group, —OPO(OH)₂, a monophosphate ester group, a borate group, and/or a phenolic hydroxyl group).

The hydrophobic structural unit is preferably a structural unit derived from (corresponding to) a compound (monomer) having a C log P value of 1.2 or more, and more preferably a structural unit derived from a compound having a C log P value of 1.2 to 8. This makes it possible for the effects of the present invention to be more reliably exhibited.

The C log P value is a value calculated by a program “C LOG P” available from Daylight Chemical Information System, Inc. This program provides a value of “calculated log P” calculated by the fragment approach (see the following documents) of Hansch and Leo. The fragment approach is based on a chemical structure of a compound, and the log P value of the compound is estimated by dividing the chemical structure into partial structures (fragments) and summing up degrees of contribution to log P which are assigned to the fragments. Details of the method are described in the following documents. In the present specification, a C log P value calculated by a program C LOG P v4.82 is used.

A. J. Leo, Comprehensive Medicinal Chemistry, Vol. 4, C. Hansch, P. G. Sammnens, J. B. Taylor and C. A. Ramsden, Eds., p. 295, Pergamon Press, 1990, C. Hansch & A. J. Leo. Substituent Constants For Correlation Analysis in Chemistry and Biology. John Wiley & Sons. A. J. Leo. Calculating log Poct from structure. Chem. Rev., 93, 1281 to 1306, 1993.

The log P refers to a common logarithm of a partition coefficient P, is a physical property value that shows how a certain organic compound is partitioned in an equilibrium of a two-phase system of oil (generally, 1-octanol) and water by using a quantitative numerical value, and is expressed by the following expression.

log P=log(Coil/Cwater)

In the expression, Coil represents a molar concentration of a compound in an oil phase, and Cwater represents a molar concentration of the compound in a water phase.

The larger the positive log P value based on 0, the higher the oil solubility, and the larger the absolute value of negative log P, the higher the water solubility. That is, the value of log P has a negative correlation with the water solubility of an organic compound and thus is widely used as a parameter for estimating the hydrophilicity and hydrophobicity of an organic compound.

The dispersing agent preferably contains, as a hydrophobic structural unit, one or more structural units selected from structural units derived from monomers represented by Formulae (i) to (iii).

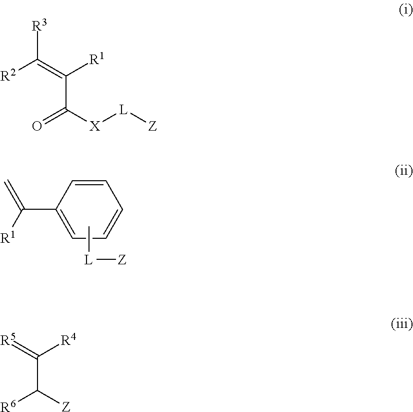

In Formulae (i) to (iii), R¹, R², and R³ each independently represent a hydrogen atom, a halogen atom (for example, a fluorine atom, a chlorine atom, a bromine atom, and the like), or an alkyl group (for example, a methyl group, an ethyl group, a propyl group, and the like) having 1 to 6 carbon atoms.

R¹, R², and R³ are preferably a hydrogen atom or an alkyl group having 1 to 3 carbon atoms, and more preferably a hydrogen atom or a methyl group. R² and R³ are still more preferably a hydrogen atom.

X represents an oxygen atom (—O—) or an imino group (—NH—), and it is preferably an oxygen atom.

L is a single bond or a divalent linking group. Examples of the divalent linking group include a divalent aliphatic group (for example, an alkylene group, a substituted alkylene group, an alkenylene group, a substituted alkenylene group, an alkynylene group, or a substituted alkynylene group), a divalent aromatic group (for example, an arylene group or a substituted arylene group), a divalent heterocyclic group, an oxygen atom (—O—), a sulfur atom (—S—), an imino group (—NH—), a substituted imino group (—NR³¹—, where R³¹ is an aliphatic group, an aromatic group, or a heterocyclic group), a carbonyl group (—CO—), and a combination thereof.

The divalent aliphatic group may have a cyclic structure or a branched structure. The aliphatic group preferably has 1 to 20 carbon atoms, more preferably 1 to 15 carbon atoms, and still more preferably 1 to 10 carbon atoms. The aliphatic group may be an unsaturated aliphatic group or a saturated aliphatic group; however, it is preferably a saturated aliphatic group. In addition, the aliphatic group may have a substituent. Examples of the substituent include a halogen atom, an aromatic group, and a heterocyclic group.

The divalent aromatic group preferably has 6 to 20 carbon atoms, more preferably 6 to 15 carbon atoms, and still more preferably 6 to 10 carbon atoms. In addition, the aromatic group may have a substituent. Examples of the substituent include a halogen atom, an aliphatic group, an aromatic group, and a heterocyclic group.

The divalent heterocyclic group preferably contains a 5-membered ring or a 6-membered ring as a heterocycle. The heterocycle may be fused with another ring (a heterocycle, an aliphatic ring, an aromatic ring, or the like). In addition, the heterocyclic group may have a substituent. Examples of the substituent include a halogen atom, a hydroxyl group, an oxo group (═O), a thioxo group (═S), an imino group (═NH), a substituted imino group (═N—R³², where R³² is an aliphatic group, an aromatic group, or a heterocyclic group), an aliphatic group, an aromatic group, and a heterocyclic group.

L is preferably a single bond, an alkylene group, or a divalent linking group having an oxyalkylene structure. The oxyalkylene structure is more preferably an oxyethylene structure or an oxypropylene structure. In addition, L may have a polyoxyalkylene structure which contains two or more repeating oxyalkylene structures. The polyoxyalkylene structure is preferably a polyoxyethylene structure or a polyoxypropylene structure. The polyoxyethylene structure is represented by —(OCH₂CH₂)ₙ—, and n is preferably an integer of 2 or more and more preferably an integer of 2 to 10.

Examples of Z include an aliphatic group (for example, an alkyl group or a substituted alkyl group), an aromatic group (for example, an aryl group or a substituted aryl group), a heterocyclic group, and a combination thereof. These groups may contain an oxygen atom (—O—), a sulfur atom (—S—), an imino group (—NH—), a substituted imino group (—NR³¹—, where R³¹ is an aliphatic group, an aromatic group, or a heterocyclic group), or a carbonyl group (—CO—).

The aliphatic group may have a cyclic structure or a branched structure. The aliphatic group preferably has 1 to 20 carbon atoms, more preferably 1 to 15 carbon atoms, and still more preferably 1 to 10 carbon atoms. The aliphatic group further contains a ring assembly hydrocarbon group or a crosslinked cyclic hydrocarbon group, and examples of the ring assembly hydrocarbon group include a bicyclohexyl group, a perhydronaphthalenyl group, a biphenyl group, and a 4-cyclohexylphenyl group. Examples of the crosslinked cyclic hydrocarbon ring include a bicyclic hydrocarbon ring such as pinane, bornane, norpinane, norbornane, and bicyclooctane rings (a bicyclo[2.2.2]octane ring, a bicyclo[3.2.1]octane ring, or the like); a tricyclic hydrocarbon ring such as homobredane, adamantane, tricyclo[5.2.1.0^{2,6}]decane, and tricyclo[4.3.1.1^{2,5}]undecane rings; and a tetracyclic hydrocarbon ring such as tetracyclo[4.4.0.1^{2,5}.1^{7,10}]dodecane and perhydro-1,4-methano-5,8-methanonaphthalene rings. In addition, the crosslinked cyclic hydrocarbon ring also includes a fused cyclic hydrocarbon ring, for example, a fused ring in which a plurality of 5- to 8-membered cycloalkane rings, such as perhydronaphthalene (decalin), perhydroanthracene, perhydrophenanthrene, perhydroacenaphthene, perhydrofluorene, perhydroindene, and perhydrophenalene rings, are fused.

As the aliphatic group, a saturated aliphatic group is preferable to an unsaturated aliphatic group. In addition, the aliphatic group may have a substituent. Examples of the substituent include a halogen atom, an aromatic group, and a heterocyclic group. However, the aliphatic group does not have an acid group as a substituent.

The aromatic group preferably has 6 to 20 carbon atoms, more preferably 6 to 15 carbon atoms, and still more preferably 6 to 10 carbon atoms. In addition, the aromatic group may have a substituent. Examples of the substituent include a halogen atom, an aliphatic group, an aromatic group, and a heterocyclic group. However, the aromatic group does not have an acid group as a substituent.

The heterocyclic group preferably contains a 5-membered ring or a 6-membered ring as a heterocycle. The heterocycle may be fused with another heterocycle, an aliphatic ring, or an aromatic ring. In addition, the heterocyclic group may have a substituent. Examples of the substituent include a halogen atom, a hydroxyl group, an oxo group (═O), a thioxo group (═S), an imino group (═NH), a substituted imino group (═N—R³², where R³² is an aliphatic group, an aromatic group, or a heterocyclic group), an aliphatic group, an aromatic group, and a heterocyclic group.

However, the heterocyclic group does not have an acid group as a substituent.

In Formula (iii), R⁴, R⁵, and R⁶ each independently represent a hydrogen atom, a halogen atom (for example, a fluorine atom, a chlorine atom, a bromine atom, and the like), an alkyl group (for example, a methyl group, an ethyl group, a propyl group, and the like) having 1 to 6 carbon atoms, Z, or L-Z. Herein, L and Z are synonymous with the groups described above. R⁴, R⁵, and R⁶ are preferably a hydrogen atom or an alkyl group having 1 to 3 carbon atoms, and more preferably a hydrogen atom.

The monomer represented by Formula (i) is preferably a compound in which R¹, R², and R³ are each a hydrogen atom or a methyl group, L is a single bond, an alkylene group, or a divalent linking group having an oxyalkylene structure, X is an oxygen atom or an imino group, and Z is an aliphatic group, a heterocyclic group, or an aromatic group.

In addition, the monomer represented by Formula (ii) is preferably a compound in which R¹ is a hydrogen atom or a methyl group, L is an alkylene group, and Z is an aliphatic group, a heterocyclic group, or an aromatic group. In addition, the monomer represented by Formula (iii) is preferably a compound in which R⁴, R⁵, and R⁶ are each a hydrogen atom or a methyl group, and Z is an aliphatic group, a heterocyclic group, or an aromatic group.

Examples of the representative compound represented by Formulae (i) to (iii) include a radically polymerizable compound selected from acrylic acid esters, methacrylic acid esters, and styrenes.

It is noted that regarding the examples of the representative compounds represented by Formulae (i) to (iii), reference can be made to, for example, the compounds described in paragraphs 0089 to 0093 of JP2013-249417A, the content of which is incorporated into the present specification.

In the dispersing agent, the content of the hydrophobic structural unit is preferably 10% to 90% by mass and more preferably 20% to 80% by mass with respect to all the repeating units of the dispersing agent. In a case where the content is within the above range, sufficient pattern formation can be obtained.

Functional Group Capable of Forming Interaction with Pigment or the Like

A functional group capable of forming interaction with the pigment or the like (for example, a black pigment) can be introduced into the dispersing agent. Herein, it is preferable that the dispersing agent further contains a structural unit containing a functional group capable of forming interaction with the pigment or the like.

Examples of the functional group capable of forming interaction with the pigment or the like include an acid group, a basic group, a coordinating group, and a reactive functional group.

In a case where the dispersing agent contains an acid group, a basic group, a coordinating group, or a reactive functional group, it is preferable that the dispersing agent contains a structural unit containing an acid group, a structural unit containing a basic group, a structural unit containing a coordinating group, or a reactive structural unit.

In particular, in a case where the dispersing agent further contains, as an acid group, an alkali-soluble group such as a carboxyl group, the developability for pattern formation by alkali development can be imparted to the dispersing agent.

That is, in a case where an alkali-soluble group is introduced into the dispersing agent, in the composition, a polymer compound as the dispersing agent which contributes to the dispersion of the pigment or the like has alkali solubility. The composition containing such a dispersing agent is excellent in light shielding properties of a light shielding film formed by exposure, and thus the alkali developability of non-exposed portions is improved.

In addition, in a case where the dispersing agent contains a structural unit containing an acid group, the dispersing agent is likely to be compatible with the solvent, and thus coating properties also tend to be improved.

It is presumed that this is because the acid group in the structural unit containing an acid group is likely to interact with the pigment or the like, the dispersing agent stably disperses the pigment or the like, the viscosity of the dispersing agent dispersing the pigment or the like is reduced, and thus the dispersing agent is also likely to be dispersed stably.

However, the structural unit containing an alkali-soluble group as an acid group may be the same as or different from the structural unit containing a graft chain, but the structural unit containing an alkali-soluble group as an acid group is a structural unit different from the hydrophobic structural unit (that is, the structural unit does not correspond to the hydrophobic structural unit).

The acid group, which is a functional group capable of forming interaction with the pigment or the like is a carboxyl group, a sulfo group, a monosulfate ester group, —OPO(OH)₂, a monophosphate ester group, a borate group, a phenolic hydroxyl group, or the like. It is preferably at least one of a carboxyl group, a sulfo group, or —OPO(OH)₂, and more preferably a carboxyl group. The carboxyl group has good adsorption to the pigment or the like and high dispersibility.

That is, it is preferable that the dispersing agent further contains a structural unit containing at least one of a carboxyl group, a sulfo group, or —OPO(OH)₂.

The dispersing agent may have one or more structural units containing an acid group.

The dispersing agent may contain or may not contain a structural unit containing an acid group. However, in a case where the dispersing agent contains a structural unit containing an acid group, the content thereof is preferably 3% to 95% by mass, and from the viewpoint of suppressing damage to the image intensity by alkali development, it is more preferably 5% to 92% by mass, with respect to all the repeating units of the dispersing agent.

Examples of the basic group, which is the functional group capable of forming interaction with the pigment or the like, include a primary amino group, a secondary amino group, a tertiary amino group, a heterocyclic ring containing an N atom, and an amide group, and from the viewpoints of favorable adsorptive power to the pigment or the like and high dispersibility, a tertiary amino group is preferable. The dispersing agent may contain one or more of these basic groups.

The dispersing agent may or may not contain the structural unit containing the basic group. However, in a case where the dispersing agent contains the structural unit containing the basic group, the content thereof is preferably 0.010% to 50% by mass by mass, and from the viewpoint of suppressing developability inhibition, it is more preferably 0.01% to 30%, with respect to all the repeating units of the dispersing agent.

Examples of the coordinating group and the reactive functional group, which are the functional groups capable of forming interaction with the pigment or the like, include an acetyl acetoxy group, a trialkoxysilyl group, an isocyanate group, an acid anhydride, and an acid chloride. A preferred functional group is an acetyl acetoxy group from the viewpoints of favorable adsorptive power to the pigment or the like and high dispersibility of the pigment or the like. The dispersing agent may have one or more of these groups.

The dispersing agent may or may not contain the structural unit containing the coordinating group or the structural unit containing the reactive functional group. However, in a case where the dispersing agent contains the structural unit containing the coordinating group or the structural unit containing the reactive functional group, the content thereof is preferably 10% to 80% by mass, and from the viewpoint of suppressing developability inhibition, it is more preferably 20% to 60% by mass, with respect to all the repeating units of the dispersing agent.

In a case where the dispersing agent contains, other than the graft chain, the functional group capable of forming interaction with the pigment or the like, the functional groups capable of forming interaction with various pigments or the like may be contained, the way these functional groups are introduced is not particularly limited; however, it is preferable that the dispersing agent contains one or more structural units selected from structural units derived from monomers represented by Formulae (iv) to (vi).

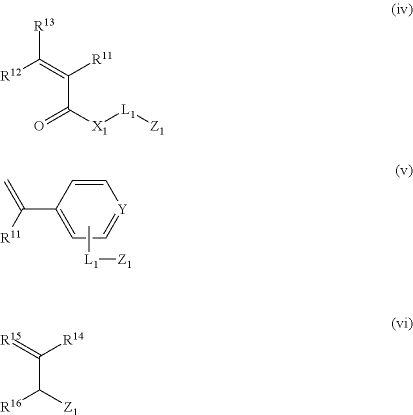

In Formulae (iv) to (vi), R¹¹, R¹², and R¹³ each independently represent a hydrogen atom, a halogen atom (for example, a fluorine atom, a chlorine atom, a bromine atom, and the like), or an alkyl group (for example, a methyl group, an ethyl group, a propyl group, and the like) having 1 to 6 carbon atoms.

In Formulae (iv) to (vi), R¹¹, R¹², and R¹³ are preferably a hydrogen atom or an alkyl group having 1 to 3 carbon atoms, and more preferably a hydrogen atom or a methyl group. In General Formula (iv), R¹² and R¹³ are still more preferably a hydrogen atom.

In Formula (iv), X₁ represents an oxygen atom (—O—) or an imino group (—NH—), and it is preferably an oxygen atom.

In addition, in Formula (v), Y represents a methine group or a nitrogen atom.

In addition, in Formulae (iv) and (v), L₁ represents a single bond or a divalent linking group. The divalent linking group has the same definition as the divalent linking group represented by L in Formula (i).

L₁ is preferably a single bond, an alkylene group, or a divalent linking group having an oxyalkylene structure. The oxyalkylene structure is more preferably an oxyethylene structure or an oxypropylene structure. In addition, L₁ may have a polyoxyalkylene structure which contains two or more repeating oxyalkylene structures. The polyoxyalkylene structure is preferably a polyoxyethylene structure or a polyoxypropylene structure. The polyoxyethylene structure is represented by —(OCH₂CH₂)ₙ—, and n is preferably an integer of 2 or more and more preferably an integer of 2 to 10.

In Formulae (iv) to (vi), Z₁ represents a functional group capable of forming interaction with the pigment or the like, other than a graft chain, and is preferably a carboxyl group or a tertiary amino group and more preferably a carboxyl group.

In Formula (vi), R¹⁴, R¹, and R¹⁶ each independently represent a hydrogen atom, a halogen atom (for example, a fluorine atom, a chlorine atom, a bromine atom, and the like), an alkyl group (for example, a methyl group, an ethyl group, a propyl group, and the like) having 1 to 6 carbon atoms, —Z₁, or L₁-Z₁. Herein, L₁ and Z₁ are synonymous with L₁ and Z₁ described above, and the same applies to the preferred examples thereof. R¹⁴, R¹⁵, and R¹⁶ are preferably a hydrogen atom or an alkyl group having 1 to 3 carbon atoms, and more preferably a hydrogen atom.

The monomer represented by Formula (iv) is preferably a compound in which R¹¹, R¹², and R¹³ are each independently a hydrogen atom or a methyl group, L₁ is an alkylene group or a divalent linking group having an oxyalkylene structure, X₁ is an oxygen atom or an imino group, and Z₁ is a carboxyl group.

In addition, the monomer represented by Formula (v) is preferably a compound in which R¹¹ is a hydrogen atom or a methyl group, L₁ is an alkylene group, Z₁ is a carboxyl group, and Y is a methine group.

Furthermore, the monomer represented by Formula (vi) is preferably a compound in which R¹⁴, R¹⁵, and R¹⁶ are each independently a hydrogen atom or a methyl group, and Z₁ is a carboxyl group.

Representative examples of the monomers (compounds) represented by Formulae (iv) to (vi) are shown below.

Examples of the monomers include methacrylic acid, crotonic acid, isocrotonic acid, a reactant of a compound (for example, 2-hydroxyethyl methacrylate) containing an addition polymerizable double bond and a hydroxyl group in a molecule with a succinic acid anhydride, a reactant of a compound containing an addition polymerizable double bond and a hydroxyl group in a molecule with a phthalic acid anhydride, a reactant of a compound containing an addition polymerizable double bond and a hydroxyl group in a molecule with a tetrahydroxyphthalic acid anhydride, a reactant of a compound containing an addition polymerizable double bond and a hydroxyl group in a molecule with trimellitic acid anhydride, a reactant of a compound containing an addition polymerizable double bond and a hydroxyl group in a molecule with a pyromellitic acid anhydride, acrylic acid, an acrylic acid dimer, an acrylic acid oligomer, maleic acid, itaconic acid, fumaric acid, 4-vinylbenzoic acid, vinyl phenol, and 4-hydroxyphenyl methacrylamide.

From the viewpoints of the interaction with the pigment or the like, the temporal stability, and the permeability into a developer, the content of the structural unit containing a functional group capable of forming interaction with the pigment or the like is preferably 0.05% to 90% by mass, more preferably 1.0% to 80% by mass, and still more preferably 10% to 70% by mass, with respect to all the repeating units of the dispersing agent.

Another Structural Unit

In addition, for the purpose of improving various performances such as image intensity, as long as the effects of the present invention are not impaired, the dispersing agent may further have another structural unit (for example, a structural unit containing a functional group or the like having the compatibility with the solvent which will be described later) which has various functions and is different from the structural unit containing a graft chain, the hydrophobic structural unit, and the structural unit containing a functional group capable of forming interaction with the pigment or the like.

Examples of such other structural unit include a structural unit derived from a radically polymerizable compound selected from acrylonitriles, methacrylonitriles, and the like.

One or more of these other structural units can be used in the dispersing agent, and the content thereof is preferably 0% to 80% by mass and more preferably 10% to 60% by mass with respect to all the repeating units of the dispersing agent. In a case where the content is within the above range, sufficient pattern formability is maintained.

In addition, as the dispersing agent, for example, the resin described in paragraphs 0033 to 0049 of JP2016-109763A can also be used, the content of which is incorporated into the present specification.

The polymer compound used as the dispersing agent may be a resin containing a radial structure (a radial polymer compound). The radial polymer compound preferably contains an acid group (for example, a carboxyl group, a sulfo group, a monosulfate ester group, —OPO(OH)₂, a monophosphate ester group, a borate group, and/or a phenolic hydroxyl group). That is, the radial polymer compound is preferably an acid group-containing resin containing a radial structure.

The radial polymer compound is preferably, for example, a compound represented by General Formula (X).

(A¹-R²—)ₙR¹(—P¹)ₘ (X)

In General Formula (X), A¹ represents a monovalent organic group containing at least one moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxyl group. n pieces of A¹ may be the same or different from each other.

That is, A¹ represents a monovalent organic group containing at least one functional group having an adsorptive ability to a pigment, such as an organic dye structure or a heterocyclic structure, or a functional group having an adsorptive ability to a pigment, such as an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, or a hydroxyl group.

Hereinafter, the moiety having an adsorptive ability to a pigment (the above-described structure and functional group) will be collectively referred to as the “adsorption moiety” and will be described below.

It suffices that one A¹ includes at least one adsorption moiety, two or more, and one A¹ may include two or more adsorption moieties.

Further, in the present invention, the “monovalent organic group containing at least one adsorption moiety” is a monovalent organic group obtained by bonding the above-described adsorption moiety to an organic linking group consisting of 1 to 200 carbon atoms, 0 to 20 nitrogen atoms, 0 to 100 oxygen atoms, 1 to 400 hydrogen atoms, and 0 to 40 sulfur atoms. In a case where the adsorption moiety itself can constitute a monovalent organic group, the adsorption moiety itself may be a monovalent organic group represented by A¹.

First, the adsorption moiety that constitutes the above A¹ will be described below.

Examples of the above-described “organic dye structure” include phthalocyanine-based, insoluble azo-based, azo lake-based, anthraquinone-based, quinacridone-based, dioxazine-based, diketopyrrolo pyrrole-based, anthrapyridine-based, anthanthrone-based, indanthrone-based, flavanthrone-based, perinone-based, perylene-based, and thioindigo-based dye structures.

In addition, examples of the above-described “heterocyclic structure” includes thiophene, furan, xanthene, pyrrole, pyrroline, pyrrolidine, dioxolane, pyrazole, pyrazoline, pyrazolidine, imidazole, oxazole, thiazole, oxadiazole, triazole, thiadiazole, pyran, pyridine, piperidine, dioxane, morpholine, pyridazine, pyrimidine, piperazine, triazine, trithiane, isoindoline, isoindolinone, benzimidazolone, benzothiazole, succinimide, phthalimide, naphthalimide, hydantoin, indole, quinoline, carbazole, acridine, acridone, and anthraquinone.

The “organic dye structure” or the “heterocyclic structure” may further have a substituent, and examples of the substituent include an alkyl group having 1 to 20 carbon atoms such as a methyl group and or an ethyl group, an aryl group having 6 to 16 carbon atoms such as phenyl group or naphthyl group, a hydroxyl group, an amino group, a carboxyl group, a sulfonamide group, N-sulfonylamide group, an acyloxy group having 1 to 6 carbon atoms such an acetoxy group, an alkoxy group having 1 to 20 carbon atoms such as a methoxy group or an ethoxy group, a halogen atom such as chlorine or bromine, an alkoxycarbonyl group having 2 to 7 carbon atoms such as a methoxycarbonyl group, an ethoxycarbonyl group, or a cyclohexyloxycarbonyl group, a cyano group, and a carbonic ester group such as t-butyl carbonate. Here, these substituents may be bonded to the organic dye structure or the heterocycle structure through a linking group composed of a combination of the following structural units or the above structural units.

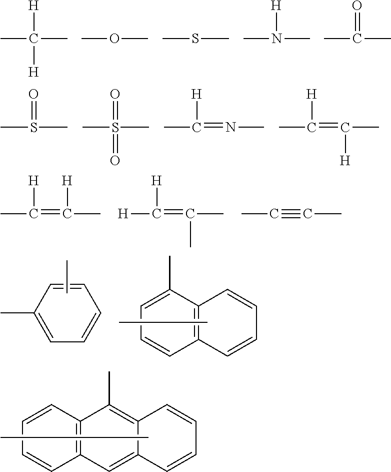

Examples of the above-described “acidic group” include a carboxyl group, a sulfo group, a monosulfate ester group, —OPO(OH)₂, a monophosphate ester group, a borate group, and a phenolic hydroxyl group.

Here, the acidic group corresponds to the above-described acid group.

Further, examples of the above-described “group having a basic nitrogen atom” include an amino group (—NH₂), a substituted imino group (—NHR⁸, or —NR⁹R¹⁰, where R⁸, R⁹, and R¹⁰ each independently represent an alkyl group having 1 to 20 carbon atoms, an aryl group having 6 or more carbon atoms, or an aralkyl group having 7 or more carbon atoms), a guanidyl group represented by Formula (a1), and an amidinyl group represented by Formula (a2).

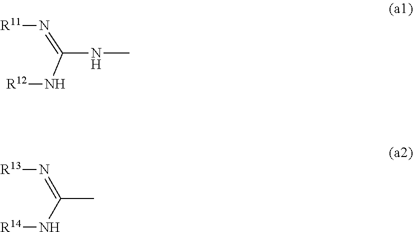

In Formula (a1), R¹¹, and R¹² each independently represent an alkyl group having 1 to 20 carbon atoms, an aryl group having 6 or more carbon atoms, or an aralkyl group having 7 or more carbon atoms.

In Formula (a2), R¹³, and R¹⁴ each independently represent an alkyl group having 1 to 20 carbon atoms, an aryl group having 6 or more carbon atoms, or an aralkyl group having 7 or more carbon atoms.

Among the above, they are preferably an amino group (—NH₂), a substituted imino group (—NHR⁸, —NR⁹R¹⁰, where R⁸, R⁹, and R¹⁰ each independently represent an alkyl group having 1 to 10 carbon atoms, a phenyl group, or a benzyl group), a guanidyl group represented by Formula (a1) [in Formula (a1), R¹¹ and R¹² each independently represent an alkyl group having 1 to 10 carbon atoms, a phenyl group, or a benzyl group], or an amidinyl group represented by Formula (a2) [in Formula (a2), R¹³ and R¹⁴ each independently represent an alkyl group having 1 to 10 carbon atoms, a phenyl group, or a benzyl group].

Examples of the above-described “urea group” include —NR¹⁵CONR¹⁶R¹⁷ (where R¹⁵, R¹⁶, and R¹⁷ each independently represent a hydrogen atom, an alkyl group having 1 to 20 carbon atoms, an aryl group having 6 or more carbon atoms, or an aralkyl group having 7 or more carbon atoms).

Examples of the above “urethane group” include —NHCOOR¹⁸, —NR¹⁹COOR²⁰, —OCONHR²¹, and —OCONR²²R²³ (where R¹⁸, R¹⁹, R²⁰, R²¹, R²², and R²³ each independently represents an alkyl group having 1 to 20 carbon atoms, an aryl group having 6 or more carbon atoms, or an aralkyl group having 7 carbon atoms).

Examples of the above-described “group having a coordinating oxygen atom” include an acetylacetonato group and a crown ether.

Examples of the above-described “hydrocarbon group having 4 or more carbon atoms” include an alkyl group having 4 or more carbon atoms, an aryl group having 6 or more carbon atoms, and an aralkyl group having 7 or more carbon atoms. An alkyl group having 4 to 20 carbon atoms, an aryl group having 6 to 20 carbon atoms, or an aralkyl group having 7 to 20 carbon atoms is preferable, and an alkyl group having 4 to 15 carbon atoms (for example, an octyl group or a dodecyl group), an aryl group having 6 to 15 carbon atoms (for example, a phenyl group or a naphthyl group), or an aralkyl group having 7 to 15 carbon atoms (for example, a benzyl group) is more preferable.

Examples of the above-described “alkoxysilyl group” include a trimethoxysilyl group and a triethoxysilyl group.

The organic linking group to which the adsorption moiety is bonded is preferably a single bond or an organic linking group consisting of 1 to 100 carbon atoms, 0 to 10 nitrogen atoms, 0 to 50 oxygen atoms, 1 to 200 hydrogen atoms, and 0 to 20 sulfur atoms, and this organic linking group may be unsubstituted or may further have a substituent.

Specific examples of this organic linking group include a group composed of a combination of the following structural units or the above structural units.

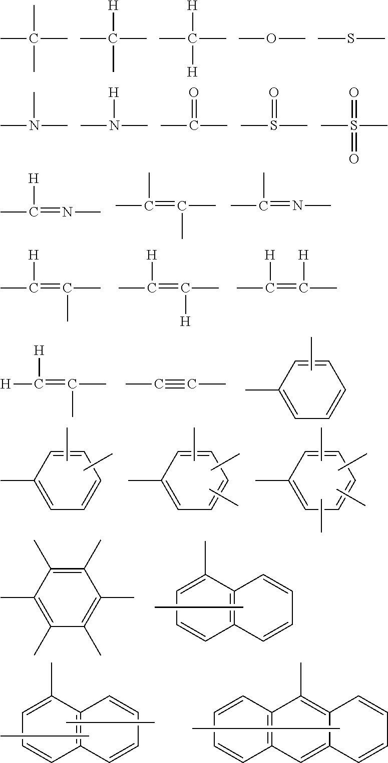

In a case where the organic linking group has a substituent, examples of the substituent include an alkyl group having 1 to 20 carbon atoms such as a methyl group and or an ethyl group, an aryl group having 6 to 16 carbon atoms such as phenyl group or naphthyl group, a hydroxyl group, an amino group, a carboxyl group, a sulfonamide group, N-sulfonylamide group, an acyloxy group having 1 to 6 carbon atoms such an acetoxy group, an alkoxy group having 1 to 6 carbon atoms such as a methoxy group or an ethoxy group, a halogen atom such as chlorine or bromine, an alkoxycarbonyl group having 2 to 7 carbon atoms such as a methoxycarbonyl group, an ethoxycarbonyl group, or a cyclohexyloxycarbonyl group, a cyano group, and a carbonic ester group such as t-butyl carbonate.

Among the above examples, the above A¹ is preferably a monovalent organic group containing at least one moiety selected from an organic dye structure, a heterocyclic structure, an acidic group, a group having a basic nitrogen atom, a urea group, and a hydrocarbon group having 4 or more carbon atoms.

The above A¹ is more preferably a monovalent organic group represented by General Formula (b).

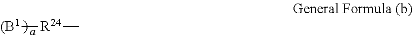

In General Formula (b), B¹ represents the above-described adsorption moiety (that is, the moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxyl group), and R²⁴ represents a single bond or an (a+1)-valent organic linking group. a represents an integer of 1 to 10, and a pieces of B¹ may be the same or different from each other.

Examples of the adsorption moiety represented by the above B¹ include the same one as the adsorption moiety that constitutes A¹ of General Formula (X) described above, and the same applies to the preferred examples thereof.

Among them, a moiety selected from an organic dye structure, a heterocyclic structure, an acidic group, a group having a basic nitrogen atom, a urea group, and a hydrocarbon group having 4 or more carbon atoms is preferable.

R²⁴ represents a single bond or an (a+1)-valent organic linking group, where a represents 1 to 10 and is preferably 1 to 3.

The (a+1)-valent organic linking group includes a group consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

Specific examples of the (a+1)-valent organic linking group include a group (which may form a ring structure) composed of a combination of the following structural units or the above structural units.

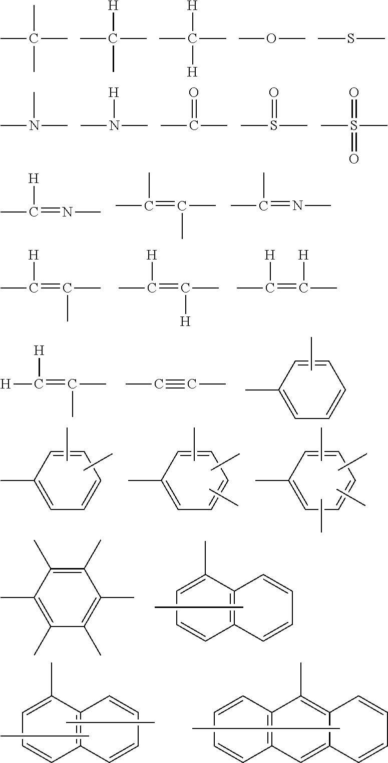

R²⁴ is preferably a single bond or an (a+1)-valent or linking group consisting of 1 to 50 carbon atoms, 0 to 8 nitrogen atoms, 0 to 25 oxygen atoms, 1 to 100 hydrogen atoms, and 0 to 10 sulfur atoms, more preferably a single bond or an (a+1)-valent or linking group consisting of 1 to 30 carbon atoms, 0 to 6 nitrogen atoms, 0 to 15 oxygen atoms, 1 to 50 hydrogen atoms, and 0 to 7 sulfur atoms, and particularly preferably a single bond or an (a+1)-valent or linking group consisting of 1 to 10 carbon atoms, 0 to 5 nitrogen atoms, 0 to 10 oxygen atoms, 1 to 30 hydrogen atoms, and 0 to 5 sulfur atoms.

Among the above, in a case where the (a+1)-valent organic linking group has a substituent, examples of the substituent include an alkyl group having 1 to 20 carbon atoms such as a methyl group and or an ethyl group, an aryl group having 6 to 16 carbon atoms such as phenyl group or naphthyl group, a hydroxyl group, an amino group, a carboxyl group, a sulfonamide group, N-sulfonylamide group, an acyloxy group having 1 to 6 carbon atoms such an acetoxy group, an alkoxy group having 1 to 6 carbon atoms such as a methoxy group or an ethoxy group, a halogen atom such as chlorine or bromine, an alkoxycarbonyl group having 2 to 7 carbon atoms such as a methoxycarbonyl group, an ethoxycarbonyl group, or a cyclohexyloxycarbonyl group, a cyano group, and a carbonic ester group such as t-butyl carbonate.

In General Formula (X), R² represents a single bond or a divalent organic linking group. n pieces of R² may be the same or different from each other.

The divalent organic linking group includes a group consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

Specific examples of the divalent organic linking group include a group composed of a combination of the following structural units or the above structural units.

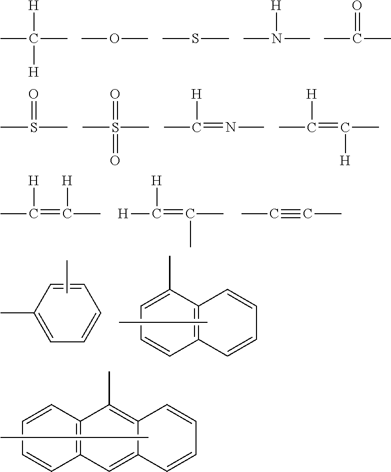

R² is preferably a single bond or a divalent organic linking group consisting of 1 to 50 carbon atoms, 0 to 8 nitrogen atoms, 0 to 25 oxygen atoms, 1 to 100 hydrogen atoms, and 0 to 10 sulfur atoms, more preferably a single bond or a divalent organic linking group consisting of 1 to 30 carbon atoms, 0 to 6 nitrogen atoms, 0 to 15 oxygen atoms, 1 to 50 hydrogen atoms, and 0 to 7 sulfur atoms, and particularly preferably a single bond or a divalent organic linking group consisting of 1 to 10 carbon atoms, 0 to 5 nitrogen atoms, 0 to 10 oxygen atoms, 1 to 30 hydrogen atoms, and 0 to 5 sulfur atoms.

Among the above, in a case where the divalent organic linking group has a substituent, examples of the substituent include an alkyl group having 1 to 20 carbon atoms such as a methyl group and or an ethyl group, an aryl group having 6 to 16 carbon atoms such as phenyl group or naphthyl group, a hydroxyl group, an amino group, a carboxyl group, a sulfonamide group, N-sulfonylamide group, an acyloxy group having 1 to 6 carbon atoms such an acetoxy group, an alkoxy group having 1 to 6 carbon atoms such as a methoxy group or an ethoxy group, a halogen atom such as chlorine or bromine, an alkoxycarbonyl group having 2 to 7 carbon atoms such as a methoxycarbonyl group, an ethoxycarbonyl group, or a cyclohexyloxycarbonyl group, a cyano group, and a carbonic ester group such as t-butyl carbonate.

In General Formula (X), R¹ represents an (m+n)-valent organic linking group. m+n satisfies 3 to 10.

The (m+n)-valent organic linking group represented by R¹ includes a group consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

Specific examples of the (m+n)-valent organic linking group include a group (which may form a ring structure) composed of a combination of the following structural units or the above structural units.

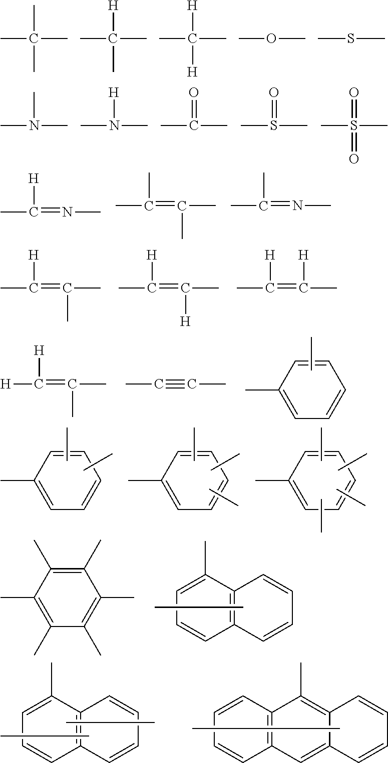

The (m+n)-valent organic linking group is preferably a group consisting of 1 to 60 carbon atoms, 0 to 10 nitrogen atoms, 0 to 40 oxygen atoms, 1 to 120 hydrogen atoms, and 0 to 10 sulfur atoms, more preferably a group consisting of 1 to 50 carbon atoms, 0 to 10 nitrogen atoms, 0 to 30 oxygen atoms, 1 to 100 hydrogen atoms, and 0 to 7 sulfur atoms, and still more preferably a group consisting of 1 to 40 carbon atoms, 0 to 8 nitrogen atoms, 0 to 20 oxygen atoms, 1 to 80 hydrogen atoms, and 0 to 5 sulfur atoms.

Among the above, in a case where the (m+n)-valent organic linking group has a substituent, examples of the substituent include an alkyl group having 1 to 20 carbon atoms such as a methyl group and or an ethyl group, an aryl group having 6 to 16 carbon atoms such as phenyl group or naphthyl group, a hydroxyl group, an amino group, a carboxyl group, a sulfonamide group, N-sulfonylamide group, an acyloxy group having 1 to 6 carbon atoms such an acetoxy group, an alkoxy group having 1 to 6 carbon atoms such as a methoxy group or an ethoxy group, a halogen atom such as chlorine or bromine, an alkoxycarbonyl group having 2 to 7 carbon atoms such as a methoxycarbonyl group, an ethoxycarbonyl group, or a cyclohexyloxycarbonyl group, a cyano group, and a carbonic ester group such as t-butyl carbonate.

Specific examples [specific examples (1) to (17)] of the (m+n)-valent organic linking group represented by the above R¹ are shown below. However, the present invention is not limited thereto.

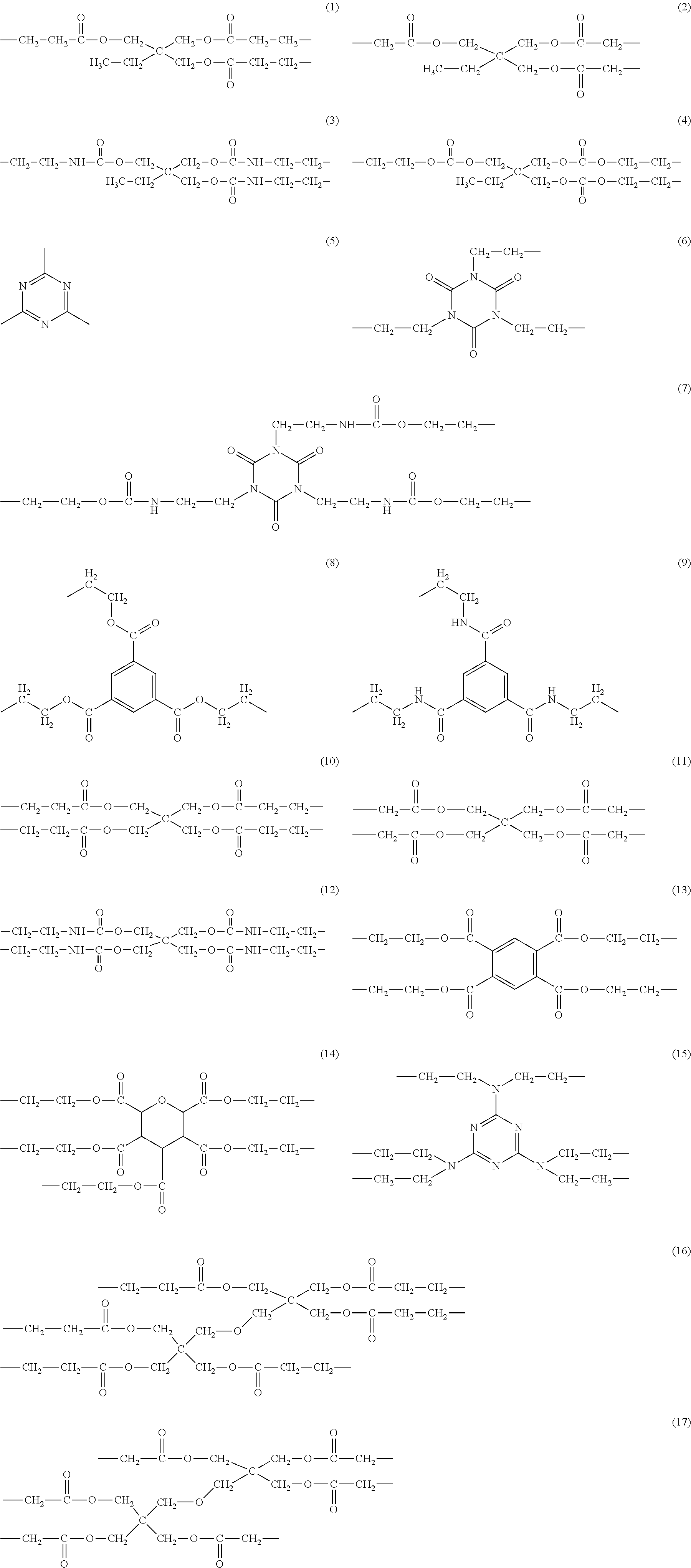

Among the above specific examples, the following groups are the most preferable (m+n)-valent organic linking groups from the viewpoint of availability of raw materials, ease of synthesis, and solubility in various solvents.

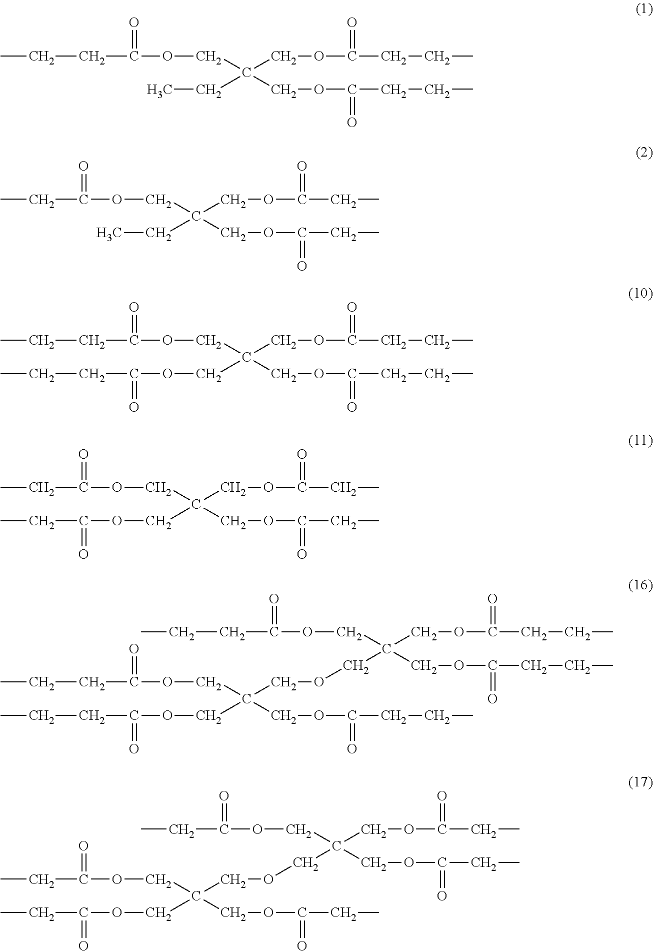

In General Formula (X), m represents 1 to 8. m is preferably 1 to 5, more preferably 1 to 4, and still more preferably 1 to 3.

In addition, in General Formula (X), n represents 2 to 9. n is preferably 2 to 8, more preferably 2 to 7, and still more preferably 3 to 6.

In General Formula (X), P¹ represents a polymer skeleton, and it can be selected from known polymers and the like according to the purpose. m pieces of P¹ may be the same or different from each other.

In order to constitute a polymer skeleton, it is preferably, among the polymers, at least one selected from the group consisting of a polymer or copolymer of a vinyl monomer, an ester-based polymer, an ether-based polymer, a urethane-based polymer, an amide-based polymer, an epoxy-based polymer, a silicone-based polymer, or a modified product or copolymer thereof, [for example, a polyether/polyurethane copolymer or a copolymer of a polymer of polyether/a vinyl monomer (any one of a random copolymer, a block copolymer, or a graft copolymer may be good) is included], more preferably at least one selected from the group consisting of a polymer or copolymer of a vinyl monomer, an ester-based polymer, an ether-based polymer, a urethane-based polymer, or a modified product or copolymer thereof, and still more preferably a polymer or copolymer of a vinyl monomer.

Further, the polymer is preferable to be soluble in an organic solvent. In a case where the compatibility with an organic solvent is low, the compatibility with the dispersion medium may be weakened, and thus an adsorption layer sufficient for stabilizing the dispersion may not be secured, for example, in a case where the polymer is used as a pigment dispersing agent.

The vinyl monomer is not particularly limited; however, it is preferably, for example, (meth)acrylic acid esters, crotonic acid esters, vinyl esters, maleic acid diesters, fumaric acid diesters, itaconic acid diesters, (meth)acrylamides, styrenes, vinyl ethers, vinyl ketones, olefins, maleimides, (meth)acrylonitriles, or vinyl monomers having an acidic group.

Hereinafter, preferred examples of these vinyl monomers will be described.

Examples of (meth)acrylic acid esters include methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, amyl (meth)acrylate, n-hexyl (meth)acrylate, cyclohexyl (meth)acrylate, t-butyl cyclohexyl (meth)acrylate, 2-ethylhexyl (meth)acrylate, t-octyl (meth)acrylate, dodecyl (meth)acrylate, octadecyl (meth)acrylate, acetoxyethyl (meth)acrylate, phenyl (meth)acrylate, 2-hydroxyethyl (meth)acrylate, 2-hydroxypropyl (meth)acrylate, 3-hydroxypropyl (meth)acrylate, 4-hydroxybutyl (meth)acrylate, 2-methoxyethyl (meth)acrylate, 2-ethoxyethyl (meth)acrylate, 2-(2-methoxyethoxy)ethyl (meth)acrylate, 3-phenoxy-2-hydroxypropyl (meth)acrylate, 2-chloroethyl (meth)acrylate, glycidyl (meth)acrylate, 3,4-epoxycyclohexylmethyl (meth)acrylate, vinyl (meth)acrylate, 2-phenylvinyl (meth)acrylate, 1-propenyl (meth)acrylate, allyl (meth)acrylate, 2-aryloxyethyl (meth)acrylate, propargyl (meth)acrylate, benzyl (meth)acrylate, diethylene glycol monomethyl ether (meth)acrylate, diethylene glycol monoethyl ether (meth)acrylate, triethylene glycol monomethyl ether (meth)acrylate, triethylene glycol monoethyl ether (meth)acrylate, polyethylene glycol monomethyl ether (meth)acrylate, polyethylene glycol monoethyl ether (meth)acrylate, β-phenoxyethoxyethyl (meth)acrylate, nonylphenoxy polyethylene glycol (meth)acrylate, dicyclopentenyl (meth)acrylate, dicyclopentenyloxyethyl (meth)acrylate, trifluoroethyl (meth)acrylate, octafluoropentyl (meth)acrylate, perfluorooctylethyl (meth)acrylate, dicyclopentanyl (meth)acrylate, tribromophenyl (meth)acrylate, tribromophenyloxyethyl (meth)acrylate, and γ-butyrolactone (meth)acrylate.

Examples of the crotonic acid ester include butyl crotonate, hexyl crotonate.

Examples of the vinyl esters include vinyl acetate, vinyl chloroacetate, vinyl propionate, vinyl butyrate, vinyl methoxyacetate, vinyl benzoate.

Examples of the maleic acid diester include dimethyl maleate, diethyl maleate, and dibutyl maleate.

Examples of the fumaric acid diester include dimethyl fumarate, diethyl fumarate, and dibutyl fumarate.

Examples of the itaconic acid diesters include dimethyl itaconate, diethyl itaconate, and dibutyl itaconate.

Examples of the (meth)acrylamides include (meth)acrylamide, N-methyl (meth)acrylamide, N-ethyl (meth)acrylamide, N-propyl (meth)acrylamide, N-isopropyl (meth)acrylamide, an N-n-butyl (meth)acrylamide, N-t-butyl (meth)acrylamide, N-cyclohexyl (meth)acrylamide, N-(2-methoxyethyl) (meth)acrylamide, N,N-dimethyl (meth)acrylamide, N, N-diethyl (meth)acrylamide, N-phenyl (meth)acrylamide, N-nitrophenyl acrylamide, N-ethyl-N-phenyl acrylamide, N-benzyl (meth)acrylamide, (meth)acryloylmorpholine, diacetone acrylamide, N-methylol acrylamide, N-hydroxyethyl acrylamide, vinyl (meth)acrylamide, N,N-diallyl (meth)acrylamide, and N-allyl (meth)acrylamide.

Examples of the styrenes include styrene, methyl styrene, dimethyl styrene, trimethyl styrene, ethyl styrene, isopropyl styrene, butyl styrene, hydroxystyrene, methoxystyrene, butoxystyrene, acetoxystyrene, chlorostyrene, dichlorostyrene, bromostyrene, chloromethyl styrene, hydroxystyrene protected by a group that can be deprotected by an acidic substance (for example, t-Boc), methyl vinylbenzoate, and α-methyl styrene.

Examples of the vinyl ethers include methyl vinyl ether, ethyl vinyl ether, 2-chloroethyl vinyl ether, hydroxyethyl vinyl ether, propyl vinyl ether, butyl vinyl ether, hexyl vinyl ether, octyl vinyl ether, methoxyethyl vinyl ether, and phenyl vinyl ether.

Examples of the vinyl ketones include methyl vinyl ketone, ethyl vinyl ketone, propyl vinyl ketone, and phenyl vinyl ketone.

Examples of the olefins include ethylene, propylene, isobutylene, butadiene, and isoprene.

Examples of the maleimides include maleimide, butyl maleimide, cyclohexyl maleimide, phenyl maleimide.

(Meth)acrylonitrile, or a heterocyclic group substituted with a vinyl group (for example, vinyl pyridine, N-vinyl pyrrolidone, or vinyl carbazole), N-vinyl formamide, N-vinyl acetamide, N-vinyl imidazole, vinyl caprolactone, can be also be used.

In addition to the above compounds, a vinyl monomer having a functional group, for example, a urethane group, a urea group, a sulfonamide group, a phenol group, or an imide group can also be used. Such a monomer having a urethane group or a urea group can be appropriately synthesized by using, for example, an addition reaction between an isocyanate group and a hydroxyl group or an amino group. Specifically, it can be appropriately synthesized by using an addition reaction between an isocyanate group-containing monomer and a compound containing one hydroxyl group or a compound containing a primary or secondary amino group or an addition reaction between a hydroxyl group-containing monomer or primary or secondary amino group-containing monomer and a monoisocyanate.

Examples of the vinyl monomer having an acidic group include a vinyl monomer having a carboxyl group and a vinyl monomer having a sulfo group.

Examples of the vinyl monomer having a carboxyl group include (meth)acrylic acid, vinylbenzoic acid, maleic acid, a maleic acid monoalkyl ester, fumaric acid, itaconic acid, crotonic acid, cinnamon acid, and an acrylic acid dimer. In addition, an addition reactant of a monomer having a hydroxyl group such as 2-hydroxyethyl (meth)acrylate and a cyclic anhydride such as maleic acid anhydride, phthalic acid anhydride, or cyclohexanedicarboxylic acid anhydride, ω-carboxy-polycaprolactone mono(meth)acrylate, or the like can also be used. Further, an anhydride-containing monomer such as maleic acid anhydride, itaconic acid anhydride, or citraconic acid anhydride may be used as a precursor of the carboxyl group. Among the above, (meth)acrylic acid is particularly preferable from the viewpoints of copolymerizability, cost, and solubility.

Examples of the vinyl monomer having a sulfo group include 2-acrylamide-2-methylpropanesulfonic acid, and examples of the vinyl monomer having —OPO(OH)₂ include monophosphate (2-acryloyloxyethyl ester) and monophosphate (1-methyl-2-acryloyloxyethyl ester).

Further, as the vinyl monomer having an acidic group, a vinyl monomer containing a phenolic hydroxyl group, a vinyl monomer containing a sulfonamide group, or the like can also be used.

Among the compounds represented by General Formula (X), a compound represented by General Formula (X-2) below is preferable.

(A²-R⁴—S—)ₙR³(—S—R⁵—P²)ₘ (X-2)

In General Formula (X-2), A² represents a monovalent organic group containing at least one moiety selected from an organic dye structure, a heterocyclic structure, an acidic group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxyl group. The n pieces of A² may be the same or different from each other.

It is noted that A² is synonymous with the above A¹ in General Formula (X), and the same applies to the preferred aspect thereof.

In General Formula (X-2), R⁴ and R⁵ each independently represent a single bond or a divalent organic linking group. n pieces of R⁴ may be the same or different from each other. In addition, m pieces of R⁵ may be the same or different from each other.

As the divalent organic linking group represented by R⁴ and R⁵, the same one as the divalent organic linking group represented by R² in General Formula (X) is used, and the same applies to the preferred aspect thereof.

In General Formula (X-2), R³ represents an (m+n)-valent organic linking group. m+n satisfies 3 to 10.

The (m+n)-valent organic linking group represented by R³ includes a group consisting of 1 to 60 carbon atoms, 0 to 10 nitrogen atoms, 0 to 50 oxygen atoms, 1 to 100 hydrogen atoms, and 0 to 20 sulfur atoms, which may be unsubstituted or may further have a substituent.

As the (m+n)-valent organic linking group represented by R³, specifically, the same one as the (m+n)-valent organic linking group represented by R¹ in General Formula (1) is used, and the same applies to the preferred aspect thereof.

In General Formula (X-2), m represents 1 to 8. m is preferably 1 to 5, more preferably 1 to 4, and still more preferably 1 to 3.

Further, in General Formula (X-2), n represents 2 to 9. n is preferably 2 to 8, more preferably 2 to 7, and still more preferably 3 to 6.

Further, P² in General Formula (X-2) represents a polymer skeleton, and it can be selected from known polymers and the like according to the purpose. m pieces of P² may be the same or different from each other. The preferred aspect of the polymer is the same as P¹ in General Formula (X).

Among the compounds represented by General Formula (X-2), the best compound is a compound in which all of R³, R⁴, R⁵, P², m, and n, which are shown below, are satisfied.

R³: The specific example (1), (2), (10), (11), (16), or (17) above described

R⁴: A single bond or a divalent organic linking group consisting of “1 to 10 carbon atoms, 0 to 5 nitrogen atoms, 0 to 10 oxygen atoms, 1 to 30 hydrogen atoms, and 0 to 5 sulfur atoms”, which is composed of a combination of the following structural units or the above structural units (which may have a substituent, where examples of the substituent include an alkyl group having 1 to 20 carbon atoms such as a methyl group and or an ethyl group, an aryl group having 6 to 16 carbon atoms such as phenyl group or naphthyl group, a hydroxyl group, an amino group, a carboxyl group, a sulfonamide group, N-sulfonylamide group, an acyloxy group having 1 to 6 carbon atoms such an acetoxy group, an alkoxy group having 1 to 6 carbon atoms such as a methoxy group or an ethoxy group, a halogen atom such as chlorine or bromine, an alkoxycarbonyl group having 2 to 7 carbon atoms such as a methoxycarbonyl group, an ethoxycarbonyl group, or a cyclohexyloxycarbonyl group, a cyano group, and a carbonic ester group such as t-butyl carbonate)

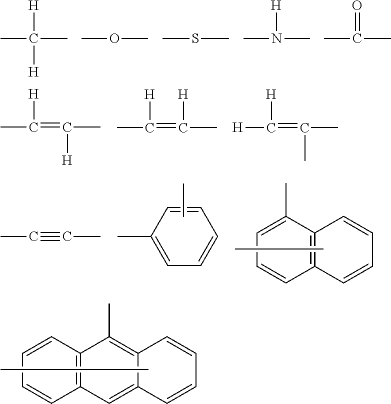

R⁵: A single bond, an ethylene group, a propylene group, the following group (a), or the following group (b)

In the following groups, R²⁵ represents a hydrogen atom or a methyl group, and l represents 1 or 2.

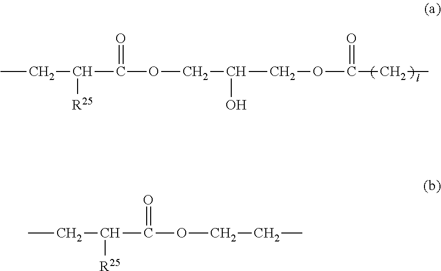

P²: A polymer or copolymer of a vinyl monomer, an ester-based polymer, an ether-based polymer, a urethane-based polymer, or a modified product thereof

m: 1 to 3

n: 3 to 6

Specific examples of the dispersing agent include “DA-7301” manufactured by Kusumoto Chemicals, Ltd., “Disperbyk-101 (polyamidoamine phosphate), 107 (carboxylic acid ester), 110 (copolymer containing an acid group), 111 (phosphoric acid-based dispersing agent), 130 (polyamide), 161, 162, 163, 164, 165, 166, 170, and 190 (polymeric copolymer)” and “BYK-P104 and P105 (high-molecular-weight unsaturated polycarboxylic acid)” manufactured by BYK Additives & Instruments, “EFKA 4047, 4050 to 4010 to 4165 (based on polyurethane), EFKA 4330 to 4340 (block copolymer), 4400 to 4402 (modified polyacrylate), 5010 (polyester amide), 5765 (high-molecular-weight polycarboxylate), 6220 (fatty acid polyester), 6745 (phthalocyanine derivative), and 6750 (azo pigment derivative)” manufactured by EFKA, “AJISPER PB821, PB822, PB880, and PB881” manufactured by Ajinomoto Fine-Techno Co., Inc., “FLOWLEN TG-710 (urethane oligomer)” and “POLYFLOW No. 50E and No. 300 (acrylic copolymer)” manufactured by KYOEISHA CHEMICAL Co., LTD., “DISPARLON KS-860, 873SN, 874, #2150 (aliphatic polyvalent carboxylic acid), #7004 (polyether ester), DA-703-50, DA-705, and DA-725” manufactured by Kusumoto Chemicals, Ltd., “DEMOL RN, N (naphthalenesulfonic acid-formalin polycondensate), MS, C, and SN-B (aromatic sulfonic acid-formalin polycondensate)”, “HOMOGENOL L-18 (polymeric polycarboxylic acid)”, “EMULGEN 920, 930, 935, and 985 (polyoxyethylene nonylphenyl ether)”, and “ACETAMIN 86 (stearylamine acetate)” manufactured by Kao Corporation, “SOLSPERSE 5000 (phthalocyanine derivative), 22000 (azo pigment derivative), 13240 (polyester amine), 3000, 12000, 17000, 20000, 27000 (polymer containing a functional portion on a terminal portion), 24000, 28000, 32000, and 38500 (graft copolymer)” manufactured by Lubrizol Japan Limited, “NIKKOL T106 (polyoxyethylene sorbitan monooleate), and MYS-IEX (polyoxyethylene monostearate)” manufactured by Nikko Chemicals Co., Ltd., HINOACT T-8000E and the like manufactured by Kawaken Fine Chemicals Co., Ltd., an organosiloxane polymer KP-341 manufactured by Shin-Etsu Chemical Co., Ltd., “W001: cationic surfactant”, nonionic surfactants such as polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and a sorbitan fatty acid ester, and anionic surfactants such as “W004, W005, and W017” manufactured by Yusho Co., Ltd., “EFKA-46, EFKA-47, EFKA-47EA, EFKA POLYMER 100, EFKA POLYMER 400, EFKA POLYMER 401, and EFKA POLYMER 450” manufactured by MORISHITA & CO., LTD., polymer dispersing agents such as “DISPERSE AID 6, DISPERSE AID 8, DISPERSE AID 15, and DISPERSE AID 9100” manufactured by SAN NOPCO LIMITED, “ADEKA PLURONIC L31, F38, L42, L44, L61, L64, F68, L72, P95, F77, P84, F87, P94, L101, P103, F108, L121, and P-123” manufactured by ADEKA CORPORATION, and “IONET (product name) S-20” manufactured by Sanyo Chemical Industries, Ltd. In addition, ACRYBASE FFS-6752 and ACRYBASE FFS-187 can also be used.

In addition, it is also preferable that an amphoteric resin containing an acid group and a basic group is used. The amphoteric resin is preferably a resin having an acid value of 5 mgKOH/g or more and an amine value of 5 mgKOH/g or more (more preferably, a resin having an acid value of 5 to 100 mgKOH/g and an amine value of 5 to 100 mgKOH/g).

Examples of the commercially available product of the amphoteric resin include DISPERBYK-130, DISPERBYK-140, DISPERBYK-142, DISPERBYK-145, DISPERBYK-180, DISPERBYK-187, DISPERBYK-191, DISPERBYK-2001, DISPERBYK-2010, DISPERBYK-2012, DISPERBYK-2025, and BYK-9076 manufactured by BYK Additives & Instruments, and AJISPER PB821, AJISPER PB822, and AJISPER PB881 manufactured by Ajinomoto Fine-Techno Co., Inc.

These dispersing agents may be used alone, or two or more kinds thereof may be used in combination.

Regarding the dispersing agent, reference can be made to, for example, the dispersing agents described in paragraphs 0127 to 0129 in JP2013-249417A, the content of which is incorporated into the present specification.

In addition, as the dispersing agent, for example, in addition to the above-described dispersing agents, the graft copolymer described in paragraphs 0037 to 0115 of JP2010-106268A (corresponding to paragraphs 0075 to 0133 of US2011/0124824A) can be used, the contents of which can be incorporated by reference into the present specification.

In addition, in addition to the above-described dispersing agent, the dispersing agent, which is described in paragraphs 0028 to 0084 of JP2011-153283A (corresponding to paragraphs 0064 to 0122 of US2011/0279759A) and contains a constitutional component having a side chain structure formed by bonding of acidic groups through a linking group, can be used, the contents of which can be incorporated by reference into the present specification.

Physical Properties of Dispersing Agent

An acid value of the dispersing agent is preferably 5 to 250 mg KOH/g, more preferably 10 to 225 mg KOH/g, still more preferably 30 to 200 mg KOH/g, and particularly preferably in a range of 35 to 200 mg KOH/g.

In a case where the acid value of the dispersing agent is 250 mg KOH/g or less, the pattern peeling during development in a case of forming a light shielding film is more effectively suppressed. In addition, in a case where the acid value of the dispersing agent is 5 mg KOH/g or more, the alkali developability is improved. In addition, in a case where the acid value of the dispersing agent is 10 mg KOH/g or more, the sedimentation of the pigment or the like can be further suppressed, the number of coarse particles can be further reduced, and the temporal stability of the composition can be further improved.

It is also preferable that the acid value of the dispersing agent is within the above range and the dispersing agent has substantially no amine value (for example, the amine value is 0 mgKOH/g or more and less than 5 mgKOH/g).

In a case where the dispersing agent has substantially no acid value (for example, in a case where the acid value is 0 mgKOH/g or more and less than 5 mgKOH/g), the amine value of the dispersing agent is preferably 5 to 250 mgKOH/g, more preferably 10 to 200 mgKOH/g, and still more preferably 30 to 100 mgKOH/g.

The weight-average molecular weight of the dispersing agent is preferably 4,000 to 300,000, more preferably 5,000 to 200,000, still more preferably 6,000 to 100,000, and particularly preferably 10,000 to 50,000.

The dispersing agent can be synthesized based on a known method.

<Alkali-Soluble Resin>

The composition preferably contains an alkali-soluble resin. In the present specification, the alkali-soluble resin refers to a resin containing a group (an alkali-soluble group, for example, an acid group such as a carboxyl group) which promotes alkali solubility, and refers to a resin different from the dispersing agent described above.

For example, it is preferable that the alkali-soluble resin substantially does not contain a structural unit containing a graft chain (typically, a structural unit represented by any one of Formulae (1) to (4), and more typically, a structural unit (1) in which n is an integer of 6 or more in Formula (2) or a structural unit in which m is an integer of 6 or more in Formula (2). The above-described “substantially does not contain” is intended to mean that the content of the structural unit containing the graft chain is 0% to 2% by mass with respect to all the repeating units of the alkali-soluble resin. Further, for example, it is also preferable that the alkali-soluble resin is not the radial polymer compound described above.

The content of the alkali-soluble resin in the composition is not particularly limited; however, it is preferably 0.1% to 30% by mass, more preferably 0.5% to 25% by mass, and still more preferably 1% to 20% by mass, with respect to the total solid content of the composition.

The alkali-soluble resin may be used alone or in a combination of two or more thereof. In a case where two or more alkali-soluble resins are used in combination, the total content thereof is preferably within the above range.

As the alkali-soluble resin, for example, a resin containing at least one alkali-soluble group in a molecule is mentioned, and examples thereof include a polyhydroxystyrene resin, a polysiloxane resin, a (meth)acrylic resin, a (meth)acrylamide resin, a (meth)acryl/(meth)acrylamide copolymer resin, an epoxy-based resin, and a polyimide resin.

Examples of the alkali-soluble resin include a copolymer of unsaturated carboxylic acid and an ethylenically unsaturated compound.

Examples of the unsaturated carboxylic acid include monocarboxylic acids such as (meth)acrylic acid, crotonic acid, and vinyl acetate; dicarboxylic acid such as itaconic acid, maleic acid, and fumaric acid or an acid anhydride thereof; and polyvalent carboxylic acid monoesters such as mono(2-(meth)acryloyloxyethyl)phthalate.

Examples of the copolymerizable ethylenically unsaturated compound include methyl (meth)acrylate. In addition, the compounds described in paragraph 0027 of JP2010-97210A and paragraphs 0036 and 0037 of JP2015-68893A can also be used, the content of which is incorporated into the present specification.

In addition, a copolymerizable ethylenically unsaturated compound containing an ethylenic unsaturated group in the side chain may be used in combination. The ethylenic unsaturated group is preferably a (meth)acrylic acid group. The acrylic resin containing an ethylenic unsaturated group in the side chain can be obtained, for example, by addition-reacting a carboxyl group of an acrylic resin containing the carboxyl group with an ethylenically unsaturated compound containing a glycidyl group or an alicyclic epoxy group.

As the alkali-soluble resin, an alkali-soluble resin containing a curable group is also preferable.

As the curable group, for example, the curable groups, which may be contained in the above-described dispersing agent, are similarly mentioned, and preferred ranges are also the same.

The alkali-soluble resin containing a curable group is preferably an alkali-soluble resin having a curable group in the side chain, or the like. Examples of the alkali-soluble resin containing a curable group include DIANAL NR series (manufactured by Mitsubishi Rayon Co., Ltd.), Photomer 6173 (COOH-containing polyurethane acrylic oligomer, manufactured by Diamond Shamrock Co., Ltd.), VISCOAT R-264 and KS resist 106 (all manufactured by OSAKA ORGANIC CHEMICAL INDUSTRY LTD.), CYCLOMER P series (for example, ACA230AA) and PLACCEL CF200 series (all manufactured by DAICEL CORPORATION), Ebecryl 3800 (manufactured by DAICEL-ALLNEX LTD.), and ACRYCURE RD-F8 (manufactured by NIPPON SHOKUBAI CO., LTD.).

As the alkali-soluble resin, for example, the radical polymers which contain a carboxyl group in the side chain and are described in JP1984-44615A (JP-S59-44615A), JP1979-34327B (JP-S54-34327B), JP1983-12577B (JP-S58-12577B), JP1979-25957B (JP-S54-25957B), JP1979-92723A (JP-S54-92723A), JP1984-53836A (JP-S59-53836A), and JP1984-71048A (JP-S59-71048A); the acetal-modified polyvinyl alcohol-based binder resins which contain an alkali-soluble group and are described in EP993966B, EP1204000B, and JP2001-318463A; polyvinylpyrrolidone; polyethylene oxide; polyether or the like which is a reactant of alcohol-soluble nylon, 2,2-bis-(4-hydroxyphenyl)-propane, and epichlorohydrin; the polyimide resin described in WO2008/123097A; and the like can be used.

As the alkali-soluble resin, for example, the compound described in paragraphs 0225 to 0245 of JP2016-75845A can also be used, the content of which is incorporated into the present specification.

As the alkali-soluble resin, for example, a polyimide precursor can also be used. The polyimide precursor refers to a resin obtained by causing an addition polymerization reaction between a compound containing an acid anhydride group and a diamine compound at a temperature of 40° C. to 100° C.

Examples of the polyimide precursor include a resin containing a repeating unit represented by Formula (1). Examples of the structure of the polyimide precursor include polyimide precursors containing an amic acid structure represented by Formula (2), and imide structures represented by Formula (3) obtained in a case where imide ring closure occurs in a portion of an amic acid structure and Formula (4) obtained in a case where imide ring closure occurs in the entirety of an amic acid structure.

It is noted that in the present specification, the polyimide precursor having an amic acid structure is referred to as polyamic acid in some cases.

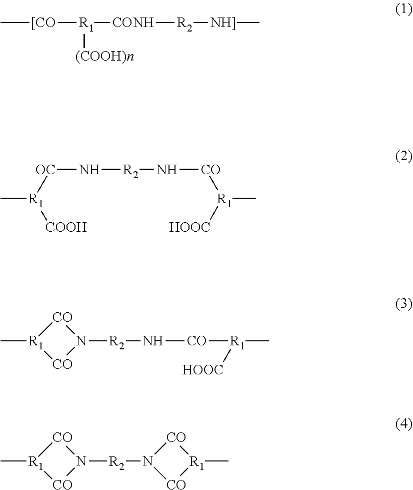

In Formula (1), n represents 1 or 2, R₁ in a case where n is 1 represents a trivalent organic group having 2 to 22 carbon atoms, and R₁ in a case where n is 2 represents a tetravalent organic group having 2 to 22 carbon atoms.

In Formulae (2) to (4), R₁ represents a trivalent organic group having 2 to 22 carbon atoms.

In Formulae (1) to (4), R₂ represents a divalent organic group having 1 to 22 carbon atoms.

Specific examples of the polyimide precursor include the compound described in paragraphs 0011 to 0031 of JP2008-106250A, the compound described in paragraphs 0022 to 0039 of JP2016-122101A, and the compound described in paragraphs 0061 to 0092 of JP2016-68401A, the contents of which are incorporated into the present specification.

From the viewpoint that a pattern shape of a patterned light shielding film formed from the composition is more excellent, it is also preferable that the alkali-soluble resin includes at least one selected from the group consisting of a polyimide resin and a polyimide precursor.

As the polyimide resin containing the alkali-soluble group, for example, a known polyimide resin containing an alkali-soluble group can be used. Examples of the polyimide resin include the resins described in paragraph 0050 of JP2014-137523A, the resins described in paragraph 0058 of JP2015-187676A, and the resins described in paragraphs 0012 and 0013 of JP2014-106326A, the contents of which are incorporated into the present specification.

As the alkali-soluble resin, a copolymer of [benzyl (meth)acrylate/(meth)acrylic acid/another addition polymerizable vinyl monomer, as necessary], and a copolymer of [allyl (meth)acrylate/(meth)acrylic acid/another addition polymerizable vinyl monomer, as necessary] are suitable because the copolymers have an excellent balance among film hardness, sensitivity, and developability.

The other addition polymerizable vinyl monomer may be one kind or two or more kinds.

The copolymer preferably has a curable group and more preferably contains an ethylenic unsaturated group such as a (meth)acryloyl group, from the viewpoint that the moisture resistance of the light shielding film is more excellent.

For example, a curable group may be introduced into a copolymer by using a monomer having the curable group as the other addition polymerizable vinyl monomer. In addition, a curable group (preferably, an ethylenic unsaturated group such as a (meth)acryloyl group) may be introduced into a part or all of one or more units derived from (meth)acrylic acid in the copolymer and/or units derived from the other addition polymerizable vinyl monomer.

Examples of the other addition polymerizable vinyl monomer include methyl (meth)acrylate, a styrene-based monomer (hydroxystyrene or the like), and an ether dimer.

Examples of the ether dimer include a compound represented by General Formula (ED1) and a compound represented by General Formula (ED2).

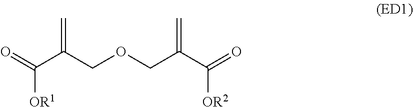

In General Formula (ED1), R¹ and R² each independently represent a hydrogen atom or a hydrocarbon group having 1 to 25 carbon atoms.

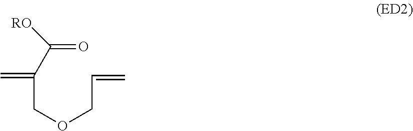

In General Formula (ED2), R represents a hydrogen atom or an organic group having 1 to 30 carbon atoms. Regarding specific examples of General Formula (ED2), reference can be made to, for example, the description of JP2010-168539A.

As the specific examples of the ether dimer, reference can be made to, for example, paragraph 0317 of JP2013-29760A, the content of which is incorporated into the present specification. The ether dimer may be one kind or two or more kinds.

It is also preferable that the alkali-soluble resin is a cardo resin.

The weight-average molecular weight of the alkali-soluble resin is preferably 4,000 to 300,000 and more preferably 5,000 to 200,000.

The acid value of the alkali-soluble resin is preferably 30 to 500 mg KOH/g and more preferably 50 to 200 mg KOH/g.

[Polymerizable Compound]

The composition according to the embodiment of the present invention contains a polymerizable compound.

In the present specification, the polymerizable compound is a compound which is polymerized by the action of the polymerization initiator, which will be described later, and it is a component different from the dispersing agent and the alkali-soluble resin, which will be described later.

In addition, the polymerizable compound is a component different from the epoxy group-containing compound which will be described later.

The content of the polymerizable compound in the composition is not particularly limited; however, it is preferably 1% to 35% by mass, more preferably 4% to 25% by mass, and still more preferably 8% to 20% by mass, with respect to the total solid content of the composition. One kind of polymerizable compound may be used alone, or two or more kinds thereof may be used. In a case where two or more polymerizable compounds are used, the total content thereof is preferably within the above range.

The polymerizable compound is preferably a low-molecular-weight compound. The low-molecular-weight compound referred to here is preferably a compound having a molecular weight of 3,000 or less.

The polymerizable compound is preferably a compound containing an ethylenic unsaturated group.

That is, the composition according to the embodiment of the present invention preferably contains, as a polymerizable compound, a low-molecular-weight compound containing an ethylenic unsaturated group.

The polymerizable compound is preferably a compound containing one or more ethylenically unsaturated bonds, more preferably a compound containing two or more ethylenically unsaturated bonds, still more preferably a compound containing three or more ethylenically unsaturated bonds, and particularly preferably a compound containing five or more ethylenically unsaturated bonds. The upper limit thereof is, for example, 15 or less. Examples of the ethylenic unsaturated group include a vinyl group, an allyl group, and a (meth)acryloyl group.

As the polymerizable compound, for example, the compounds described in paragraph 0050 of JP2008-260927A and paragraph 0040 of JP2015-68893A can be used, the contents of which are incorporated into the present specification.

The polymerizable compound may have any chemical form such as a monomer, a prepolymer, an oligomer, a mixture thereof, or a multimer thereof.

The polymerizable compound is preferably a (meth)acrylate compound having 3 to 15 functional groups and more preferably a (meth)acrylate compound having 3 to 6 functional groups.

As the polymerizable compound, a compound which contains one or more ethylenic unsaturated groups and has a boiling point of 100° C. higher under normal pressure is also preferable. Reference can be made to, for example, the compounds described in paragraph 0227 of JP2013-29760A and paragraphs 0254 to 0257 of JP2008-292970A, the contents of which are incorporated into the present specification.

The polymerizable compound is preferably the following compound: dipentaerythritol triacrylate (as a commercially available product, KAYARAD D-330; manufactured by Nippon Kayaku Co., Ltd.), dipentaerythritol tetraacrylate (as a commercially available product, KAYARAD D-320; manufactured by Nippon Kayaku Co., Ltd.), dipentaerythritol penta(meth)acrylate (as a commercially available product, KAYARAD D-310; manufactured by Nippon Kayaku Co., Ltd.), dipentaerythritol hexa(meth)acrylate (as commercially available products, KAYARAD DPHA; manufactured by Nippon Kayaku Co., Ltd., A-DPH-12E; manufactured by SHIN-NAKAMURA CHEMICAL Co., Ltd.), or a structure (for example, SR454 or SR499, which is commercially available from Sartomer Company Inc.) in which a (meth)acryloyl group of the above compound is bonded through an ethylene glycol residue or a propylene glycol residue. Oligomer types thereof can also be used. In addition, NK ESTER A-TMMT (pentaerythritol tetraacrylate, manufactured by SHIN-NAKAMURA CHEMICAL Co., Ltd.), KAYARAD RP-1040, KAYARAD DPEA-12LT, KAYARAD DPHA LT, KAYARAD RP-3060, and KAYARAD DPEA-12, KAYARAD DPCA-20 (manufactured by Nippon Kayaku Co., Ltd.), ARONIX M-305, ARONIX M-510 (manufactured by Toagosei Co., Ltd.), VISCOAT #802 (manufactured by OSAKA ORGANIC CHEMICAL INDUSTRY LTD.), or the like may be used.

The preferred aspects of the polymerizable compound are shown below.

The polymerizable compound may have an acid group such as a carboxyl group, a sulfo group, or —OPO(OH)₂. The polymerizable compound containing an acid group is preferably an ester of an aliphatic polyhydroxy compound and an unsaturated carboxylic acid, more preferably a polymerizable compound having an acid group by reacting a nonaromatic carboxylic acid anhydride with an unreacted hydroxyl group of an aliphatic polyhydroxy compound, and still more preferably a compound in which the aliphatic polyhydroxy compound in the ester is pentaerythritol and/or dipentaerythritol. Examples of the commercially available product thereof include ARONIX TO-2349, M-305, M-510, and M-520 manufactured by TOAGOSEI CO., LTD.

It is also preferable that the polymerizable compound does not contain an acid group.

The content of the polymerizable compound containing no acid group is preferably 10% to 100% by mass, more preferably 50% to 100% by mass, and still more preferably 75% to 100% by mass, with respect to the total mass of the polymerizable compound.

The acid value of the polymerizable compound containing an acid group is preferably 0.1 to 40 mg KOH/g and more preferably 5 to 30 mg KOH/g. In a case where the acid value of the polymerizable compound is 0.1 mg KOH/g or more, development dissolution characteristics are favorable, and in a case where the acid value is 40 mg KOH/g or less, the polymerizable compound is advantageous in terms of production and/or handling. Further, a photopolymerization performance is favorable, and curing properties are excellent.

As the polymerizable compound, a compound having a caprolactone structure is also a preferred aspect.

The compound having a caprolactone structure is not particularly limited as long as the compound has a caprolactone structure in a molecule; however, examples thereof include ε-caprolactone-modified polyfunctional (meth)acrylate which is obtained by esterifying polyhydric alcohol such as trimethylolethane, ditrimethylolethane, trimethylolpropane, ditrimethylolpropane, pentaerythritol, dipentaerythritol, tripentaerythritol, glycerin, diglycerol, and trimethylol melamine, (meth)acrylic acid, and ε-caprolactone. Among them, a compound which has a caprolactone structure and is represented by Formula (Z-1) is preferable.

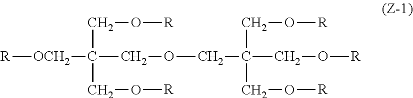

In Formula (Z-1), all six R's are groups represented by Formula (Z-2), or one to five among the six R's are groups represented by Formula (Z-2) and the others are groups represented by Formula (Z-3).

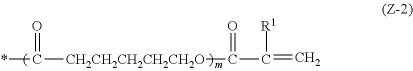

In Formula (Z-2), R¹ represents a hydrogen atom or a methyl group, m represents the number of 1 or 2, and “*” represents a bonding site.

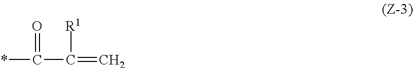

In Formula (Z-3), R¹ represents a hydrogen atom or a methyl group, and “*” represents a bonding site.

The polymerizable compound having a caprolactone structure is commercially available, for example, as KAYARAD DPCA series from Nippon Kayaku Co., Ltd., and examples thereof include DPCA-20 (a compound in which, in Formulae (Z-1) to (Z-3), m is 1, the number of groups represented by Formula (Z-2) is 2, and all of R¹'s represent hydrogen atoms), DPCA-30 (a compound in which, in Formulae (Z-1) to (Z-3), m is 1, the number of groups represented by Formula (Z-2) is 3, and all of R¹'s represent hydrogen atoms), DPCA-60 (a compound in which, in Formulae (Z-1) to (Z-3), m is 1, the number of groups represented by Formula (Z-2) is 6, and all of R¹'s represent hydrogen atoms), and DPCA-120 (a compound in which, in Formulae (Z-1) to (Z-3), m is 2, the number of groups represented by Formula (Z-2) is 6, and all of R¹'s represent hydrogen atoms).

As the polymerizable compound, a compound represented by Formula (Z-6) can also be used.

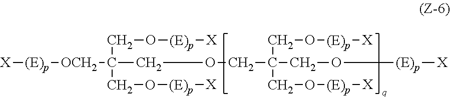

In Formula (Z-6), E's each independently represent —(CH₂)_{y}—CH₂—O—, —(CH₂)_{y}—CH(CH₃)—O—, —(CH₂)_{y}—CH₂—CO—O—, —(CH₂)_{y}—CH(CH₃)—CO—O—, —CO—(CH₂)_{y}—CH₂—O—, —CO—(CH₂)_{y}—CH(CH₃)—O—, —CO—(CH₂)_{y}—CH₂—CO—O—, or —CO—(CH₂)_{y}—CH(CH₃)—CO—O—. In these groups, the bonding position on the right side is preferably a bonding position on the X side.

y's each independently represent an integer of 1 to 10.

X's each independently represent a (meth)acryloyl group or a hydrogen atom.

p's each independently represent an integer of 0 to 10.

q represents an integer 0 to 3.

In Formula (Z-6), the total number of (meth)acryloyl groups is preferably (3+2q) or (4+2q).

p is preferably an integer of 0 to 6 and more preferably an integer of 0 to 4.

The total of each p is preferably 0 to (40+20q), more preferably 0 to (16+8q), and still more preferably 0 to (12+6q).

The compound represented by Formula (Z-6) may be used alone, or two or more kinds thereof may be used.

In addition, the total content of the compound represented by Formula (Z-6) in the polymerizable compound is preferably 20% to 100% by mass, more preferably 50% to 100% by mass, and still more preferably 80% to 100% by mass.

Among the compounds represented by Formula (Z-6), a pentaerythritol derivative, a dipentaerythritol derivative, a tripentaerythritol derivative, and/or a tetrapentaerythritol derivative is more preferable.

In addition, the polymerizable compound may have a cardo skeleton.

The polymerizable compound having a cardo skeleton is preferably a polymerizable compound having a 9,9-bisarylfluorene skeleton.

The polymerizable compound having a cardo skeleton is not limited; however, examples thereof include ONCOAT EX series (manufactured by NAGASE & CO., LTD.), and OGSOL (manufactured by Osaka Gas Chemicals Co., Ltd.).

As the polymerizable compound, a compound having an isocyanuric acid skeleton as a core is also preferable. Examples of such a polymerizable compound include NK ESTER A-9300 (manufactured by SHIN-NAKAMURA CHEMICAL Co., Ltd.).

The content (that is intended to indicate a value obtained by dividing the number of ethylenic unsaturated groups in the polymerizable compound by the molecular weight (g/mol) of the polymerizable compound) of the ethylenic unsaturated group in the polymerizable compound is preferably 5.0 mmol/g or more. The upper limit thereof is not particularly limited; however, it is generally 20.0 mmol/g or less.

It is noted that in a case where the composition contains a plurality of polymerizable compounds and double bond equivalents of the respective polymerizable compounds are not the same, a value obtained by summing up products of mass ratios of the respective polymerizable compounds in all the polymerizable compounds and double bond equivalents of the respective polymerizable compounds is preferably within the above range.

[Photopolymerization Initiator]

The composition contains a photopolymerization initiator.

The photopolymerization initiator is not particularly limited as long as the photopolymerization initiator can initiate the polymerization of the polymerizable compound, and a known photopolymerization initiator can be used. The photopolymerization initiator is preferably, for example, a photopolymerization initiator that exhibits photosensitivity to ranges from an ultraviolet range to a visible light range. In addition, the photopolymerization initiator may be an activator which generates active radicals by causing a certain action with a photoexcited sensitizer, or an initiator which initiates cationic polymerization according to the type of the polymerizable compound.

In addition, the photopolymerization initiator is preferably a compound having a molar absorption coefficient of at least 50 (l·mol⁻¹·cm⁻¹) within a range of 300 to 800 nm (more preferably 330 to 500 nm).

The content of the photopolymerization initiator in the composition is preferably 0.5% to 20% by mass, more preferably 1.0% to 10% by mass, and still more preferably 1.5% to 8% by mass, with respect to the total solid content of the composition.

The photopolymerization initiator may be used alone or in a combination of two or more thereof. In a case where two or more photopolymerization initiators are used in combination, the total content thereof is preferably within the above range.

Examples of the photopolymerization initiator include a halogenated hydrocarbon derivative (for example, a compound having a triazine skeleton, a compound having an oxadiazole skeleton, or the like), an acyl phosphine compound such as acyl phosphine oxide, hexaaryl biimidazole, an oxime compound such as an oxime derivative, an organic peroxide, a thio compound, a ketone compound, an aromatic onium salt, an aminoacetophenone compound, and hydroxyacetophenone.

As the photopolymerization initiator, reference can be made to, for example, paragraphs 0265 to 0268 of JP2013-29760A, the content of which is incorporated into the present specification.

As the photopolymerization initiator, for example, the aminoacetophenone-based initiator described in JP1998-291969A (JP-H10-291969A) and the acyl phosphine oxide-based initiator described in JP4225898B can also be used.

As the hydroxyacetophenone compound, for example, Omnirad 184, Omnirad 1173, Omnirad 500, Omnirad 2959, and Omnirad 127 (product names, all manufactured by IGM Resins B.V.) can be used. These products correspond to IRGACURE 184, IRGACURE 1173, IRGACURE 500, IRGACURE 2959, and IRGACURE 127 (former product name, formerly manufactured by BASF SE), respectively.

As the aminoacetophenone compound, for example, Omnirad 907, Omnirad 369, and Omnirad 379EG (product names, all manufactured by IGM Resins B.V), which are commercially available products, can be used. These products correspond to IRGACURE 907, IRGACURE 369, and IRGACURE 379EG (former product name, formerly manufactured by BASF SE), respectively.

As the aminoacetophenone compound, for example, the compound which is described in JP2009-191179A and of which absorption wavelength is matched to a light source having a long wavelength such as a wavelength of 365 nm or a wavelength of 405 nm can also be used.

As the acyl phosphine compound, for example, Omnirad 819 and Omnirad TPO H (product names, all manufactured by IGM Resins B.V), which are commercially available products, can be used. These products correspond to IRGACURE 819 and IRGACURE TPO (former product name, formerly manufactured by BASF SE), respectively.

(Oxime Compound)

As the photopolymerization initiator, an oxime ester-based polymerization initiator (an oxime compound) is more preferable. In particular, the oxime compound is preferable since it has high sensitivity and high polymerization efficiency and the content of the coloring material in the composition is easily designed to be high.

The content of the oxime compound is preferably 10% to 100% by mass, more preferably 40% to 100% by mass and still more preferably 80% to 100% by mass, with respect to the total mass of the polymerization initiator.

As the oxime compound, for example, the compound described in JP2001-233842A, the compound described in JP2000-80068A, or the compound described in JP2006-342166A can be used.

Examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

In addition, the compounds described in J. C. S. Perkin II (1979) pp. 1653 to 1660, J. C. S. Perkin II (1979) pp. 156 to 162, Journal of Photopolymer Science and Technology (1995) pp. 202 to 232, JP2000-66385A, JP2000-80068A, JP2004-534797A, and JP2006-342166A, and the like are also mentioned.

Among commercially available products thereof, IRGACURE-OXE01 (manufactured by BASF SE), IRGACURE-OXE02 (manufactured by BASF SE), IRGACURE-OXE03 (manufactured by BASF SE), or IRGACURE-OXE04 (manufactured by BASF SE) is also preferable. In addition, TR-PBG-304 (manufactured by TRONLY), ADEKA ARKLS NCI-831, and ADEKA ARKLS NCI-930 (manufactured by ADEKA CORPORATION), or N-1919 (carbazole and oxime ester skeleton-containing photoinitiator (manufactured by ADEKA CORPORATION)) can also be used.

In addition, as oxime compounds other than the above-described oxime compounds, the compound which is described in JP2009-519904A and in which oxime is linked to an N-position of carbazole; the compound which is described in U.S. Pat. No. 7,626,957B and in which a hetero substituent is introduced into a benzophenone moiety; the compounds which are described in JP2010-15025A and US2009/292039A and in which a nitro group is introduced into the dye moiety; the ketoxime compound described in WO2009/131189A; the compound which is described in U.S. Pat. No. 7,556,910B and contains a triazine skeleton and an oxime skeleton in the same molecule; the compound which is described in JP2009-221114A, has maximal absorption wavelength at 405 nm, and exhibits favorable sensitivity with respect to a light source of a g-line; and the like may be used.

Reference can be made to, for example, paragraphs 0274 and 0275 of JP2013-29760A, the content of which is incorporated into the present specification.

Specifically, the oxime compound is preferably a compound represented by Formula (OX-1). It is noted that an N—O bond in the oxime compound may be an (E) isomer, a (Z) isomer, or a mixture of an (E) isomer and a (Z) isomer.

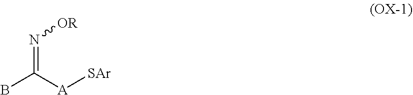

In Formula (OX-1), R and B each independently represent a monovalent substituent, A represents a divalent organic group, and Ar represents an aryl group.

In Formula (OX-1), the monovalent substituent represented by R is preferably a group of monovalent non-metal atoms.

Examples of the group of monovalent non-metal atoms include an alkyl group, an aryl group, an acyl group, an alkoxycarbonyl group, an aryloxycarbonyl group, a heterocyclic group, an alkylthiocarbonyl group, and an arylthiocarbonyl group. In addition, these groups may have one or more substituents. In addition, each of the substituents may be further substituted with another substituent.

Examples of the substituent include a halogen atom, an aryloxy group, an alkoxycarbonyl group or an aryloxycarbonyl group, an acyloxy group, an acyl group, an alkyl group, and an aryl group.

The monovalent substituent represented by B in Formula (OX-1) is preferably an aryl group, a heterocyclic group, an arylcarbonyl group, or a heterocyclic carbonyl group, and more preferably an aryl group or a heterocyclic group. These groups may have one or more substituents. Examples of the substituent include the above-described substituents.

The divalent organic group represented by A in Formula (OX-1) is preferably an alkylene group having 1 to 12 carbon atoms, a cycloalkylene group, or an alkynylene group. These groups may have one or more substituents. Examples of the substituent include the above-described substituents.

As the photopolymerization initiator, a fluorine atom-containing oxime compound can also be used. Specific examples of the fluorine atom-containing oxime compound include the compound described in JP2010-262028A; the compounds 24 and 36 to 40 described in JP2014-500852A; and the compound (C-3) described in JP2013-164471A. The contents thereof are incorporated into the present specification.

As the photopolymerization initiator, compounds represented by General Formulae (1) to (4) can also be used.

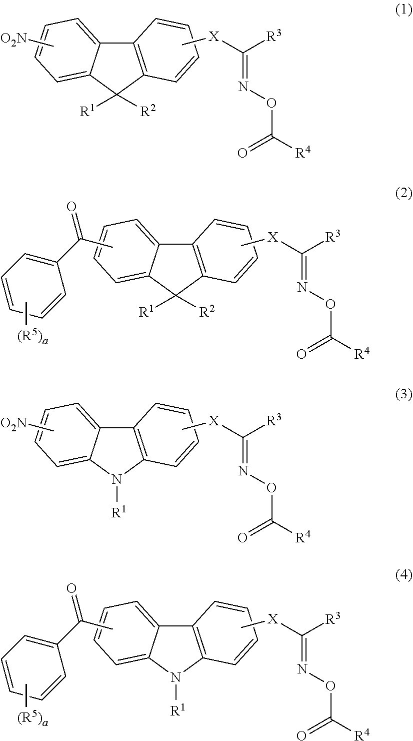

In Formula (1), R¹ and R² each independently represent an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms, in a case where R¹ and R² are phenyl groups, the phenyl groups may be bonded to each other to form a fluorene group, R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a direct bond or a carbonyl group.

In Formula (2), R¹, R², R³, and R⁴ are respectively synonymous with R¹, R², R³, and R⁴ in Formula (1), R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a direct bond or a carbonyl group, and a represents an integer of 0 to 4.

In Formula (3), R¹ represents an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms. R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a direct bond or a carbonyl group.

In Formula (4), R¹, R³, and R⁴ are respectively synonymous with R¹, R³, and R⁴ in Formula (3), R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a direct bond or a carbonyl group, and a represents an integer of 0 to 4.

In Formulae (1) and (2), R¹ and R² are preferably a methyl group, an ethyl group, an n-propyl group, an i-propyl group, a cyclohexyl group, or a phenyl group. R³ is preferably a methyl group, an ethyl group, a phenyl group, a tolyl group, or a xylyl group. R⁴ is preferably an alkyl group having 1 to 6 carbon atoms or a phenyl group. R⁵ is preferably a methyl group, an ethyl group, a phenyl group, a tolyl group, or a naphthyl group. X is preferably a direct bond.

In addition, in Formulae (3) and (4), R¹ is preferably a methyl group, an ethyl group, an n-propyl group, an i-propyl group, a cyclohexyl group, or a phenyl group. R³ is preferably a methyl group, an ethyl group, a phenyl group, a tolyl group, or a xylyl group. R⁴ is preferably an alkyl group having 1 to 6 carbon atoms or a phenyl group. R⁵ is preferably a methyl group, an ethyl group, a phenyl group, a tolyl group, or a naphthyl group. X is preferably a direct bond.

Specific examples of the compounds represented by Formula (1) and Formula (2) include the compound described in paragraphs 0076 to 0079 of JP2014-137466A. The contents thereof are incorporated into the present specification.

Specific examples of an oxime compound preferably used in the composition are shown below. Among the oxime compounds shown below, an oxime compound represented by General Formula (C-13) is more preferable.

In addition, as the oxime compound, for example, the compounds described in Table 1 of WO2015/036910A can also be used, the content of which is incorporated into the present specification.

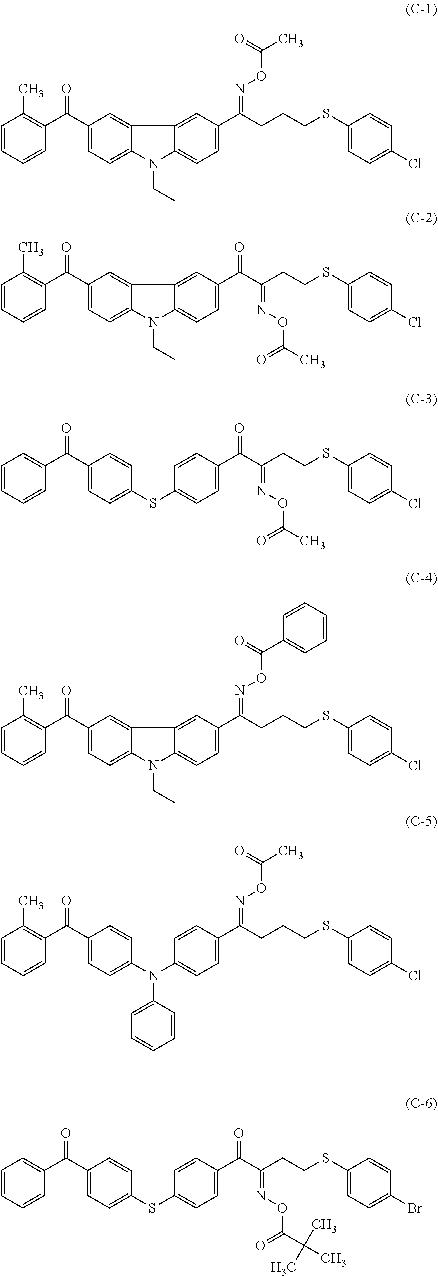 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

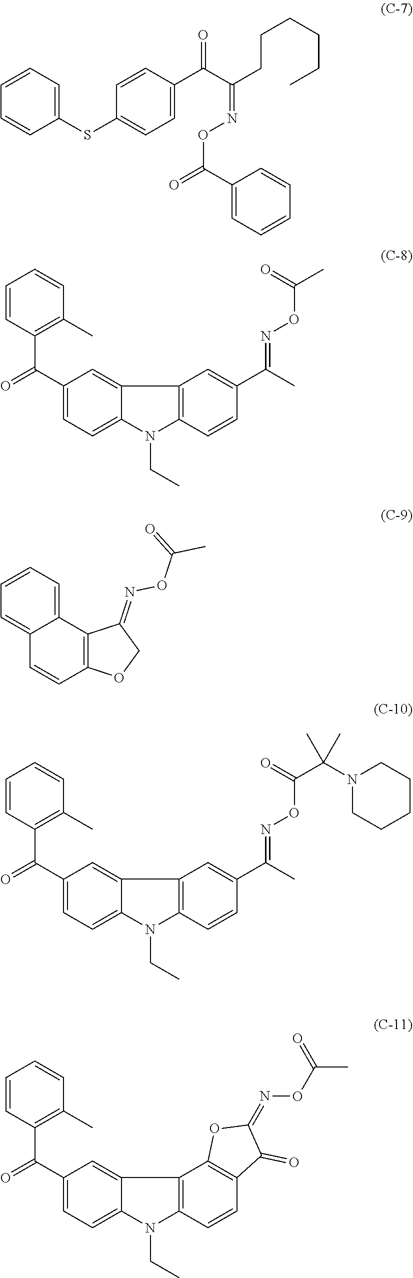

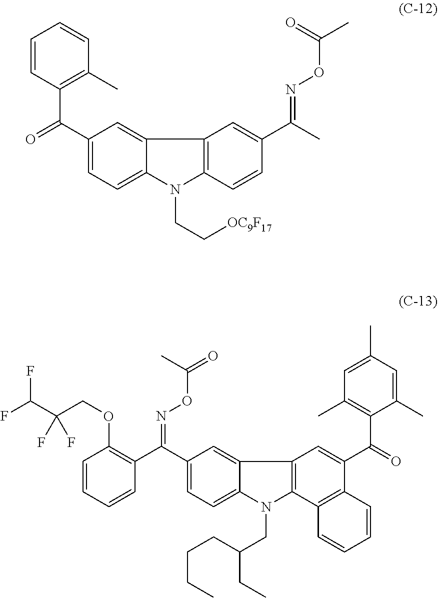

The oxime compound preferably has a maximal absorption wavelength in a wavelength range of 350 to 500 nm, more preferably has a maximal absorption wavelength in a wavelength range of 360 to 480 nm, and still more preferably has a high absorbance at wavelengths of 365 nm and 405 nm.

From the viewpoint of sensitivity, a molar absorption coefficient of the oxime compound at 365 nm or 405 nm is preferably 1,000 to 300,000, more preferably 2,000 to 300,000, and still more preferably 5,000 to 200,000.

The molar absorption coefficient of the compound can be measured by a known method; however, for example, it is preferable that the measurement is carried out with an ultraviolet and visible spectrophotometer (a Cary-5 spectrophotometer manufactured by Varian, Inc.) at a concentration of 0.01 g/L using ethyl acetate.

Two or more photopolymerization initiators may be used in combination, as necessary.

In addition, as the photopolymerization initiator, for example, the compounds described in paragraph 0052 of JP2008-260927A, paragraphs 0033 to 0037 of JP2010-97210A, and paragraph 0044 of JP2015-68893A can also be used, the contents of which are incorporated into the present specification.

[Polymerization Inhibitor]

The composition may contain a polymerization inhibitor.

As the polymerization inhibitor, for example, a known polymerization inhibitor can be used. Examples of the polymerization inhibitor include a phenolic polymerization inhibitor (for example, p-methoxyphenol, 2,5-di-tert-butyl-4-methylphenol, 2,6-di-tert-butyl-4-methylphenol, 4,4′-thiobis(3-methyl-6-t-butylphenol), 2,2′-methylenebis(4-methyl-6-t-butylphenol), 4-methoxynaphthol, and the like); a hydroquinone-based polymerization inhibitor (for example, hydroquinone, 2,6-di-tert-butylhydroquinone, and the like); a quinone-based polymerization inhibitor (for example, benzoquinone and the like); a free radical-based polymerization inhibitor (for example, 2,2,6,6-tetramethylpiperidine 1-oxyl free radical, 4-hydroxy-2,2,6,6-tetramethylpiperidine 1-oxyl free radicals, and the like); a nitrobenzene-based polymerization inhibitor (for example, nitrobenzene, 4-nitrotoluene, and the like); and a phenothiazine-based polymerization inhibitor (for example, phenothiazine, 2-methoxyphenothiazine, and the like).

Among them, from the viewpoint that the composition has a more excellent effect, a phenolic polymerization inhibitor or a free radical-based polymerization inhibitor is preferable.

In a case where the polymerization inhibitor is used together with a resin containing a curable group, the effect thereof is remarkable.

The content of the polymerization inhibitor in the composition is preferably 0.0001% to 0.5% by mass, more preferably 0.001% to 0.2% by mass, and still more preferably 0.008% to 0.05% by mass, with respect to the total solid content of the composition. The polymerization inhibitor may be used alone or in a combination of two or more thereof. In a case where two or more polymerization inhibitors are used in combination, the total content thereof is preferably within the above range.

In addition, the ratio (the content of the polymerization inhibitor/the content of the polymerizable compound (in terms of mass ratio)) of the content of the polymerization inhibitor to the content of the polymerizable compound in the composition is preferably 0.00005 to 0.02 and more preferably 0.0001 to 0.005.

[Surfactant]

The composition may contain a surfactant. The surfactant contributes to improvement in coating properties of the composition.

In a case where the composition contains a surfactant, the content of the surfactant is preferably 0.001% to 2.0% by mass, more preferably 0.003% to 0.5% by mass, and still more preferably 0.005% to 0.1% by mass, with respect to the total solid content of the composition.

The surfactant may be used alone or in a combination of two or more thereof. In a case where two or more surfactants are used in combination, the total amount thereof is preferably within the above range.

Examples of the surfactant include a fluorine-based surfactant, a nonionic surfactant, a cationic surfactant, an anionic surfactant, and a silicone-based surfactant.

For example, in a case where the composition contains a fluorine-based surfactant, liquid characteristics (particularly, fluidity) of the composition are further improved. That is, in a case where a film is formed from the composition containing the fluorine-based surfactant, the interfacial tension between a surface to be coated and a coating liquid is reduced, and accordingly, wettability with respect to the surface to be coated is improved, and coating properties to the surface to be coated are improved. As a result, even in a case where a thin film having a thickness of about several micrometers is formed with a small amount of a liquid, the fluorine-based surfactant is effective from the viewpoint that a film having a uniform thickness with small thickness unevenness is more suitably formed.

The content of fluorine in the fluorine-based surfactant is preferably 3% to 40% by mass, more preferably 5% to 30% by mass, and still more preferably 7% to 25% by mass. The fluorine-based surfactant having the content of fluorine within the above range is effective from the viewpoint of uniformity of the thickness of the coating film and/or liquid saving properties, and also has favorable solubility in the composition.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, MEGAFACE F780, and MEGAFACE F781F (all manufactured by DIC Corporation); FLUORAD FC430, FLUORAD FC431, and FLUORAD FC171 (all manufactured by Sumitomo 3M Limited); SURFLON S-382, SURFLON SC-101, SURFLON SC-103, SURFLON SC-104, SURFLON SC-105, SURFLON SC-1068, SURFLON SC-381, SURFLON SC-383, SURFLON S-393, and SURFLON KH-40 (all manufactured by ASAHI GLASS CO., LTD.); and PF636, PF656, PF6320, PF6520, and PF7002 (manufactured by OMNOVA Solutions Inc.).

As the fluorine-based surfactant, a block polymer can also be used, and specific examples thereof include the compound described in JP2011-89090A.

[Solvent]

The composition preferably contains a solvent.

As the solvent, for example, a known solvent can be used.

The content of the solvent in the composition is preferably an amount such that the solid content of the composition is 10% to 90% by mass, more preferably an amount such that the solid content is 10% to 45% by mass, and still more preferably an amount such that the solid content is 20% to 40% by mass.

The solvent may be used alone or in a combination of two or more thereof. In a case where two or more solvents are used in combination, the content thereof is preferably adjusted so that the total solid content of the composition is within the above range.

Examples of the solvent include water and an organic solvent.

<Organic Solvent>

Examples of the organic solvent include, which are not limited thereto, acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetyl acetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, methoxymethoxy ethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethyl sulfoxide, γ-butyrolactone, butyl acetate, methyl lactate, N-methyl-2-pyrrolidone, and ethyl lactate. However, it may be better to reduce aromatic hydrocarbons (toluene and the like) as the organic solvent for environmental reasons in some cases (for example, the content thereof may be 50 parts per million (ppm) by mass or less, 10 ppm by mass or less, or 1 ppm by mass or less, with respect to the total amount of the organic solvent). In the present invention, an organic solvent having a low metal content can be used, and the metal content in the organic solvent can be selected to be, for example, 10 parts per billion (ppb) by mass or less. An organic solvent at a level of parts per trillion (ppt) by mass may be used, as necessary, and such an organic solvent is provided by Toyo Gosei Co., Ltd., for example (The Chemical Daily, Nov. 13, 2015). Examples of the method of removing impurities such as a metal from the organic solvent include distillation (molecular distillation, thin film distillation, or the like) or filtration with a filter. The filter pore diameter of the filter that is used for the filtration is preferably 10 μm or less, more preferably 5 μm or less, and still more preferably 3 μm or less. The material of the filter is preferably polytetrafluoroethylene, polyethylene, or nylon. The organic solvent may contain isomers (compounds which have the same number of atoms but have different structures). In addition, only one isomer may be contained, or a plurality of isomers may be contained. The content of the peroxide in the organic solvent is preferably 0.8 mmol/L or less, and it is also preferable that the peroxide is substantially not contained.

<Water>

In a case where the composition contains water, the content (the moisture content) thereof is preferably 0.001% to 5.0% by mass, more preferably 0.01% to 3.0% by mass, and still more preferably 0.1% to 1.0% by mass, with respect to the total mass of the composition from the viewpoint of excellent storage stability of the composition.

In a case where the water content is 3.0% by mass or less (more preferably 1.0% by mass or less) with respect to the total mass of the composition, it is conceived that the inhibition of the adsorption of the resin (particularly the dispersing agent) due to the excessive adsorption of the moisture to the pigment (the black pigment or the like) can be suppressed, the pigment is easily maintained in a state of being dispersed in the composition, and thus the storage stability of the composition can be improved.

On the other hand, in a case where the water content is 0.01% by mass or more (preferably 0.1% by mass or more), the moisture is properly adsorbed to the pigment (the black pigment or the like), and thus the resin (particularly the dispersing agent) is not excessively adsorbed only to a part of the pigment (the black pigment or the like) and is uniformly adsorbed to the entire pigment (the black pigment or the like). As a result, it is conceived that the storage stability of the composition can be improved even in a case where the resin (particularly the dispersing agent) is not excessively added to the composition.

The moisture content of the composition can be measured by the Karl Fischer method.

[Silica Particle]

The composition may contain silica particles (silicon dioxide particles).

The silica particle is a material different from the above-described black pigment. That is, even in a case where the silica particle is black, it is not included in the black pigment.

In a case where the composition contains silica particles, it is conceived that the silica particles are likely to be unevenly distributed on the surface of the cured film (the light shielding film) formed from the composition, and the proper unevenness can be formed on the surface of the cured film (the light shielding film), and thus the reflection properties of the cured film (the light shielding film) can be suppressed.

The content of the silica particle in the composition is preferably 0.1% to 16.0% by mass, more preferably 1.0% to 10.0% by mass, and still more preferably 3.0% to 8.5% by mass, with respect to the total solid content of the composition.

The composition may contain only one kind of silica particle or may contain two or more kinds thereof. In a case where two or more kinds thereof are contained, the total amount thereof is preferably within the above range.

The average primary particle diameter of the silica particles is preferably 1 to 200 nm, more preferably 10 to 100 nm, and still more preferably 15 to 78 nm, from the viewpoint that the effects of the present invention are more excellent.

It is noted that in the present specification, the average primary particle diameter of the silica particles means the average primary particle diameter of particles measured according to the following method. The average primary particle diameter can be measured using a scanning electron microscope (SEM).

A maximum length (Dmax: a maximum length between two points on a contour of the particle image) and a length vertical to the maximum length (DV-max: in a case where an image is sandwiched between two straight lines parallel to the maximum length, the shortest length that vertically connects the two straight lines) of a particle image obtained using the SEM are measured, and a geometric mean value thereof (Dmax×DV-max)^{1/2} shall be taken as the primary particle diameter. Primary particle diameters of 100 particles are measured by this method, and an arithmetic average value thereof shall be taken as the average primary particle diameter of the particles.

The refractive index of the silica particle is not particularly limited; however, it is preferably 1.10 to 1.60 and more preferably 1.15 to 1.45 from the viewpoint that the low reflection properties of the cured film are more excellent.

In addition, the silica particle may be a hollow particle or a solid particle.

The hollow particles refer to particles in which a cavity is present inside the particle. The hollow particle may have a structure in which the particle consists of an inner cavity and an outer shell surrounding the cavity. In addition, the hollow particle may have a structure in which a plurality of cavities are present inside the particle.

The solid particle refers to a particle in which a cavity is substantially not present in the inside of the particle.

The hollow particle preferably has a void volume of 3% or more, and the solid particle preferably has a void volume of less than 3%.

Examples of the solid particle (the silica particle which is a solid particle) include silica particles such as IPA-ST, IPA-ST-L, IPA-ST-ZL, MIBK-ST, MIBK-ST-L, CHO-ST-M, PGM-AC-2140Y, and PGM-AC-4130Y (manufactured by Nissan Chemical Corporation).

It is conceived that since the hollow particle has a cavity inside and has a low specific gravity as compared with a particle having no hollow structure, the hollow particle floats on the surface of the coating film formed from the curable composition, and thus the effect of being unevenly distributed on the surface of the cured film is further enhanced.

In addition, in the hollow particle, the particle itself has a low refractive index as compared with a particle having no hollow structure. For example, in a case where the hollow particle is formed of silica, the hollow particle has air having a low refractive index (refractive index=1.0), and thus the refractive index of the particle itself is 1.2 to 1.4, which is significantly low as compared with normal silica (refractive index=1.6). As a result, it is conceived that in a case where the cured film is formed by using the composition containing the hollow particles, the hollow particles having a low refractive index are unevenly distributed on the surface of the cured film, an anti-reflection (AR)-type low-reflection effect is achieved, and thus the low reflection properties of the cured film are improved.

Examples of the hollow particle (the silica particle which is a hollow particle) include the hollow particles described in JP2001-233611A and JP3272111B.

As the hollow silica particle, for example, THRULYA 4110 (product name, manufactured by JGC Catalysts and Chemicals Ltd.) can also be used.

As the silica particle, rosary-shaped silica particles which are a particle aggregate in which a plurality of silica particles are connected in a chain shape may be used. As the rosary-shaped silica particles, particles in which a plurality of spherical colloidal silica particles having an average primary particle diameter of 5 to 50 nm are bonded to each other by metal oxide-containing silica are preferable.

Examples of the rosary-shaped colloidal silica particles include the silica sols described in JP4328935B and JP2013-253145A.

The silica particle may contain a component other than silicon dioxide, as desired. The content of the silicon dioxide in the silica particle is preferably 75% to 100% by mass, preferably 90% to 100% by mass, and still more preferably 99% to 100% by mass, with respect to the total mass of the silica particle.

From the viewpoint that the cured film has more excellent light transmittance, the silica particle is preferably a modified silica particle including silica and a coating layer with which the silica is coated.

<Coating Layer>

The coating layer is a layer with which silica that constitutes the silica particle is coated. The coating with the coating layer may be a coating of the entire surface of the silica or may be a coating of a part of the surface thereof.

The coating layer may be disposed directly on the surface of the silica or may be disposed with another layer interposed between the coating layer and the silica.

The coating layer preferably includes at least one group selected from the group consisting of a group containing a silicon atom, a group containing a fluorine atom, an alkyl group which may have a substituent, an aryl group which may have a substituent, a (meth)acryloyl group, a glycidoxy group, and an amino group. Among the above, the coating layer more preferably includes at least one group selected from the group consisting of a group containing a silicon atom, a group containing a fluorine atom, an alkyl group which may have a substituent, and an aryl group which may have a substituent, and still more preferably includes at least one group selected from the group consisting of a group containing a silicon atom and a group containing a fluorine atom, from the viewpoint that the effects of the present invention are more excellent and/or that the generation of residues in a case where a patterned cured film is formed can be further suppressed.

However, the silicon atom in the group containing a silicon atom referred to here does not include the silicon atom bonded to silica through the oxygen atom. For example, in a case where a silane coupling agent is used to produce modified silica particles, a silicon atom derived from the hydrolyzable silyl group bonded to silica through an oxygen atom does not correspond to the silicon atom in the group containing a silicon atom, and in a case where a silylating agent is used to produce modified silica particles, a silicon atom derived from the silylating agent bonded to silica through an oxygen atom does not correspond to the silicon atom in the group containing a silicon atom.

As a more detailed specific example, even in a case where a trimethoxysilyl group of 3-methacryloxypropyl trimethoxysilane is reacted with silica to produce modified silica particles having a methacryloyl group, a silicon atom derived from the trimethoxysilyl group that has reacted with the silica does not correspond to the silicon atom in a group containing a silicon atom, where the group is contained in the coating layer. Similarly, even in a case where hexamethyl disilazane is reacted with silica to produce modified silica particles having an alkyl group (a methyl group), a silicon atom derived from the hexamethyl disilazane that has reacted with silica does not correspond to the silicon atom in a group containing a silicon atom, where the group is contained in the coating layer.

The group containing a silicon atom and the group containing a fluorine atom are preferably a group contained in a repeating unit represented by General Formula (1) described later (preferably a group represented by S^{S1} in General Formula (1)). In other words, the coating layer preferably contains a polymer containing a repeating unit represented by General Formula (1).

The coating layer may contain the polymer as a part, or the coating layer may be the polymer itself. The content of the polymer is preferably 10% to 100% by mass, preferably 70% to 100% by mass, and still more preferably 95% to 100% by mass, with respect to a total mass of the coating layer.

The repeating unit, which is contained in the polymer and represented by General Formula (1), is shown below.

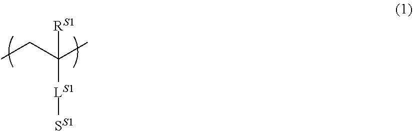

In General Formula (1), R^{S1} represents an alkyl group which may have a substituent, or a hydrogen atom.

The alkyl group may be linear or branched. In addition, the alkyl group may have a cyclic structure as a whole or may partially have a cyclic structure.

The alkyl group preferably has 1 to 10 carbon atoms and more preferably 1 to 3 carbon atoms. In a case where the alkyl group has a substituent, the preferred number of carbon atoms mentioned here is intended to be the number of carbon atoms which also includes the number of carbon atoms that can be present in the substituent.

Among them, R^{S1} is preferably a hydrogen atom or a methyl group.

In General Formula (1), L^{S1} represents a single bond or a divalent linking group. Examples of the divalent linking group include —O—, —CO—, —COO—, —S—, —SO₂—, —NR^{N}— (R^{N} represents a hydrogen atom or an alkyl group), a divalent hydrocarbon group (alkylene group, alkenylene group (for example, —CH═CH—), or an alkynylene group (for example, —C≡C— or the like), and an arylene group), —SiR^{SX}₂— (R^{SX} represents a hydrogen atom or a substituent), and a group obtained by combining one or more groups selected from the group consisting of these groups.

The divalent linking group may have a substituent, in a case where possible, and the substituent of the divalent linking group may be a group represented by S^{S1}, which will be described later, or may be a group partially having a group represented by S^{S1}, which will be described later.

Among them, the divalent linking group is preferably a group obtained by combining groups selected from the group consisting of an ester group and an alkylene group (preferably an alkylene group having 1 to 10 carbon atoms).

Among them, the divalent linking group is preferably a group represented by *A-CO—O—*B or *A-CO—O-alkylene group-*B.

*B represents a bonding position to S^{S1} in General Formula (1), and *A represents a bonding position on a side opposite to *B.

The alkylene group may be linear or branched. In addition, the alkylene group may have a cyclic structure as a whole or may partially have a cyclic structure. The alkylene group is preferably linear.

The alkylene group preferably has 1 to 10 carbon atoms and more preferably 1 to 3 carbon atoms. In a case where the alkylene group has a substituent, the preferred number of carbon atoms mentioned here is intended to be the number of carbon atoms which also includes the number of carbon atoms that can be present in the substituent. It is preferable that the alkylene group is unsubstituted.

In General Formula (1), S^{S1} represents a substituent.

The substituent preferably contains a silicon atom or a fluorine atom. That is, the substituent is preferably a group containing a silicon atom or a group containing a fluorine atom.

The substituent is preferably an unsubstituted alkyl group, a fluoroalkyl group, or a group represented by General Formula (SS1), and more preferably a fluoroalkyl group or a group represented by General Formula (SS1).

The unsubstituted alkyl group as the substituent represented by S^{S1} may be linear or branched. In addition, the unsubstituted alkyl group may have a cyclic structure as a whole or may partially have a cyclic structure.

The unsubstituted alkyl group preferably has 1 to 10 carbon atoms and more preferably 1 to 5 carbon atoms.

The alkyl group moiety in the fluoroalkyl group as the substituent represented by S^{S1} may be linear or branched. In addition, the alkyl group moiety may have a cyclic structure as a whole or may partially have a cyclic structure.

The alkyl group moiety preferably has 1 to 15 carbon atoms and more preferably 1 to 10 carbon atoms.

It is also preferable that the alkyl group moiety does not have a substituent other than a fluorine atom.

The number of fluorine atoms contained in the fluoroalkyl group is preferably 1 to 30 and more preferably 5 to 20.

It is also preferable that the whole or a part of the fluoroalkyl group is a perfluoroalkyl group.

The group represented by General Formula (SS1) as the substituent represented by S^{S1} is as follows.

*-L^{S2}-O—SiR^{S2}₃ (SS1)

In General Formula (SS1), * represents a bonding position.

In General Formula (SS1), R^{S2} represents a hydrocarbon group which may have a substituent and has 1 to 20 carbon atoms.

The hydrocarbon group has 1 to 20 carbon atoms, preferably 1 to 10 carbon atoms, and more preferably 1 to 5 carbon atoms. In a case where the hydrocarbon group has a substituent, the number of carbon atoms mentioned here is intended to be the number of carbon atoms which also includes the number of carbon atoms that can be present in the substituent.

The hydrocarbon group is preferably an alkyl group.

The alkyl group may be linear or branched. In addition, the alkyl group may have a cyclic structure as a whole or may partially have a cyclic structure.

A plurality of R^{S2}'s may be the same or different from each other.

In General Formula (SS1), L^{S2} represents a single bond or a divalent linking group.

Examples of the divalent linking group as L^{S2} in General Formula (SS1) include the same groups as those mentioned as the examples of the divalent linking group as L^{S1} in General Formula (1).

In addition, the divalent linking group as L^{S2} may contain one or more (for example, 1 to 1,000) —SiR^{S2}₂—O-'s. It is noted that R^{S2} in —SiR^{S2}₂—O— is the same as the above-described R^{S2}.

S^{S1} is more preferably a group represented by General Formula (2) from the viewpoint that the effects of the present invention are more excellent.

The group represented by General Formula (2) is shown below.

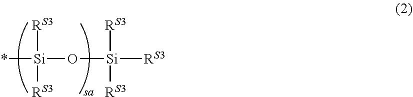

In General Formula (2), * represents a bonding position.

In General Formula (2), sa represents an integer of 1 to 1,000.

In General Formula (2), R^{S3} represents a hydrocarbon group, which may have a substituent and has 1 to 20 carbon atoms, or a group represented by General Formula (3).

In General Formula (2), a plurality of R^{S3}'s may be the same or different from each other.

Examples of the hydrocarbon group, which can be represented by R^{S3}, include the hydrocarbon group which may have a substituent and can be represented by the above-described R^{S2}.

Among them, it is preferable that R^{S3}'s bonded to rightmost Si in General Formula (2) are each independently the hydrocarbon group.

In a case where sa in General Formula (2) is 1, it is preferable that R^{S3}'s in “—(SiR^{S3}₂—O—)ₛₐ-” are each independently the group represented by General Formula (3). Among “2×sa” pieces of R^{S3}'s in “(SiR^{S3}₂—O—)ₛₐ-”, the number of R^{S3}'s which are groups represented by General Formula (3) is preferably 0 to 1,000, more preferably 0 to 10, and still more preferably 0 to 2.

The group represented by General Formula (3), which can be represented by R^{S3}, is shown below.

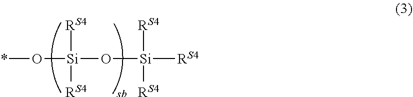

In General Formula (3), * represents a bonding position.

In General Formula (3), sb represents an integer of 0 to 300.

In General Formula (3), R^{S4} represents a hydrocarbon group which may have a substituent and has 1 to 20 carbon atoms.

In General Formula (3), a plurality of R^{S4}'s may be the same or different from each other.

Examples of the hydrocarbon group, which can be represented by R^{S4}, include the hydrocarbon group which may have a substituent and can be represented by the above-described R^{S2}.

The polymer contained in the coating layer may contain a repeating unit other than the repeating unit represented by General Formula (1).

The repeating unit other than the repeating unit represented by General Formula (1) is preferably a (meth)acrylic repeating unit.

The molecular weight of the repeating unit other than the repeating unit represented by General Formula (1) is preferably 86 to 1,000 and more preferably 100 to 500.

From the viewpoint that the effects of the present invention are more excellent, the content of the repeating unit represented by General Formula (1) in the polymer contained in the coating layer is preferably 10% to 100% by mass, preferably 60% to 100% by mass, and still more preferably 90% to 100% by mass, with respect to all the repeating units.

It is preferable that the polymer contained in the coating layer substantially does not contain a repeating unit having an ethylenic unsaturated group and/or a repeating unit having a hydrolyzable silyl group.

The description that the above-described repeating unit is substantially not contained means that the contents of the repeating unit having an ethylenic unsaturated group and the repeating unit having a hydrolyzable silyl group in the polymer contained in the coating layer are each independently 1.0% by mass or less (preferably 0.10% by mass or less) with respect to all the repeating units.

The coating layer, which contains the polymer containing the repeating unit represented by General Formula (1), can be formed, for example, by the following method.

First, a silane coupling agent (3-methacryloxypropyl trimethoxysilane or the like) containing an ethylenic unsaturated group (for example, a (meth)acryloyl group, a vinyl group, a styryl group, and the like) is reacted with silica to form a polymer precursor layer containing an ethylenic unsaturated group on the surface of silica. Next, by polymerizing the ethylenic unsaturated group of the polymer precursor layer, an ethylenic unsaturated group of a monomer corresponding to the repeating unit represented by General Formula (1), and an ethylenic unsaturated group of another ethylenic unsaturated group-containing monomer added as desired, a coating layer, which contains the polymer containing the repeating unit represented by General Formula (1), can be formed.

Further, the group containing a fluorine atom may be a group contained in a coating layer having no polymer, and examples thereof include a layer formed by using a silane coupling agent containing a group containing a fluorine atom. In this case, specific examples of the group containing a fluorine atom include a fluoroalkyl group, and a perfluoroalkyl group is preferable.

The fluoroalkyl group preferably has 1 to 10 carbon atoms, more preferably 1 to 5 carbon atoms, and still more preferably 1 to 3 carbon atoms in that defects in the cured film can be further suppressed.

The coating layer having a group containing a fluorine atom and having no polymer can be formed, for example, by reacting a silane coupling agent containing a fluoroalkyl group (trifluoropropyl trimethoxysilane or the like) with silica. That is, the coating layer may be a layer formed by using a silane coupling agent containing a fluoroalkyl group.

The coating layer having an alkyl group which may have a substituent may be a coating layer having no polymer, and examples thereof include a layer formed by using a silylating agent.

Regarding the alkyl group which may have a substituent, the alkyl group preferably has 1 to 20 carbon atoms, and from the viewpoint that the cured film has more excellent light transmittance, it more preferably has two or more carbon atoms and still more preferably 3 or more carbon atoms. From the viewpoint that the uniformity of the cured film is more excellent, the alkyl group more preferably has 10 or fewer carbon atoms and still more preferably 8 or fewer carbon atoms.

The alkyl group may have any linear, branched, or cyclic structure; however, it is preferably linear from the viewpoint that the effects of the present invention are more excellent.

Specific examples of the alkyl group include a methyl group, an ethyl group, an isopropyl group, a tert-butyl group, an n-octyl group, an n-decyl group, an n-hexadecyl group, a cyclopropyl group, a cyclopentyl group, and a cyclohexyl group.

Regarding the alkyl group which may have a substituent, examples of the substituent include a 2-(3,4-epoxycyclohexyl)ethyl group and a 3-glycidoxypropyl group.

The coating layer having an alkyl group which may have a substituent can be formed, for example, by reacting a silylating agent containing an alkyl group (hexamethyl disilazane or the like) with silica. That is, the coating layer may be a layer formed by using a silylating agent containing an alkyl group.

The coating layer having an aryl group which may have a substituent may be a coating layer having no polymer, and examples thereof include a layer formed by using a silane coupling agent containing an aryl group which may have a substituent.

Regarding the aryl group which may have a substituent in the coating layer, the aryl group preferably has 6 to 30 carbon atoms, and from the viewpoint that the uniformity of the cured film is more excellent, it more preferably has 20 or fewer carbon atoms, and still more preferably 12 or fewer carbon atoms.

The aryl group may be a monocyclic ring or may have a fused-ring structure of two or more rings; however, it is preferably a monocyclic ring from the viewpoint that the effects of the present invention are more excellent.

Specific examples of the aryl group include a phenyl group, a 2,6-diethylphenyl group, a 3,5-ditrifluoromethylphenyl group, a naphthyl group, and a biphenyl group.

Examples of the substituent in the aryl group which may have a substituent include a p-styryl group an N-phenyl-3-aminopropyl group.

The coating layer having an aryl group which may have a substituent can be formed, for example, by reacting a silane coupling agent containing an aryl group with silica. That is, the coating layer may be a layer formed by using a silane coupling agent containing an aryl group.

The coating layer having a (meth)acryloyl group may be a coating layer having no polymer and can be formed, for example, by reacting a silane coupling agent (3-methacryloxypropyl trimethoxysilane or the like) containing a (meth)acryloyl group with silica. That is, the coating layer may be a layer formed by using a silane coupling agent containing a (meth)acryloyl group.

Further, the coating layer having a glycidoxy group may be a coating layer having no polymer, and it can be formed, for example, by reacting a silane coupling agent (3-glycidoxypropyl trimethoxysilane or the like) containing a glycidoxy group with silica. That is, the coating layer may be a layer formed by using a silane coupling agent containing a glycidoxy group.

Further, the coating layer having an amino group may be a coating layer having no polymer, and it can be formed, for example, by reacting a silane coupling agent (3-aminopropyl trimethoxysilane or the like) containing an amino group with silica. That is, the coating layer may be a layer formed by using a silane coupling agent containing an amino group.

The content of the coating layer in the modified silica particles is preferably 2% by mass or more, preferably 6% by mass or more, still more preferably 8% by mass or more, with respect to the total mass of the modified silica particles, from the viewpoint that the effects of the present invention are more excellent. The upper limit thereof is preferably 30% by mass or less, more preferably 20% by mass or less, and still more preferably 15% by mass or less.

[Ultraviolet Absorbing Agent]

The composition according to the embodiment of the present invention may contain or may not contain an ultraviolet absorbing agent.

However, in a case where the composition contains an ultraviolet absorbing agent, the content thereof is preferably more than 0% by mass and 5% by mass or less with respect to the total mass of the solid content thereof. From the viewpoint of improving the curability, it is more preferably 4% by mass or less and still more preferably 3% by mass or less. The ultraviolet absorbing agent referred to here is a compound other than the photopolymerization initiator, and it is intended to be an organic compound having a molar absorption coefficient of 50 (l·mol⁻¹·cm⁻¹) or more within a range of 300 to 800 nm (more preferably 330 to 500 nm).

Examples of the ultraviolet absorbing agent include a conjugated diene-based compound, and a compound represented by Formula (I) may be used.

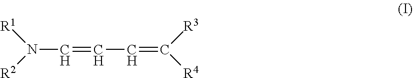

In Formula (I), R¹ and R² each independently represent a hydrogen atom, an alkyl group having 1 to 20 carbon atoms, or an aryl group having 6 to 20 carbon atoms, and R¹ and R² may be the same as different from each other; however, both R¹ and R² do not represent a hydrogen atom at the same time.

In Formula (I), R³ and R⁴ each independently represent an electron-withdrawing group. The electron-withdrawing group is an electron-withdrawing group having a Hammett's substituent constant σₚ value of 0.20 or more and 1.0 or less.

The description of R¹ to R⁴ of the ultraviolet absorbing agent represented by Formula (I), reference can be made to the description in paragraphs 0024 to 0033 of WO2009/123109A (paragraphs 0040 to 0059 of corresponding US2011/0039195A), the content of which is incorporated into the present specification. With regard to the compound represented by Formula (I), reference can be made to the description of the exemplary compounds (1) to (14) in paragraphs 0034 to 0037 of WO2009/123109A (paragraph 0060 of corresponding US2011/0039195A), the content of which is incorporated into the present specification. Specific examples of the ultraviolet absorbing agent represented by Formula (I) include the following compounds.

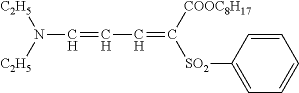

[Other Optional Components]

The composition may further contain optional components other than the above-described components. Examples thereof include particle components other than the above-described components, an ultraviolet absorbing agent, a silane coupling agent, a sensitizer, a co-sensitizer, a crosslinking agent, a curing accelerator, a heat curing accelerator, a plasticizer, a diluent, and an oil sensitizing agent, and known additives such as an adhesion promoter to the surface of the substrate and other auxiliaries (for example, conductive particles, a filler, an anti-foaming agent, a flame retardant, a leveling agent, a peeling accelerator, an antioxidant, a fragrance, a surface tension adjuster, a chain transfer agent, and the like) may be further contained, as necessary or may not be contained.

Regarding these components, reference can be made to, for example, the descriptions in paragraphs 0183 to 0228 of JP2012-003225A (corresponding to paragraphs 0237 to 0309 of US2013/0034812A), paragraphs 0101, 0102, 0103, 0104, and 0107 to 0109 of JP2008-250074A, and paragraphs 0159 to 0184 of JP2013-195480A, the contents of which are incorporated into the specification of the present application.

[Production Method for Composition]

Regarding the composition, it is preferable that a coloring material composition (a coloring material dispersion liquid) containing a black pigment is produced, and the obtained coloring material composition is further mixed with other components to obtain a composition.

The coloring material composition is preferably prepared by mixing a black coloring material, a resin, and a solvent. In addition, it is also preferable that a polymerization inhibitor is incorporated into the coloring material composition.

The coloring material composition can be prepared by mixing the above-described respective components through a known mixing method (for example, a mixing method using a stirrer, a homogenizer, a high-pressure emulsification device, a wet-type pulverizer, a wet-type disperser, or the like).

In a case of preparing the composition, the respective components may be formulated at once, or each of the components may be dissolved or dispersed in a solvent and then sequentially formulated. In addition, the input order and the operation conditions during the formulation are not particularly limited.

For the purpose of removing foreign substances, reducing defects, and the like, the composition is preferably filtered with a filter. Any filter can be used without particular limitation as long as it is a filter, for example, which has been used in the related art for the use application to filtration or the like. Examples of the filter include filters made of a fluororesin such as polytetrafluoroethylene (PTFE), a polyamide-based resin such as nylon, a polyolefin-based resin (having a high density and an ultrahigh molecular weight) such as polyethylene and polypropylene (PP), or the like. Among these materials, polypropylene (including high-density polypropylene) and nylon are preferable.

The pore diameter of the filter is preferably 0.1 to 7.0 μm, more preferably 0.2 to 2.5 μm, still more preferably 0.2 to 1.5 μm, and particularly preferably 0.3 to 0.7 μm. In a case where the pore diameter is within the above range, it is possible to reliably remove fine foreign substances, such as impurities and aggregates, contained in a pigment while suppressing filtration clogging of the pigment (including a black pigment).

In a case of using a filter, different filters may be combined. In this case, filtering with a first filter may be carried out only once or may be carried out twice or more times. In a case where filtering is carried out twice or more times with the combination of different filters, the pore diameters of the filters that are used in the second and subsequent filtering are preferably the same as or larger than the pore diameter of the filter that is used in the first filtering. In addition, the first filters having different pore diameters within the above range may be combined. Regarding the pore diameter mentioned here, reference can be made to nominal values of filter manufacturers. A commercial filter can be selected from various filters provided by, for example, Nihon Pall Ltd., Advantec Toyo Kaisha, Ltd., Nihon Entegris K. K. (formerly Nippon Microlith Co., Ltd.), Kitz Micro Filter Corporation.

As a second filter, a filter formed of the same material as that of the first filter, or the like can be used. The pore diameter of the second filter is preferably 0.2 to 10.0 μm, more preferably 0.2 to 7.0 μm, and still more preferably 0.3 to 6.0 μm.

The composition preferably does not contain impurities such as a metal, a halogen-containing metal salt, an acid, and an alkali. The content of impurities contained in these materials is preferably 1 ppm by mass or less, more preferably 1 ppb by mass or less, still more preferably 100 ppt by mass or less, and particularly preferably 10 ppt by mass or less, and it is most preferable that the impurities are substantially not contained (the content is equal to or less than the detection limit of the measuring device).

It is noted that the impurities can be measured using an inductively coupled plasma mass spectrometer (manufactured by Agilent Technologies, Inc., Agilent 7500cs model).

[Manufacturing of Cured Film]

A composition layer formed from the composition according to the embodiment of the present invention is cured to obtain a cured film (including a patterned cured film).

The manufacturing method for a cured film is not particularly limited; however, it preferably includes the following steps.
Composition layer forming step
Exposure step
Development step

Hereinafter, each of the steps will be described.

[Composition Layer Forming Step]

In the composition layer forming step, prior to exposure, the composition is applied on a support or the like to form a layer (composition layer) of the composition. As the support, for example, a substrate for a solid-state imaging element, where an imaging element (a light-receiving element) such as a CCD or CMOS is provided on the substrate (for example, a silicon substrate), can be used. In addition, in order to improve adhesion with the upper layer, prevent the diffusion of substances, and planarize the surface of the substrate, an undercoat layer may be provided on the support, as needed.

As a method of applying the composition onto the support, for example, various coating methods such as a slit coating method, an ink jet method, a spin coating method, a cast coating method, a roll coating method, and a screen printing method can be applied. The film thickness of the composition layer is preferably 0.1 to 10 μm, more preferably 0.2 to 5 μm, and still more preferably 0.2 to 3 μm. The composition layer applied on the support can be dried (pre-baked) at a temperature of 50° C. to 140° C. for 10 to 300 seconds, for example, using a hot plate, an oven, or the like.

[Exposure Step]

In the exposure step, the composition layer (the dried film) formed in the composition layer forming step is exposed by irradiation with actinic rays or radiation, and the composition layer irradiated with light is cured.

In the method of light irradiation, it is preferable to carry out light irradiation through a photo mask having a patterned opening portion.

The exposure is preferably carried out by irradiation with radiation. The radiation, which can be used during the exposure, is preferably ultraviolet rays such as a g-line, an h-line, or an i-line, and a light source is preferably a high-pressure mercury lamp. The irradiation intensity is preferably 5 to 1,500 mJ/cm² and more preferably 10 to 1,000 mJ/cm².

In addition, in a case where the composition contains a thermal polymerization initiator, the composition layer may be heated in the exposure step. The heating temperature is not particularly limited; however, it is preferably 80° C. to 250° C. In addition, the heating time is preferably 30 to 300 seconds.

It is noted that in a case where the composition layer is heated in the exposure step, the exposure step may serve as a post-heating step which will be described later. In other words, in a case where the composition layer is heated in the exposure step, the method for manufacturing a cured film may not include the post-heating step.

[Development Step]

The development step is a step of developing the exposed composition layer to form a cured film. By this step, the composition layer in a portion which is not irradiated with light in the exposure step is eluted, only a photo-cured portion remains, and thus a patterned cured film can be obtained.

The kind of the developer used in the development step is not particularly limited; however, an alkali developer which does not damage the underlying imaging element and circuit or the like is desirable.

The development temperature is, for example, 20° C. to 30° C.

The development time is, for example, 20 to 90 seconds. In order to more efficiently remove the residues, in recent years, the development may be carried out for 120 to 180 seconds. Furthermore, in order to further improve residue removability, a step of shaking off the developer every 60 seconds and further supplying a fresh developer may be repeated several times.

The alkali developer is preferably an alkaline aqueous solution which is prepared by dissolving an alkaline compound in water so that the concentration thereof is 0.001% to 10% by mass (preferably 0.01% to 5% by mass).

Examples of the alkaline compound include sodium hydroxide, potassium hydroxide, sodium carbonate, sodium silicate, sodium metasilicate, aqueous ammonia, ethylamine, diethylamine, dimethylethanolamine, tetramethylammonium hydroxide, tetraethylammonium hydroxide, tetrapropylammonium hydroxide, tetrabutylammonium hydroxide, benzyltrimethylammonium hydroxide, choline, pyrrole, piperidine, and 1,8-diazabicyclo[5.4.0]-7-undecene (among them, an organic base is preferable).

It is noted that in a case where the alkaline compound is used as an alkali developer, the alkaline compound is generally subjected to a washing treatment with water after development.

[Post-Baking]

A heating treatment (post-baking) is preferably carried out after the exposure step. The post-baking is a heating treatment after development for completing the curing. The heating temperature is preferably 240° C. or lower and more preferably 220° C. or lower. The lower limit thereof is not particularly limited; however, it is preferably 50° C. or more and more preferably 100° C. or more, in consideration of efficient and effective treatment.

The post-baking can be carried out continuously or batchwise by using a heating unit such as a hot plate, a convection oven (hot-air circulating dryer), and a high-frequency heater.

The post-baking is preferably carried out in an atmosphere of a low oxygen concentration. The oxygen concentration is preferably 19% by volume or less, more preferably 15% by volume or less, still more preferably 10% by volume or less, particularly preferably 7% by volume or less, and most preferably 3% by volume or less. The lower limit thereof is not particularly limited; however, it is practically 10 ppm by volume or more.

In addition, the curing may be completed by irradiation with ultraviolet rays (UV) instead of the post-baking by heating.

In this case, it is preferable that the composition further contains a UV curing agent. The UV curing agent is preferably a UV curing agent which can be cured at a wavelength shorter than 365 nm that is an exposure wavelength of a polymerization initiator added for a lithography step by ordinary i-line exposure. Examples of the UV curing agent include Omnirad 2959 (corresponding to IRGACURE 2959 (former product name, formerly manufactured by BASF SE) manufactured IGM Resins B.V. In a case where UV irradiation is carried out, the composition layer is preferably a material which is cured at a wavelength of 340 nm or less. The lower limit value of the wavelength is not particularly limited; however, it is generally 220 nm or more. In addition, the exposure amount of the UV irradiation is preferably 100 to 5,000 mJ, more preferably 300 to 4,000 mJ, and still more preferably 800 to 3,500 mJ. The UV curing step is preferably carried out after the exposure step, in order to more effectively carry out low-temperature curing. As the exposure light source, an ozoneless mercury lamp is preferably used.

[Physical Properties of Cured Film and Use Application of Cured Film]

[Physical Properties of Cured Film]

A cured film formed from the composition according to the embodiment of the present invention (particularly, the composition according to the embodiment of the present invention containing a black coloring material) can be preferably used as a light shielding film.

In the cured film, the optical density (OD) per film thickness of 1.5 μm in a wavelength range of 400 to 700 nm is preferably more than 2.0 and more preferably more than 3.0 from the viewpoint that excellent light shielding properties are exhibited. It is noted that the upper limit value thereof is not particularly limited; however, in general, it is preferably 10 or less.

In the present specification, the description that the optical density per film thickness of 1.5 μm in a wavelength range of 400 to 700 nm is more than 2.0 means that an optical density per film thickness of 1.5 μm in the entire wavelength range of 400 to 700 nm is more than 2.0.

In addition, the cured film (the light shielding film) preferably has good light shielding properties against light in the infrared region, and the optical density per film thickness of 1.5 μm in the light having a wavelength of 940 nm is preferably more than 2.0 and more preferably more than 3.0. It is noted that the upper limit value thereof is not particularly limited; however, in general, it is preferably 10 or less.

In a case where the cured film is used as a light attenuating film, it is preferable that the optical density is smaller than the value described above.

In the present specification, as the method of measuring the optical density of the cured film, a cured film is first formed on a glass substrate, and the optical density per predetermined film thickness is calculated by using a spectrophotometer (UV-3600 manufactured by Shimadzu Corporation, or the like).

By the way, even in the state of the composition layer (the dried film) in which the composition is applied and dried, the film thickness and the optical density generally do not change significantly as compared with the state of the cured film which has been subsequently exposed and cured. In such a case, the optical density of the composition layer (the dried film) may be measured by the above-described measuring method, and the obtained value may be used as the optical density of the cured film.

The film thickness of the cured film is, for example, preferably 0.1 to 4.0 μm and more preferably 1.0 to 2.5 μm. In addition, the cured film may be thinner or thicker than the above range depending on the use application.

In addition, in a case where the cured film is used as a light attenuating film, the light shielding properties may be adjusted by making the cured film thinner (for example, 0.1 to 0.5 μm) than the above range. In this case, the optical density per film thickness of 1.0 μm in a wavelength range of 400 to 700 nm (and/or light having a wavelength of 940 nm) is preferably 0.1 to 1.5 and more preferably 0.2 to 1.0.

The reflectivity of the cured film is preferably lower than 8%, more preferably lower than 6%, and still more preferably lower than 4%. The lower limit thereof is 0% or more.

The reflectivity mentioned here is obtained from the reflectivity spectrum obtained by causing light having wavelengths of 400 to 1,100 nm to be incident at an incidence angle of 5° using a VAR unit of a spectrometer V7200 (product name) manufactured by JASCO Corporation. Specifically, the reflectivity of light having a wavelength at which the maximum reflectivity is exhibited in a wavelength range of 400 to 1,100 nm shall be taken as the reflectivity of the cured film.

In addition, the cured film is suitable for a light shielding member and a light shielding film as well as an antireflection member and an antireflection film of an optical filter and a module that are used in portable instruments such as a personal computer, a tablet PC, a mobile phone, a smartphone, and a digital camera; office automation (OA) instruments such as a printer composite machine and a scanner; industrial instruments such as a surveillance camera, a barcode reader, an automated teller machine (ATM), a high-speed camera, and an instrument having a personal authentication function using face image authentication or biometric authentication; in-vehicle camera instruments; medical camera instruments such as an endoscope, a capsule endoscope, and a catheter; a biological sensor, a biosensor, a military reconnaissance camera, a camera for a three-dimensional map, a camera for observing weather and sea, a camera for a land resource exploration, and space instruments such as an exploration camera for the astronomy of the space and a deep space target.

The cured film can also be used in applications of a micro light emitting diode (LED), a micro organic light emitting diode (OLED). The cured film is suitable for an optical filter and an optical film that are used in the micro LED and the micro OLED as well as a member which imparts a light shielding function or an antireflection function.

Examples of the micro LED and the micro OLED include the examples described in JP2015-500562A and JP2014-533890A.

The cured film is also suitable as an optical film that is used in a quantum dot sensor and a quantum dot solid-state imaging element. In addition, the cured film is suitable as a member which imparts a light shielding function or an antireflection function. Examples of the quantum dot sensor and the quantum dot solid-state imaging element include the examples described in US2012/37789A and WO2008/131313A.

[Light Shielding Film, Optical Element, Solid-State Imaging Element, and Solid-State Imaging Device]

It is also preferable that the cured film according to the embodiment of the present invention is used as a so-called light shielding film. It is also preferable that such a light shielding film is used in a solid-state imaging element.

As described above, the cured film formed from the photosensitive composition according to the embodiment of the present invention has excellent light shielding properties and low reflection properties.

It is noted that the light shielding film is one of the preferred use applications in the cured film according to the embodiment of the present invention, and the light shielding film according to the embodiment of the present invention can be manufactured by the same method as the method described as the above manufacturing method for a cured film. Specifically, by applying the composition onto a substrate to form a composition layer and carrying out exposure and development on the composition layer, a light shielding film can be manufactured.

The present invention also includes an invention of an optical element. The optical element according to the embodiment of the present invention is an optical element including the above-described cured film (light shielding film). Examples of the optical element include an optical element that is used in an optical instrument such as a camera, binoculars, a microscope, and a semiconductor exposure device.

Among them, the optical element is preferably, for example, a solid-state imaging element mounted on a camera or the like.

In addition, the solid-state imaging element according to the embodiment of the present invention is a solid-state imaging element including the cured film (the light shielding film) according to the embodiment of the present invention.

Examples of the form in which the solid-state imaging element according to the embodiment of the present invention includes the cured film (the light shielding film) include a form in which a plurality of photodiodes and light-receiving elements consisting of polysilicon or the like, which constitute a light-receiving area of a solid-state imaging element (a CCD image sensor, a CMOS image sensor, or the like), are provided on a substrate, and the cured film is provided on a surface side (for example, a portion other than light-receiving parts and/or pixels for adjusting color) of a support on which the light-receiving elements are formed or on a side opposite to the surface on which the light-receiving elements are formed.

In addition, in a case where the cured film is used as a light attenuating film, for example, by disposing the light attenuating film so that a part of the light passes through the light attenuating film and then is incident on a light-receiving element, the dynamic range of the solid-state imaging element can be improved.

The solid-state imaging device is equipped with the above-described solid-state imaging element.

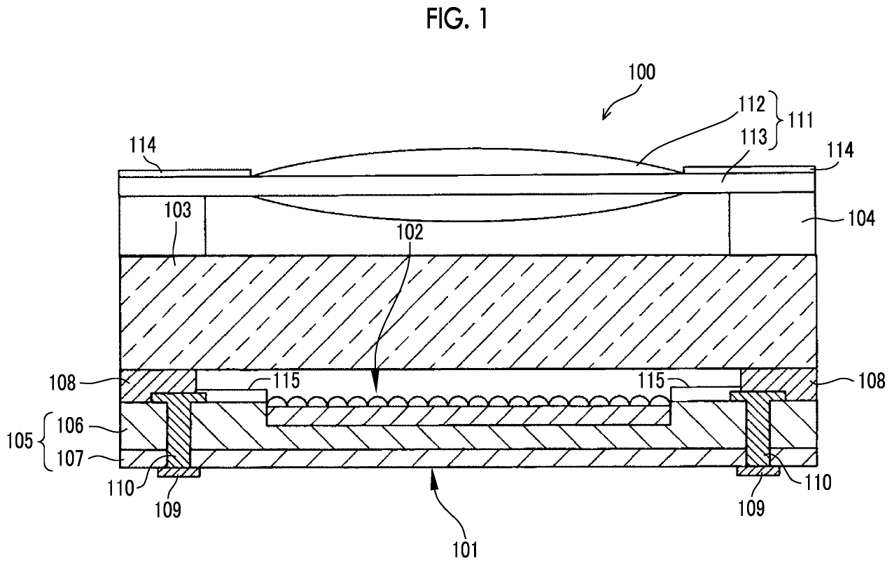

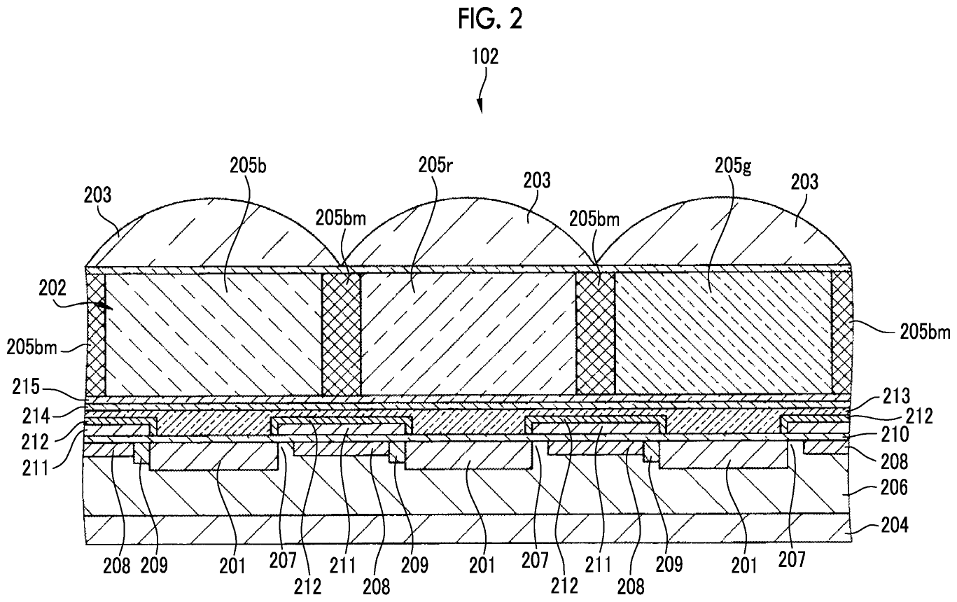

Examples of the configurations of the solid-state imaging device and the solid-state imaging element will be described with reference to FIGS. 1 and 2. In FIGS. 1 and 2, some parts are magnified in disregard of the thickness ratio and/or the width ratio between the parts so that the respective parts are clearly seen.

FIG. 1 is a schematic cross-sectional view illustrating an example of the configuration of the solid-state imaging device including the solid-state imaging element according to the embodiment of the present invention.

As illustrated in FIG. 1, a solid-state imaging device 100 includes a rectangular solid-state imaging element 101 and a transparent cover glass 103 which is held above the solid-state imaging element 101 and seals the solid-state imaging element 101. Further, on the cover glass 103, a lens layer 111 is superposably provided through a spacer 104. The lens layer 111 includes a support 113 and a lens material 112. The lens layer 111 may have a configuration in which the support 113 and the lens material 112 are integrally formed. In a case where stray light is incident on the peripheral edge region of the lens layer 111, due to the diffusion of light, an effect of light condensation on the lens material 112 is weakened, and thus the light reaching an imaging unit 102 is reduced. In addition, noise is also generated due to the stray light. For this reason, a light shielding film 114 is provided in the peripheral edge region of the lens layer 111 so that light is shielded. The cured film according to the embodiment of the present invention can also be used as the light shielding film 114.

The solid-state imaging element 101 carries out photoelectric conversion on an optical image formed on the imaging unit 102 serving as a light-receiving surface of the solid-state imaging element 101, and outputs the converted optical image as an image signal. The solid-state imaging element 101 includes a laminated substrate 105 obtained by laminating two sheets of substrates. The laminated substrate 105 consists of a chip substrate 106 and a circuit board 107 which have the same size and a rectangular shape, and the circuit board 107 is laminated on the rear surface of the chip substrate 106.

As the material of the substrate that is used as the chip substrate 106, for example, a known material can be used.

The imaging unit 102 is provided in the central part of the surface of the chip substrate 106. In addition, a light shielding film 115 is provided in the peripheral edge region of the imaging unit 102. By shielding stray light incident on the peripheral edge region by the light shielding film 115, the generation of a dark current (noise) from a circuit in the peripheral edge region can be prevented. The cured film according to the embodiment of the present invention is preferably used as the light shielding film 115.

A plurality of electrode pads 108 are provided at an edge part of the surface of the chip substrate 106. The electrode pads 108 are electrically connected to the imaging unit 102 through a signal line (a bonding wire can also be used) (not shown) provided on the surface of the chip substrate 106.

On the rear surface of the circuit board 107, external connection terminals 109 are provided at positions approximately below the electrode pads 108, respectively. The external connection terminals 109 are respectively connected to the electrode pads 108 through a through-electrode 110 vertically passing through the laminated substrate 105. In addition, the external connection terminals 109 are connected to a control circuit controlling the driving of the solid-state imaging element 101, an image processing circuit carrying out image processing on an imaging signal output from the solid-state imaging element 101, and the like through a wiring line (not shown).

A schematic cross-sectional view of the imaging unit 102 is illustrated in FIG. 2. As illustrated in FIG. 2, the imaging unit 102 includes the parts, such as a light-receiving element 201, a color filter 202, and a micro lens 203, which are provided on a substrate 204. The color filter 202 has a blue pixel 205b, a red pixel 205r, a green pixel 205g, and a black matrix 205bm. The cured film according to the embodiment of the present invention may be used as the black matrix 205bm.

As the material of the substrate 204, for example, the same material as that of the chip substrate 106 can be used. On the surface layer of the substrate 204, a p-well layer 206 is formed. In the p-well layer 206, the light-receiving elements 201, which consist of an n-type layer and generate and accumulate signal charges by photoelectric conversion, are formed to be arranged in the square lattice form.

On one lateral side of each light-receiving element 201, through a reading gate part 207 on the surface layer of the p-well layer 206, a vertical electric charge transfer path 208 consisting of an n-type layer is formed. In addition, on the other lateral side of each light-receiving element 201, through an element separation region 209 consisting of a p-type layer, a vertical electric charge transfer path 208 belonging to the adjacent pixel is formed. The reading gate part 207 is a channel region for the signal charges accumulated in the light-receiving element 201 to be read out toward the vertical electric charge transfer path 208.

On the surface of the substrate 204, a gate insulating film 210 consisting of an oxide-nitride-oxide (ONO) film is formed. On the gate insulating film 210, vertical electric charge transfer electrodes 211 consisting of polysilicon or amorphous silicon are formed to cover the portions which are approximately immediately above the vertical electric charge transfer path 208, the reading gate part 207, and the element separation region 209. The vertical electric charge transfer electrodes 211 function as driving electrodes for driving the vertical electric charge transfer path 208 and carrying out charge transfer, and as reading electrodes for driving the reading gate part 207 and reading out signal charges. The signal charges are transferred to a horizontal electric charge transfer path and an output part (floating diffusion amplifier), which are not shown in the drawing, in this order from the vertical electric charge transfer path 208, and then output as voltage signals.

On each of the vertical electric charge transfer electrodes 211, a light shielding film 212 is formed to cover the surface of the electrode. The light shielding film 212 has an opening portion at a position immediately above the light-receiving element 201 and shields a region other than the opening portion from light. The cured film according to the embodiment of the present invention may be used as the light shielding film 212.

On the light shielding film 212, a transparent interlayer, which consists of an insulating film 213 consisting of borophosphosilicate glass (BPSG), an insulating film (passivation film) 214 consisting of P—SiN, and a planarization film 215 consisting of a transparent resin or the like, is provided. The color filter 202 is formed on the interlayer.

[Image Display Device]

An image display device according to the embodiment of the present invention is equipped with the cured film according to the embodiment of the present invention.

Examples of the form in which the image display device includes a cured film include a form in which a cured film is contained in a black matrix and a color filter including such a black matrix is used in an image display device.

Next, a black matrix, and a color filter including the black matrix will be described, and a liquid crystal display device including such a color filter will be described as a specific example of the image display device.

<Black Matrix>

It is also preferable that the cured film according to the embodiment of the present invention is contained in the black matrix. The black matrix is incorporated into a color filter, a solid-state imaging element, and an image display device such as a liquid crystal display device in some cases.

Examples of the black matrix include those described above; a black rim provided in the peripheral edge part of an image display device such as a liquid crystal display device; a lattice-formed and/or stripe-shaped black portion between pixels of red, blue, and green; and a dot-like and/or linear black pattern for shielding a thin film transistor (TFT) from light. The definition of the black matrix is described in, for example, “Glossary of liquid crystal display manufacturing device”, written by Yasuhira KANNO, 2nd edition, NIKKAN KOGYO SHIMBUN, LTD., 1996, p. 64.

In order to improve the display contrast, and to prevent image quality deterioration resulting from current leakage of light in a case of an active matrix driving-type liquid crystal display device using a thin film transistor (TFT), the black matrix preferably has high light shielding properties (the optical density OD is 3 or more).

As the method for manufacturing the black matrix, for example, the black matrix can be manufactured in the same manner as the method for manufacturing the cured film. Specifically, by applying the composition onto a substrate to form a composition layer and carrying out exposure and development on the composition layer, a patterned cured film (black matrix) can be manufactured. It is noted that the film thickness of the cured film used as the black matrix is preferably 0.1 to 4.0 μm.

The material of the substrate preferably has a light transmittance of 80% or more for visible light (wavelength of 400 to 800 nm). Examples of such a material include: glass such as soda lime glass, alkali-free glass, quartz glass, and borosilicate glass; and plastic such as a polyester-based resin and a polyolefin-based resin, and from the viewpoints of chemical resistance and heat resistance, alkali-free glass, quartz glass, or the like is preferable.

<Color Filter>

It is also preferable that the cured film according to the embodiment of the present invention is included in a color filter.

Examples of the form in which the color filter includes the cured film include a color filter comprising a substrate and the above-described black matrix. That is, a color filter comprising colored pixels of red, green, and blue which are formed in the opening portion of the black matrix formed on a substrate can be exemplified.

The color filter including a black matrix (cured film) can be manufactured, for example, by the following method.

First, in an opening portion of a patterned black matrix formed on a substrate, a coating film (composition layer) of a composition containing each of pigments corresponding to the respective colored pixels of the color filter is formed. It is noted that as the composition for each color, for example, a known composition can be used; however, in the composition described in the present specification, it is preferable that a composition in which the black coloring material is replaced with a coloring agent corresponding to each pixel is used.

Subsequently, the composition layer is subjected to exposure through a photo mask having a pattern corresponding to the opening portion of the black matrix. Next, colored pixels can be formed in the opening portion of the black matrix by removing non-exposed portions by a development treatment, and then carrying out baking. In a case where the series of operations are carried out using, for example, a composition for each color containing each of red, green, and blue pigments, a color filter having red, green, and blue pixels can be manufactured.

<Liquid Crystal Display Device>

It is also preferable that the cured film according to the embodiment of the present invention is included in a liquid crystal display device. Examples of the form in which the liquid crystal display device includes the cured film include a form in which a liquid crystal display device includes the color filter including the black matrix (cured film) described above.

Examples of the liquid crystal display device according to the present embodiment include a form in which a liquid crystal display device includes a pair of substrates disposed to face each other and a liquid crystal compound sealed in the space between the substrates. The substrates are as described above, for example, as the substrate for a black matrix.

Examples of the specific form of the liquid crystal display device include a laminate including polarizing plate/substrate/color filter/transparent electrode layer/alignment film/liquid crystal layer/alignment film/transparent electrode layer/thin film transistor (TFT) element/substrate/polarizing plate/backlight unit in this order from the user side.

In addition, examples of the liquid crystal display device include the liquid crystal display devices described in “Electronic display device (written by Akio SASAKI, Kogyo CHOSAKAI Publishing Co., Ltd., published in 1990)”, “Display device (written by Sumiaki IBUKI, Sangyo Tosho Publishing Co., Ltd., published in 1989)”, or the like. In addition, examples thereof include the liquid crystal display device described in “Next-Generation Liquid Crystal Display Technology (edited by Tatsuo UCHIDA, Kogyo Chosakai Publishing Co., Ltd., published in 1994)”.

[Infrared Sensor]

It is also preferable that the cured film according to the embodiment of the present invention is included in an infrared sensor.

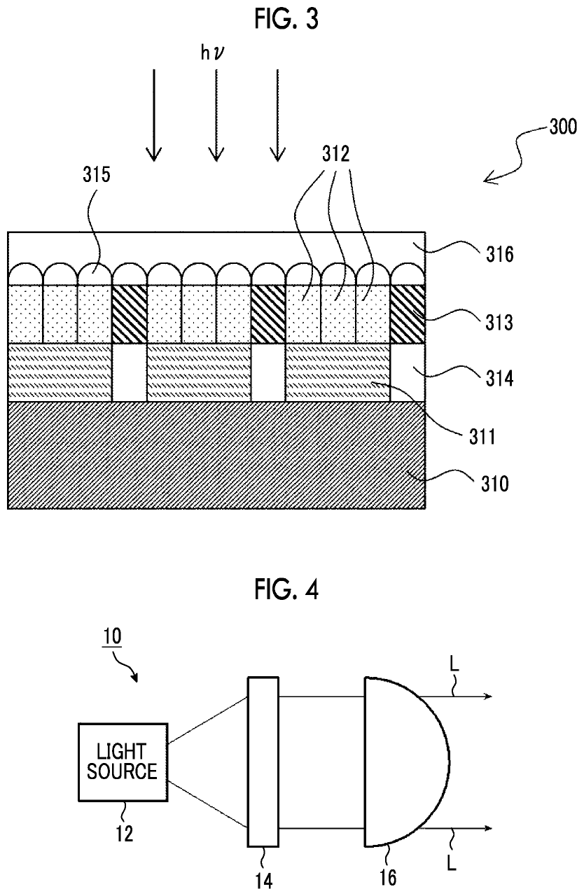

The infrared sensor according to the embodiment will be described with reference to FIG. 3. FIG. 3 is a schematic cross-sectional view illustrating an example of the configuration of an infrared sensor comprising the cured film according to the embodiment of the present invention. An infrared sensor 300 illustrated in FIG. 3 includes a solid-state imaging element 310.

An imaging region provided on the solid-state imaging element 310 is configured by combining an infrared absorption filter 311 and a color filter 312 according to the embodiment of the present invention.

The infrared absorption filter 311 is a film which transmits light (for example, light having wavelengths of 400 to 700 nm) in the visible light range and shields light (for example, light having wavelengths of 800 to 1,300 nm, preferably light having wavelengths of 900 to 1,200 nm, and more preferably light having wavelengths of 900 to 1,000 nm) in the infrared range, and a cured film containing an infrared absorbing agent (the form of the infrared absorbing agent is as described above) as a coloring agent can be used.

The color filter 312 is a color filter in which pixels transmitting or absorbing light having a specific wavelength in the visible light range are formed, for example, a color filter in which pixels of red (R), green (G), and blue (B) are formed, or the like is used, and the form thereof is as described above.

Between an infrared transmitting filter 313 and the solid-state imaging element 310, a resin film 314 (for example, a transparent resin film or the like), which is capable of transmitting light having the wavelength transmitted through the infrared transmitting filter 313, is disposed.

The infrared transmitting filter 313 is a filter which has visible light shielding properties and transmits infrared rays having a specific wavelength, and the cured film according to the embodiment of the present invention can be used, which contains a coloring agent (for example, a perylene compound and/or a bisbenzofuranone compound) absorbing light in a visible light range, and an infrared absorbing agent (for example, a pyrrolo pyrrole compound, a phthalocyanine compound, a naphthalocyanine compound, a polymethine compound, or the like). It is preferable that, for example, the infrared transmitting filter 313 shields light having wavelengths of 400 to 830 nm and transmits light having wavelengths of 900 to 1,300 nm.

On the incidence ray hv side of the color filter 312 and the infrared transmitting filter 313, micro lenses 315 are arranged. A planarization film 316 is formed to cover the micro lenses 315.

In the form illustrated in FIG. 3, the resin film 314 is disposed; however, the infrared transmitting filter 313 may be formed instead of the resin film 314. That is, on the solid-state imaging element 310, the infrared transmitting filter 313 may be formed.

In the form illustrated in FIG. 3, the film thickness of the color filter 312 is the same as the film thickness of the infrared transmitting filter 313, but both the film thicknesses may be different from each other.

In the form illustrated in FIG. 3, the color filter 312 is provided to be closer to the incidence ray hv side than the infrared absorption filter 311, but the order of the infrared absorption filter 311 and the color filter 312 may be switched so that the infrared absorption filter 311 is provided to be closer to the incidence ray hv side than the color filter 312.

In the form illustrated in FIG. 3, the infrared absorption filter 311 and the color filter 312 are laminated to be adjacent to each other, but both the filters are not necessarily adjacent to each other, and another layer may be provided between the filters. The cured film according to the embodiment of the present invention can be used as a light shielding film on an end part of the surface and/or a lateral surface of the infrared absorption filter 311, and in a case of being used in an interior wall of a device of an infrared sensor, the internal reflection and/or the unintended incidence of light on the light-receiving part can be prevented and thus sensitivity can be improved.

According to the infrared sensor, image information can be simultaneously taken in, and thus motion sensing or the like by which a subject whose movement is to be detected is recognized can be carried out. In addition, according to the infrared sensor, distance information can be obtained, and thus images including 3D information and the like can also be captured. Furthermore, the infrared sensor can also be used as a biometric authentication sensor.

Next, a solid-state imaging device to which the above-described infrared sensor is applied will be described.

The solid-state imaging device includes a lens optical system, a solid-state imaging element, an infrared light emitting diode. It is noted that regarding each of the configurations of the solid-state imaging device, reference can be made to paragraphs 0032 to 0036 of JP2011-233983A, the content of which is incorporated into the specification of the present application.

[Headlight Unit]

It is also preferable that the cured film according to the embodiment of the present invention is included, as the light shielding film, in a headlight unit for a vehicle such as an automobile. The cured film according to the embodiment of the present invention, which is included in the headlight unit as the light shielding film, is preferably formed in a patterned manner to shield at least a part of light emitted from a light source.

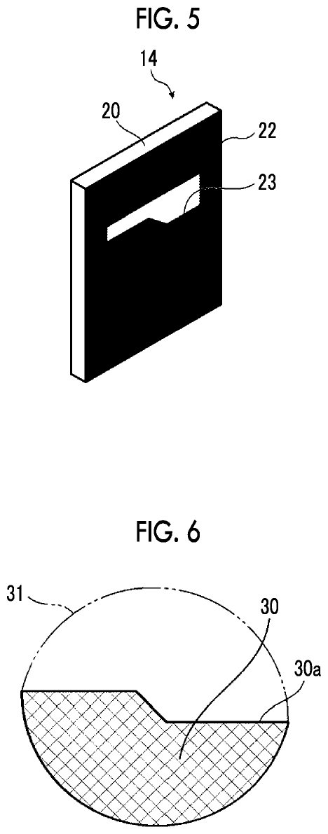

The headlight unit according to the embodiment will be described with reference to FIGS. 4 and 5. FIG. 4 is a schematic view illustrating an example of the configuration of the headlight unit, and FIG. 5 is a schematic perspective view illustrating an example of the configuration of a light shielding unit of the headlight unit.

As illustrated in FIG. 4, a headlight unit 10 includes a light source 12, a light shielding unit 14, and a lens 16, and the light source 12, the light shielding unit 14, and the lens 16 are arranged in this order.

As illustrated in FIG. 5, the light shielding unit 14 has a base body 20 and a light shielding film 22.

In the light shielding film 22, a patterned opening portion 23 for radiating light emitted from the light source 12 into a specific shape is formed. A light distribution pattern radiated from the lens 16 is determined by the shape of the opening portion 23 of the light shielding film 22. The lens 16 projects light L from the light source 12, which has passed through the light shielding unit 14. In a case where a specific light distribution pattern can be radiated from the light source 12, the lens 16 is not necessarily required. The lens 16 is appropriately determined according to an irradiation distance and an irradiation range of the light L.

In addition, the configuration of the base body 20 is not particularly limited as long as the substrate can hold the light shielding film 22. However, the base body 20 is preferably not deformed by the heat of the light source 12, and it is, for example, made of glass.

An example of the light distribution pattern is illustrated in FIG. 5, which is not limited thereto.

In addition, the number of the light sources 12 is also not limited to one, and the light sources may be arranged, for example, in a row or in a matrix. In a case where a plurality of light sources are provided, for example, one light shielding unit 14 may be provided for one light source 12. In this case, the respective light shielding films 22 of a plurality of light shielding units 14 may all have the same pattern or may have different patterns.

The light distribution pattern based on the pattern of the light shielding film 22 will be described.

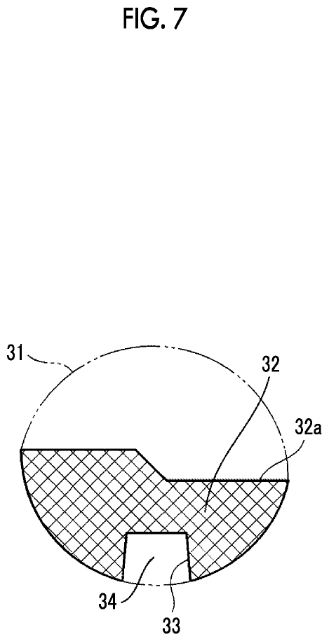

FIG. 6 is a schematic view illustrating an example of the light distribution pattern formed by the headlight unit, and FIG. 7 is a schematic view illustrating another example of the light distribution pattern formed by the headlight unit. It is noted that a light distribution pattern 30 illustrated in FIG. 6 and a light distribution pattern 32 illustrated in FIG. 7 both indicate a region irradiated with light. Further, a region 31 illustrated in FIG. 6 and a region 31 illustrated in FIG. 7 both indicate an irradiation region irradiated by the light source 12 (see FIG. 4) in a case where the light shielding film 22 is not provided.

Due to the pattern of the light shielding film 22, the intensity of light is sharply reduced at an edge 30a, for example, as in the light distribution pattern 30 illustrated in FIG. 6. The light distribution pattern 30 illustrated in FIG. 6 is, for example, a pattern in which light is not flashed at an oncoming vehicle in a case of left-side traveling.

In addition, as in the light distribution pattern 32 illustrated in FIG. 7, a pattern in which a part of the light distribution pattern 30 illustrated in FIG. 6 is notched can also be used. Also in this case, similar to the light distribution pattern 30 illustrated in FIG. 6, the intensity of light is sharply reduced at an edge 32a, and the pattern is, for example, a pattern in which light is not flashed at an oncoming vehicle in a case of left-side traveling. Further, the intensity of light is sharply reduced even at a notched portion 33. Therefore, in a region 34 corresponding to the notched portion 33, a mark indicating a state where the road is curved, inclined upward, inclined downward, or the like can be displayed. This makes it possible to improve the safety during night-time traveling.

In addition, the light shielding unit 14 is not limited to being fixedly disposed between the light source 12 and the lens 16, and a configuration in which the light shielding unit 14 is allowed to enter between the light source 12 and the lens 16, as necessary, by a driving mechanism (not shown) to obtain a specific light distribution pattern may be adopted.

In addition, in the light shielding unit 14, a shade member capable of shielding the light from the light source 12 may be formed. In this case, a configuration in which the shade member is allowed to enter between the light source 12 and the lens 16, as necessary, by the driving mechanism (not shown) to obtain a specific light distribution pattern may be adopted.

### EXAMPLES

Hereinafter, the present invention will be described in more detail based on Examples. The materials, the amounts and proportions of the materials used, the details of treatments, the procedure of treatments, and the like shown in the following Examples can be appropriately modified as long as the gist of the present invention is maintained. Accordingly, the scope of the present invention will not be restrictively interpreted by the following Examples.

<<Test X>>

[Production of Composition]

Hereinafter, each component used in the preparation of the composition will be described.

[Black Pigment]

Particles produced by the method described below were used as the black pigment in the preparation of the composition.

Among the particle described below, Zr-2 to Zr-9 are coated particles.

<Production of Zr-1 (Uncoated Zirconium Nitride)>

7.3 g of a metal magnesium powder having an average primary particle diameter of 150 μm and 9.0 g of a magnesium nitride powder having an average primary particle diameter of 200 nm were added to 7.4 g of a monoclinic zirconium dioxide powder having an average primary particle diameter of 50 nm, as calculated from a specific surface area measured by the BET method, and the mixture was uniformly mixed by a reaction device in which a graphite boat was internally mounted in a quartz-made glass tube. Here, the adding amount of the metal magnesium was 5.0 molar times that of zirconium dioxide, and the adding amount of the magnesium nitride was 0.5 molar times that of zirconium dioxide. This mixture was calcined at a temperature of 700° C. for 60 minutes in an atmosphere of a nitrogen gas to obtain a calcined product. This calcined product was dispersed in 1 liter of water, 10% hydrochloric acid was gradually added thereto, the resultant was washed while keeping the pH at 1 or more and the temperature at 100° C. or lower, then the pH was adjusted to 7 to 8 with 25% aqueous ammonia, and filtration was carried out. The filtration solid content was redispersed in water at 400 g/liter, and the resultant was subjected again to the washing with acid and the pH adjustment with aqueous ammonia in the same manner as described above, and then filtered. After the washing with acid and the pH adjustment with aqueous ammonia were repeated twice as described above, the filtration product was dispersed in ion exchange water at 500 g/liter expressed in terms of solid contents, heating and stirring at 60° C. and pH adjustment to 7 were carried out, and then the resultant was filtered with a suction filtration device, further washed with an equal amount of ion exchange water, and dried by a hot air dryer at a set temperature of 120° C. to obtain a zirconium nitride powder Zr-1.

<Production of Zr-2 (Zirconium Nitride Coated with Silica)>

12 mol of ethanol as alcohol with respect to 0.1 mol of Zr-1 was added, Zr-1 was dispersed in the ethanol, and the resultant was subjected to wet-type pulverization by a beads mill to obtain a dispersion liquid of Zr-1. Subsequently, 6 mol of ethanol for adjusting the concentration was added to the dispersion liquid of Zr-1, and then 1×10⁻² mol of tetramethyl orthosilicate was added as a silica source for forming a silica film. Next, 1×10⁻³ mol of sodium hydroxide as an alkali source (reaction initiator) was added to the dispersion liquid of Zr-1 to which the tetramethyl orthosilicate had been added, and a reaction with the dispersion liquid was started. Moreover, this dispersion liquid was washed, dried, and then calcined to obtain a powder Zr-2 in which the zirconium nitride powder Zr-1 was coated with a silica film.

In addition, the washing of the dispersion liquid was carried out by passing the dispersion liquid through a centrifugal separator, and then passing the dispersion liquid through an ion exchange resin-made filter, in order to remove impurities from the dispersion liquid. Moreover, the calcination was a treatment of holding at 350° C. for 5 hours in an atmosphere of a nitrogen gas.

In Zr-2, the content of the metal oxide (metal oxide coating layer consisting of silica) with respect to the total mass of the coated particle was 5% by mass.

It is noted that the presence or absence of the coating was confirmed by the FE-STEM/EDS, and the above content was confirmed by the ESCA.

<Production of Zr-3 to Zr-9 (Zirconium Nitrides Coated with Alumina)>

Zr-1 was mixed with water, and the mixture was adjusted to an aqueous slurry having a powder weight of 100 g/liter using a sand mill, thereby obtaining an aqueous dispersion liquid having a powder concentration of 100 g/liter. This slurry was heated to 60° C. while stirring, a sodium aluminate aqueous solution and a dilute sulfuric acid solution were simultaneously added for 30 minutes while maintaining the temperature and maintaining the pH of the aqueous slurry at 7.0, followed by aging for 30 minutes.

Thereafter, the obtained neutralization reaction product was filtered, washed, and dried at a temperature of 120° C. for 5 hours to obtain a powder (zirconium nitride coated with alumina) in which a powder base of zirconium nitride was coated with an alumina film.

The adding amount of the sodium aluminate aqueous solution mentioned above was in a range of an amount corresponding to 0.1 to 25 parts by mass as Al₂O₃ with respect to the 100 parts by mass of Zr-1.

The adding amount of the sodium aluminate aqueous solution was adjusted to obtain Zr-3 to Zr-9, which are zirconium nitride coated with the metal oxide coating layer (alumina) in the following coating amount.

| Type | Coating amount |
|---|---|
| Zr-3 | 1% by mass |
| Zr-4 | 2% by mass |
| Zr-5 | 3% by mass |
| Zr-6 | 5% by mass |
| Zr-7 | 7% by mass |
| Zr-8 | 8% by mass |
| Zr-9 | 10% by mass |

The coating amount refers to the content of the metal oxide (metal oxide coating layer consisting of alumina) with respect to the total mass of the coated particle.

It is noted that the presence or absence of the coating was confirmed by the FE-STEM/EDS, and the coating amount was confirmed by the ESCA.

<Production of Ti-1>

100 g of titanium oxide MT-150A (product name; manufactured by TAYCA CORPORATION) having an average primary particle diameter of 15 nm, 25 g of silica particles AEROPERL (registered trade name) 300/30 (manufactured by Evonik Industries AG) having a BET surface area of 300 m²/g, and 100 g of dispersing agent Disperbyk190 (product name; manufactured by BYK Additives & Instruments) were weighed, and these were added to 71 g of ion exchange water to obtain a mixture.

Then, the mixture was treated for 20 minutes at a revolution speed of 1,360 rpm and a rotation speed of 1,047 rpm using MAZERUSTAR KK-400 W manufactured by KURABO INDUSTRIES LTD. to obtain a mixed solution. A quartz vessel was filled with this mixed solution and heated to 920° C. in an oxygen atmosphere using a small-sized rotary kiln (manufactured by Motoyama). Then, the atmosphere in the small-sized rotary kiln was replaced with nitrogen, and at the same temperature, an ammonia gas was allowed to flow into the small-sized rotary kiln at 100 mL/min for 5 hours to carry out the nitridization reduction treatment. After the completion of the treatment, the collected powder was pulverized in a mortar to obtain titanium black Ti-1 [a substance to be dispersed containing titanium black (an oxynitride of titanium) particles and Si atoms, specific surface area:73 m²/g)] containing Si atoms.

<Production of V-1>

The temperature of a vanadium oxide powder (specific surface area: 1 to 10 m²/g) was raised to 800° C. at a temperature raising rate of 7° C./min under a nitrogen atmosphere, and then an ammonia gas was allowed to flow to carry out the nitridization reduction so that the blackness (the L value) in the black particles to be finally obtained was 14.9, the oxygen content was 6.4% by mass, and the nitrogen content was 19% by mass. The obtained product obtained by the nitridization reduction was pulverized using a hammer mill to obtain single-particle black particles V-1 (an oxynitride of vanadium).

<Production of Vc-1>

An oxynitride of vanadium Vc-1, coated with silica, was obtained in the same manner except that in the production of Zr-2, the raw material was changed from Zr-1 to V-1.

In Vc-1, the content of the metal oxide (metal oxide coating layer consisting of silica) with respect to the total mass of the coated particle was 5% by mass.

It is noted that the presence or absence of the coating was confirmed by the FE-STEM/EDS, and the above content was confirmed by the ESCA.

<Production of Nb-1>

The temperature of a niobium oxide powder (specific surface area: 1 to 10 m²/g) was raised to 800° C. at a temperature raising rate of 7° C./min under a nitrogen atmosphere, and then an ammonia gas was allowed to flow to carry out the nitridization reduction so that the blackness (the L value) in the black particles to be finally obtained was 14.9, the oxygen content was 6.4% by mass, and the nitrogen content was 19% by mass. The obtained product obtained by the nitridization reduction was pulverized using a hammer mill to obtain single-particle black particles Nb-1 (an oxynitride of niobium).

<Production of Nbc-1>

An oxynitride of niobium Nbc-1, coated with silica, was obtained in the same manner except that in the production of Zr-2, the raw material was changed from Zr-1 to Nb-1.

In Nbc-1, the content of the metal oxide (metal oxide coating layer consisting of silica) with respect to the total mass of the coated particle was 5% by mass.

It is noted that the presence or absence of the coating was confirmed by the FE-STEM/EDS, and the above content was confirmed by the ESCA.

[Dispersing Agent]

The following dispersing agent was used.

Dispersing Agent A

The dispersing agent A is a dispersing agent produced by the production method described below.

### Synthesis Example A1: Synthesis of Macromonomer A-1

ε-caprolactone (1,044.2 g), δ-valerolactone (184.3 g), and 2-ethyl-1-hexanol (71.6 g) were introduced into a three-neck flask having a volume of 3,000 mL to obtain a mixture. Next, the above-described mixture was stirred while blowing nitrogen. Next, Disperbyk 111 (12.5 g, manufactured by BYK Additives & Instruments, a phosphoric acid resin) was added to the mixture, and the obtained mixture was heated to 90° C. After 6 hours, using ¹H-nuclear magnetic resonance (NMR), it was confirmed that a signal derived from 2-ethyl-1-hexanol in the mixture had disappeared, and then the mixture was heated to 110° C. After the polymerization reaction was continued at 110° C. for 12 hours under nitrogen, the disappearance of the signals derived from ε-caprolactone and δ-valerolactone was confirmed by ¹H-NMR, and the molecular weight of the resulting compound was measured by gel permeation chromatography (GPC). After confirming that the molecular weight of the compound reached a desired value, 2,6-di-t-butyl-4-methylphenol (0.35 g) was added to the mixture containing the above compound, and then 2-methacryloxyethyl isocyanate (87.0 g) was added dropwise to the obtained mixture over 30 minutes. Six hours after the completion of the dropwise addition, the disappearance of the signal derived from 2-methacryloxyethyl isocyanate (MOI) was confirmed by ¹H-NMR, and then propylene glycol monomethyl ether acetate (PGMEA) (1,387.0 g) was added to the mixture, whereby a macromonomer A-1 solution (2,770 g) having a concentration of 50% by mass was obtained. The weight-average molecular weight of the obtained macromonomer A-1 was 6,000.

### Synthesis Example P-1: Synthesis of Dispersing Agent A

A macromonomer A-1 (200.0 g), methacrylic acid (hereinafter, also referred to as “MAA”, 60.0 g), benzyl methacrylate (hereinafter, also referred to as “BzMA”, 40.0 g), propylene glycol 1-monomethyl ether 2-acetate (PGMEA, 366.7 g) were introduced into a three-neck flask having a volume of 1,000 mL to obtain a mixture. The above mixture was stirred while blowing nitrogen. Next, the mixture was warmed to 75° C. while allowing nitrogen to flow into the flask. Next, dodecyl mercaptan (5.85 g), then 2,2′-azobis(methyl 2-methylpropionate) (1.48 g, hereinafter, also referred to as “V-601”) were added to the mixture to initiate the polymerization reaction. After heating the mixture at 75° C. for 2 hours, V-601 (1.48 g) was further added to the mixture. After 2 hours, V-601 (1.48 g) was further added to the mixture. After the reaction for 2 hours, the mixture was further added to 90° C. and stirred for 3 hours. By the above operation, the polymerization reaction was completed, and the dispersing agent A was obtained.

Dispersing Agent B

The dispersing agent B is a dispersing agent produced by the production method described below.

Tetrabutylammonium bromide (TBAB, 7.5 g) and p-methoxyphenol (MEHQ, 0.13 g) were added to a solution of the dispersing agent A obtained in Synthesis Example P-1 in atmospheric air, and then glycidyl methacrylate (GMA, 66.1 g) was added dropwise thereto. After the completion of the dropwise addition, the reaction was continued in the air for 7 hours, and then the completion of the reaction was confirmed by acid value measurement. PGMEA (643.6 g) was added to the resulting mixture to obtain a 20% by mass solution of the dispersing agent B. The weight-average molecular weight of the obtained dispersing agent B was 35,000, and the acid value thereof was 50 mgKOH/mg.

The structures of the dispersing agents C to H are shown below.

In the structural formulae of the dispersing agents C to F, the numerical value noted to each repeating unit indicates the mass ratio.

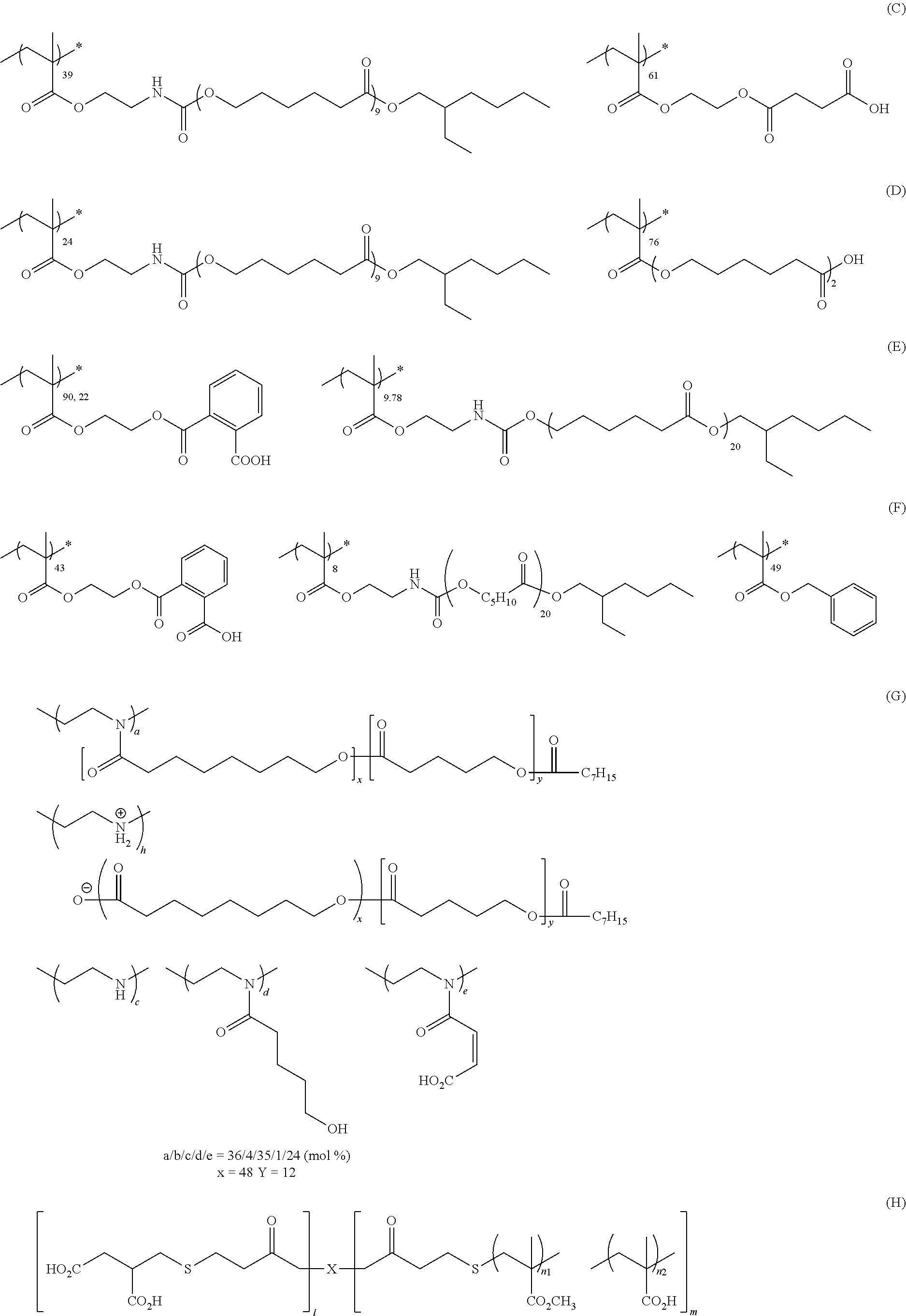

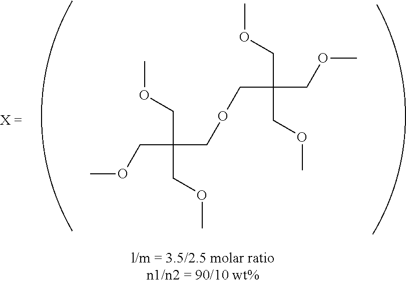

Dispersing agent I: A resin containing structural units (1a) to (3a) shown below, having an amine value of 75 mgKOH/g, and having an acid value of 0 mgKOH/g

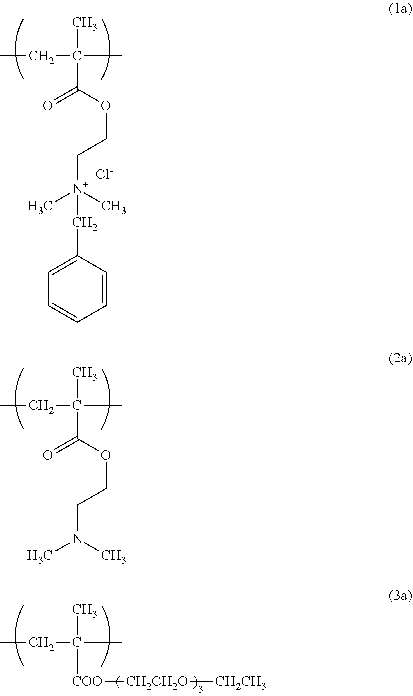

Among the dispersing agents A to I, the dispersing agents A to G and I correspond to a dispersing agent containing a graft structure.

The dispersing agent H corresponds to a dispersing agent containing a radial structure.

Among the dispersing agents A to I, the dispersing agents A to H correspond to a dispersing agent containing an acid group.

The acid value (unit: mgKOH/g), the amine value (unit: mgKOH/g), and the molecular weight (the weight-average molecular weight) of the solid content of each of the dispersing agents A to I are as follows.

| Kind | Acid value | Amine value | Molecular weight |
|---|---|---|---|
| Dispersing agent A | 120 | — | more than 3,000 |
| Dispersing agent B | 50 | — | 35,000 |
| Dispersing agent C | 50 | — | 24,000 |
| Dispersing agent D | 75 | — | 20,000 |
| Dispersing agent E | 100 | — | 40,000 |
| Dispersing agent F | 60 | — | 33,000 |
| Dispersing agent G | 36 | 47 | 21,000 |
| Dispersing agent H | 190 | — | 11,000 |
| Dispersing agent I | — | 75 | more than 3,000 |

[Resin (Alkali-Soluble Resin)]

The resin (the alkali-soluble resin) shown below was used.
A-1: A resin having the following structure (solid content: 40%, solvent: propylene glycol monomethyl ether, see the structure below for the structure of the solid content (in terms of the resin), where the compositional ratio shown in the structure is the molar ratio, weight-average molecular weight of resin: 11,000, acid value of resin: 70 mgKOH/g)

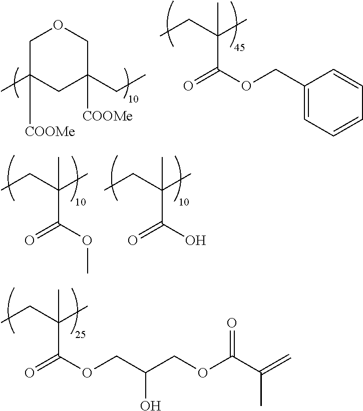

A-2: A copolymer of benzyl methacrylate and methacrylic acid (7:3, in terms of molar ratio) (weight-average molecular weight: 30,000, acid value: 112.8 mgKOH/g, a solution of 40% by mass of PGMEA)

[Polymerizable Compound]

The polymerizable compound shown below was used.
M1: A mixture of compounds having the following structure (the compositional ratio indicated in the structure is the mass ratio)

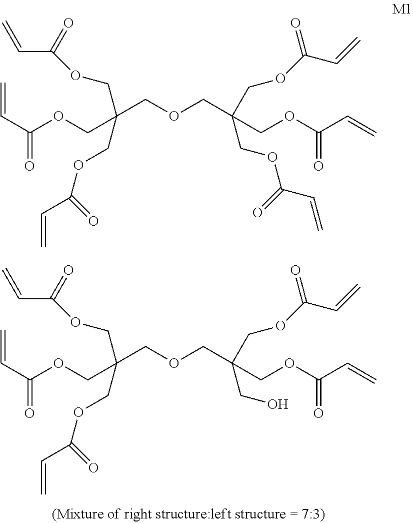

M2: A mixture of compounds having the following structure (the compositional ratio indicated in the structure is in terms of % by mass)

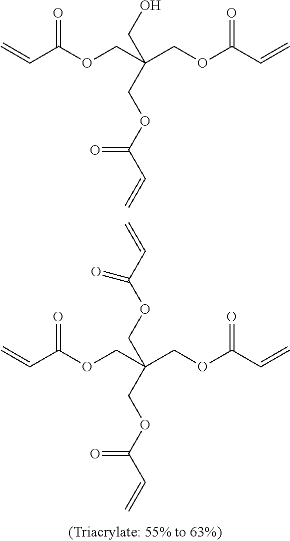

M3: A compound having the following structure

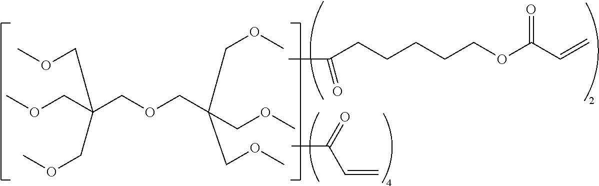

M4: A mixture of compounds having the following structures

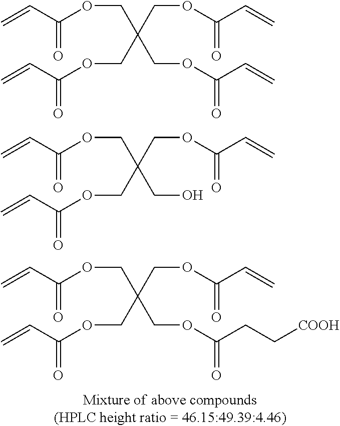

[Polymerization Initiator]

The following polymerization initiators (photopolymerization initiators) were used. In the polymerization initiators shown below, I-1 to I-8 are photopolymerization initiators which are oxime compounds. I-9 is a photopolymerization initiator other than the oxime compound.
I-1: The polymerization initiator of Formula (I-1)
I-2: Irgacure OXE01 (product name, manufactured by BASF Japan Ltd.)
I-3: Irgacure OXE02 (product name, manufactured by BASF Japan Ltd.)
I-4: The polymerization initiator of Formula (I-4)
I-5: The polymerization initiator of Formula (I-5)
I-6: The polymerization initiator of Formula (I-6)
I-7: ADEKAARKLS NCI-831 (manufactured by ADEKA CORPORATION)
I-8: N-1919 (manufactured by ADEKA CORPORATION)
I-9: Omnirad 907 (manufactured IGM Resins B.V.)

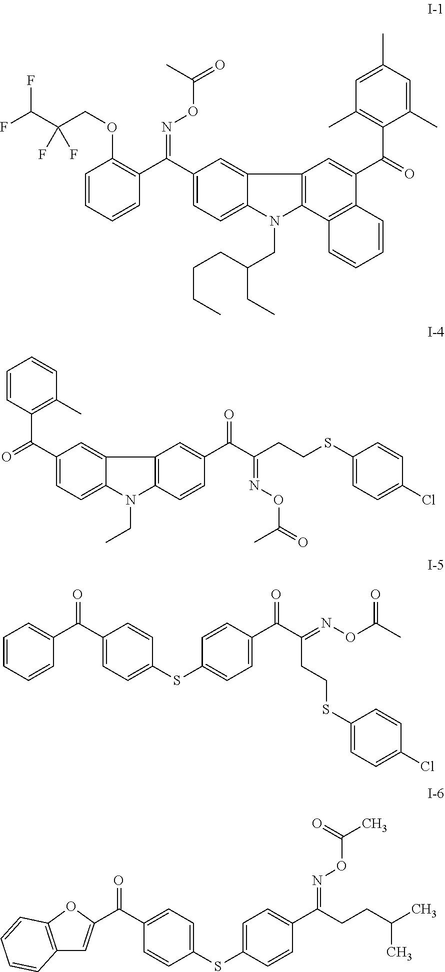 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CC(=O)O/N=C(\CCC(C)C)c1ccc(Sc2ccc(C(=O)c3cc4ccccc4o3)cc2)cc1]

[Surfactant]

The surfactant shown below was used.
F-1: A surfactant (weight-average molecular weight (Mw)=15,311) represented by the following formula

However, in the following formula, structural units represented by (A) and (B) are 62% by mole and 38% by mole, respectively. In the structural unit represented by (B) in the formula, a, b, and c each satisfy relationships of a+c=14 and b=17.

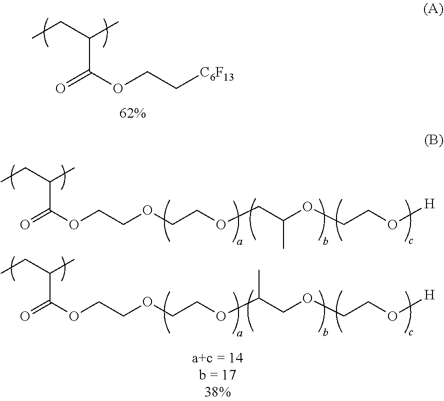

[Polymerization Inhibitor]

The polymerization inhibitor shown below was used.
PI-1: p-methoxyphenol

[Organic Solvent]

The organic solvents shown below were used.
PGMEA: Propylene glycol monomethyl ether acetate
Cyclopentanone

[Silica Particle]

Silica particles produced by the method described below were used to prepare the composition.

<Preparation of Silica Particle Dispersion Liquid>

### Synthesis Example 1: Production of Silica Particle Dispersion Liquid PS-1

4 g of KBM-503 (manufactured by Shin-Etsu Chemical Co., Ltd., 3-methacryloxypropyl trimethoxysilane), 0.5 g of 10% by mass formic acid aqueous solution, and 1 g of water were mixed with 100 g of THRULYA 4110 (manufactured by JGC Catalysts and Chemicals Ltd., solid content: 20%, isopropyl alcohol solvent, hollow silica sol, average primary particle diameter: 60 nm) to obtain a mixed solution. The obtained mixed solution was stirred at 60° C. for 3 hours. Moreover, the solvent in the mixed solution was replaced with 1-methoxy-2-propanol using a rotary evaporator. The concentration of the solid contents in the mixed solution was checked, and the mixed solution was further diluted with the required amount of 1-methoxy-2-propanol to obtain a silica particle dispersion liquid PS-1 (a dispersion liquid of silica which is hollow particles subjected to the surface modification with a methacryl group) having a solid content of 20% by mass.

### Synthesis Example 2: Production of Silica Particle S-1

The silica particle dispersion liquid PS-1 (the dispersion liquid having a solid content of 20% by mass and produced above) (30.0 g), X-22-2404 (manufactured by Shin-Etsu Chemical Co., Ltd., one-terminal methacryl-modified silicone oil, 1.8 g), and propylene glycol monomethyl ether acetate (PGMEA, 28.2 g) were placed in a three-neck flask, and the contents of the flask were heated to 80° C. in a nitrogen atmosphere. An initiator V-601 (manufactured by FUJIFILM Wako Pure Chemical Corporation, 0.01 g) was added to this flask, and the mixture was stirred for 3 hours. V-601 (0.02 g) was further added to this flask, and the mixture was stirred for 2 hours. Then, the contents of the flask were subjected to microfiltration, and the obtained filtrate was denoted by silica particles S-1.

### Synthesis Example 3: Production of Silica Particle S-2

Silica particles S-2 were obtained in the same manner as in Synthesis Example 2 except that the silica particle dispersion liquid PS-1 of Synthesis Example 2 was changed to a PGM-AC-4130Y dispersion liquid.

It is noted that the PGM-AC-4130Y dispersion liquid is a dispersion liquid obtained by adding 1-methoxy-2-propanol to PGM-AC-4130Y (manufactured by Nissan Chemical Corporation, solid content of 32% by mass, 1-methoxy-2-propanol solvent, a dispersion liquid of silica which is solid particles subjected to the surface modification with a methacryl group) so that the solid content is 20% by mass.

[Preparation of Composition (Photosensitive Composition)]

A composition (a photosensitive composition) was prepared by the method described below.

<Preparation of Pigment Dispersion Liquid 1 (Dispersion Liquid 1)>

First, a pigment dispersion liquid (a dispersion liquid) was prepared.

The following components were mixed in the following formulation to prepare a dispersion liquid 1.
Any one of black pigments Zr-2 to Zr-9, Vc-1, or Nbc-1: 25 parts by mass
A solution of 30% by mass of PGMEA of any one of the dispersing agents A to I (a solution in which any one of the dispersing agents A to I is dissolved in PGMEA at a content of 30% by mass with respect to the total mass of the solution): 25 parts by mass
Cyclopentanone: 50 parts by mass
Silica particles S-1 or S-2 as desired: 2.08 parts by mass.

The silica particles S-1 or S-2 were added to the dispersion liquid 1 only in a case where the composition to be finally prepared contained silica particles.

(Dispersion Conditions)

The mixture of the above components was subjected to a dispersion treatment using NPM-Pilot manufactured by Shinmaru Enterprises Corporation under the following conditions to obtain a dispersion liquid 1.
Bead diameter: φ0.05 mm, (YTZ, zirconia beads, manufactured by NIKKATO Corporation)
Bead filling rate: 65% by volume
Circumferential speed of mill: 10 m/sec
Circumferential speed of separator: 13 m/s
Amount of mixed solution subjected to dispersion treatment: 15 kg
Circulation flow rate (pump supply rate): 90 kg/hour
Temperature of treatment liquid: 45° C.
Cooling water: water
Treatment time: 22 hours

<Preparation of Pigment Dispersion Liquid 2 (Dispersion Liquid 2)>

The following components were mixed in the following formulation to prepare a dispersion liquid 2. The mixing conditions are the same as in the case of the dispersion liquid 1.
Any one of black pigments Zr-1, Ti-1, V-1, or Nb-1: 25 parts by mass
A solution of 30% by mass of PGMEA of any one of the dispersing agents A to I: 25 parts by mass
Cyclopentanone: 50 parts by mass

<Preparation of Composition>

The dispersion liquid 1, the dispersion liquid 2 to be added as desired, a resin (an alkali-soluble resin), a polymerizable compound, a polymerization initiator, a surfactant, a polymerization inhibitor, PGMEA for solid content adjustment to be added as desired, and each component in pure water for moisture content adjustment were mixed to prepare a composition of each example. The mixing ratio of each component in each composition was adjusted so that the composition to be finally obtained satisfied the kind and the mass ratio of the solid content, the solid content concentration, and the moisture content, as shown in the latter part of the table.

Before the preparation of the composition, the organic solvent to be used (including the organic solvent to be used for the preparation of the dispersion liquid and the like) was subjected to distillation and a drying treatment using a desiccant to remove water, and the organic solvent from which moisture had been removed was used for the preparation of the composition. After mixing each component, it was confirmed that the moisture content of the obtained composition (the composition in a state where pure water was not added, which is shown below) was 0.001% by mass or less, and then a desired amount of pure water was added to the above composition to adjust it to a composition having the moisture content (in terms of % by mass) shown in the table.

In the table, “Particle 1” and “Particle 2” indicate the amount or the kind of the black pigment introduced by the dispersion liquid 1 and the dispersion liquid 2, respectively. “Dispersing agent 1” and “Dispersing agent 2” indicate the amount or the kind of the dispersing agent introduced by the dispersion liquid 1 and the dispersion liquid 2, respectively.

The moisture content was measured by the Karl Fischer method according to the known method. Specifically, the moisture content of the measurement sample was measured using a Karl Fischer moisture meter (KF-06 manufactured by Mitsubishi Chemical Holdings Corporation), and the moisture content was determined as the moisture content/the mass of the measurement sample×100.

[Evaluation]

Regarding the composition of each example, the following evaluations were carried out.

[Moisture Resistance]

The composition was applied onto an 8-inch glass substrate by spin coating to form a coating film at a rotation speed at which a cured film having an optical density (OD) of 3 could be formed with respect to light having a wavelength of 940 nm. The coating film was subjected to a heat treatment at 100° C. for 2 minutes on a hot plate to obtain a dried film. Next, using an i-line stepper exposure device FPA-5510 iZa (manufactured by Canon Inc.), the dried film was exposed at an exposure amount of 500 mJ/cm² through a reticle with which a region of 20 μm×20 μm was exposed with light having a wavelength of 365 nm. Then, the glass substrate on which the exposed dried film was formed was placed on a horizontal rotary table of a spin shower developing machine (DW-30 Type, manufactured by Chemitronics Co., Ltd.), and subjected to a puddle development at 23° C. for 60 seconds using CD-2000 (an organic alkali liquid developer, manufactured by FUJIFILM Electronic Materials Co., Ltd.). Next, the glass substrate after the puddle development was fixed on the above horizontal rotary table by a vacuum chuck method, a rinse treatment was carried out by supplying pure water from a jet nozzle from above the rotation center in a shower-like manner while rotating the glass substrate at a rotation speed of 50 rpm by a rotating device, whereby a glass substrate having a pattern of 20 um×20 um formed on the substrate was produced. The obtained pattern-formed substrate was subjected to heat treatment at 220° C. for 1 hour using a clean oven (HIGH TEMPERATURE CLEAN OVEN CLH-300S, manufactured by Koyo Thermo Systems Co., Ltd.) to obtain a cured film (a glass substrate with a cured film).

The obtained cured film (the glass substrate with a cured film) was stored at a humidity of 85% and a temperature of 85° C. for 2,000 hours, and the spectrums before and after the storage were obtained to measure the optical density (OD) at 400 to 700 nm by using UV-3600 (manufactured by Shimadzu Corporation). The moisture resistance was evaluated according to the following criteria.

A: The maximum value of the change of the light shielding properties (the OD) at a wavelength of 400 to 700 nm before and after being subjected to the moisture resistance environment is less than 2%.

B: The maximum value of the change of the light shielding properties (the OD) at a wavelength of 400 to 700 nm before and after being subjected to the moisture resistance environment is 2% or more and less than 5%.

C: The maximum value of the change of the light shielding properties (the OD) at a wavelength of 400 to 700 nm before and after being subjected to the moisture resistance environment is 5% or more.

[Dispersibility (Dispersion Stability)]

50 g of the composition immediately after preparation was placed in a 100 mL glass container, the container was sealed, and the container was allowed to stand at 45° C. for 7 days. After being allowed to stand, the change in viscosity before standing and after standing was measured, and the dispersibility (the dispersion stability) was evaluated according to the following criteria.

The change in viscosity was determined based on the viscosity before standing (100%).

In addition, the viscosity was measured in an environment of 25° C. using a cone plate type viscometer (manufactured by TOKI SANGYO Co., Ltd., model number: RE-85L).

A: The rate of change in viscosity was less than 5%.

B: The rate of change in viscosity was 5% or more and less than 10%.

C: The rate of change in viscosity was 10% or more.

[Light Shielding Properties (Against Visible Light)]

The composition was applied onto a glass plate (Eagle XG, Corning Inc.) having a thickness of 0.7 mm and an area of a square of 10 cm×10 cm by spin coating to form a coating film at a rotation speed at which the thickness of the dried film became 1.5 μm, and the coating film was subjected to a heat treatment at 100° C. for 2 min on a hot plate to obtain a dried film. With respect to the obtained dried film, the optical density (OD) with respect to light having a wavelength of 400 to 700 nm was measured by using UV-3600 (manufactured by Shimadzu Corporation). The minimum OD with respect to 400 to 700 nm was checked, and the spectrum (the light shielding properties) was evaluated according to the following criteria.

A: OD>3.0

B: 3.0≥OD>2.0

C: 2.0≥OD

[Light Shielding Properties (940 nm)]

The composition was applied onto a glass plate (Eagle XG, Corning Inc.) having a thickness of 0.7 mm and an area of a square of 10 cm×10 cm by spin coating to form a coating film at a rotation speed at which the thickness of the dried film became 1.5 μm, and the coating film was subjected to a heat treatment at 100° C. for 2 min on a hot plate to obtain a dried film. With respect to the obtained dried film, the optical density (OD) with respect to light having a wavelength of 940 nm was measured by using UV-3600 (manufactured by Shimadzu Corporation). The spectrum (the light shielding properties) was evaluated according to the following criteria.

A: OD>3.0

B: 3.0≥OD>2.0

C: 2.0≥OD

[Patterning Properties]

The composition was applied onto an 8-inch silicon wafer substrate by spin coating to form a coating film at a rotation speed at which a cured film having an optical density (OD) of 3 could be formed with respect to light having a wavelength of 940 nm. The coating film was subjected to a heat treatment at 100° C. for 2 minutes on a hot plate to obtain a dried film. Next, using an i-line stepper exposure device FPA-5510 iZa (manufactured by Canon Inc.), the dried film was exposed at an exposure amount of 500 mJ/cm² through a reticle with which a region of 20 μm×20 μm was exposed with light having a wavelength of 365 nm. Then, the silicon wafer substrate on which the exposed dried film was formed was placed on a horizontal rotary table of a spin shower developing machine (DW-30 Type, manufactured by Chemitronics Co., Ltd.), and subjected to a puddle development at 23° C. for 60 seconds using CD-2000 (an organic alkali liquid developer, manufactured by FUJIFILM Electronic Materials Co., Ltd.). Next, the silicon wafer substrate after the puddle development was fixed on the above horizontal rotary table by a vacuum chuck method, a rinse treatment was carried out by supplying pure water from a jet nozzle from above the rotation center in a shower-like manner while rotating the silicon wafer substrate at a rotation speed of 50 rpm by a rotating device, whereby a silicon wafer substrate having a pattern of 20 um×20 um formed on the substrate was produced. The obtained pattern-formed substrate was subjected to heat treatment at 220° C. for 1 hour using a clean oven (HIGH TEMPERATURE CLEAN OVEN CLH-300S, manufactured by Koyo Thermo Systems Co., Ltd.) to obtain a cured film (a substrate with a cured film).

The obtained cured film (the substrate with a cured film) was observed with a cross-sectional scanning electron microscope (SEM), and the patterning properties were evaluated according to the following criteria.

A: The width of the space between the cured film and the substrate (the width at which the peeling of the cured film has occurred) is 5 μm or less from the pattern edge.

B: The width of the space between the cured film and the substrate (the width at

which the peeling of the cured film has occurred) is 5 μm or more from the pattern edge. C: A pattern of 20 um×20 um is peeled off, and thus measurement is impossible.

[Alignment Mark Visibility]

The composition was applied onto an 8-inch silicon substrate having an alignment mark by spin coating to form a coating film at a rotation speed at which a dried film having an optical density (OD) of 3 could be formed with respect to light having a wavelength of 940 nm. The coating film was subjected to a heat treatment at 100° C. for 2 minutes on a hot plate to obtain a dried film (a silicon substrate with a dried film). Three such silicon substrates with a dried film were produced using each composition. Next, the visibility of the alignment mark was evaluated from the following viewpoints using an i-line stepper exposure device FPA-5510 iZa (manufactured by Canon Inc.).

A: Alignment marks are visible in three substrates among the three substrates.

B: Alignment marks are visible in one or two substrates among the three substrates (not visible in one or two substrates)

C: Alignment marks are not visible in three substrates among the three substrates.

[Results]

The table below shows the formulation of the solid content and the characteristics of the composition used in each test example, as well as the test results thereof.

In the table, the amount of each component described in the column of “Content of solid content” indicates the content (in terms of % by mass) of each component with respect to the total solid content of the composition. The content of each component described in the column of “Content of solid content” is the content of the solid content itself of each component. For example, a resin (an alkali-soluble resin) is subjected to the preparation of a composition in a state of a dispersion solution in which the resin (the solid content) is dissolved in an organic solvent, where the value of the content (in terms of % by mass) of the resin described in the table indicates the content of the resin (the solid content) itself with respect to the total solid content of the composition.

In the table, the column of “Kind” indicates a more specific kind of each component used in the preparation of the composition. In addition, the description of “M2/M4=83/17” in the column of “Polymerizable compound” present below the column of “Kind” means that M2 and M4 are used in combination at a ratio of M2/M4=83/17 (in terms of mass ratio).

In the table, “Particle 1” and “Particle 2” indicate the adding amount or the kind of the black pigment introduced by the dispersion liquid 1 and the dispersion liquid 2, respectively. “Dispersing agent 1” and “Dispersing agent 2” indicate the adding amount or the kind of the dispersing agent introduced by the dispersion liquid 1 and the dispersion liquid 2, respectively.

In the table, the column of “Polymerizable compound containing no acid group” indicates whether or not the polymerizable compound used is a polymerizable compound having no acid group. A case where this requirement is satisfied is indicated as “A”, and a case where it is not satisfied is indicated as “B”.

In the table, the column of “Oxime-based polymerization initiator” indicates whether or not the polymerization initiator used is a photopolymerization initiator which is an oxime compound. A case where this requirement is satisfied is indicated as “A”, and a case where it is not satisfied is indicated as “B”.

In the table, the column of “Pigment concentration (% by mass)” indicates the content (in terms of % by mass) of the black pigment with respect to the total solid content of the composition.

In the table, the column of “Coating kind of particle 1” indicates the kind of the coating layer in the particle 1.

In the table, the column of “Coating kind (% by mass) of particle 1” indicates the content (the coating amount, in terms of % by mass) of the coating layer (the metal oxide) with respect to the total mass of the particle 1.

In the table, the column of “Polymerizable dispersing agent” indicates whether or not the dispersing agent used has a polymerizable group (a curable group). A case where this requirement is satisfied is indicated as “A”, and a case where it is not satisfied is indicated as “B”.

In the table, the column “Particle 1 ratio (% by mass)” and the column of “Particle 2 ratio (% by mass)” indicate the content (in terms of % by mass) of the particle 1 or the particle 2 with respect to the total content of the particle 1 and particle 2.

In the table, the column of “Moisture content (mass %)” indicates the moisture content (in terms of % by mass) of each composition.

TABLE 1

| | | Example | Example | Example | Example | Example | Example | Example | Example | Example |
|---|---|---|---|---|---|---|---|---|---|---|
| | | 1 | 2 | 3 | 4 | 5 | 6 | 7 | 8 | 9 |
| Content of | Resin | 1.48 | 1.48 | 1.48 | 1.48 | 1.48 | 1.48 | 1.48 | 1.48 | 1.48 |
| solid content | Polymerizable compound | 14.49 | 14.49 | 14.49 | 14.49 | 14.49 | 14.49 | 14.49 | 14.49 | 14.49 |
| | Surfactant | 0.02 | 0.02 | 0.02 | 0.02 | 0.02 | 0.02 | 0.02 | 0.02 | 0.02 |
| | Polymerization inhibitor | 0.01 | 0.01 | 0.01 | 0.01 | 0.01 | 0.01 | 0.01 | 0.01 | 0.01 |
| | Polymerization initiator | 6.00 | 6.00 | 6.00 | 6.00 | 6.00 | 6.00 | 6.00 | 6.00 | 6.00 |
| | Particle 1 | 60.00 | 60.00 | 60.00 | 60.00 | 60.00 | 60.00 | 60.00 | 60.00 | 60.00 |
| | Dispersing agent 1 | 18.00 | 18.00 | 18.00 | 18.00 | 18.00 | 18.00 | 18.00 | 18.00 | 18.00 |
| | Particle 2 | | | | | | | | | |
| | Dispersing agent 2 | | | | | | | | | |
| | Silica particle | | | | | | | | | |
| Total solid content | | 100 | 100 | 100 | 100 | 100 | 100 | 100 | 100 | 100 |
| Kind | Resin | A-1 | A-1 | A-1 | A-1 | A-1 | A-1 | A-1 | A-1 | A-1 |
| | Polymerizable compound | M1 | M1 | M1 | M1 | M1 | M1 | M1 | M1 | M1 |
| | Surfactant | F-1 | F-1 | F-1 | F-1 | F-1 | F-1 | F-1 | F-1 | F-1 |
| | Polymerization inhibitor | PI-1 | PI-1 | PI-1 | PI-1 | PI-1 | PI-1 | PI-1 | PI-1 | PI-1 |
| | Polymerization initiator | I-1 | I-1 | I-1 | I-1 | I-1 | I-1 | I-1 | I-1 | I-1 |
| | Particle 1 | Zr-2 | Zr-3 | Zr-4 | Zr-5 | Zr-6 | Zr-7 | Zr-8 | Zr-9 | Vc-I |
| | Dispersing agent 1 | B | B | B | B | B | B | B | B | B |
| | Particle 2 | | | | | | | | | |
| | Dispersing agent 2 | | | | | | | | | |
| | Silica particle | | | | | | | | | |
| Characteristics | Solid content | 32.5 | 32.5 | 32.5 | 32.5 | 32.5 | 32.5 | 32.5 | 32.5 | 32.5 |
| | concentration | | | | | | | | | |
| | (% by mass) | | | | | | | | | |
| | Polymerizable compound | A | A | A | A | A | A | A | A | A |
| | containing no acid group | | | | | | | | | |
| | Oxime-based | A | A | A | A | A | A | A | A | A |
| | polymerization Initiator | | | | | | | | | |
| | Pigment concentration | 60 | 60 | 60 | 60 | 60 | 60 | 60 | 60 | 60 |
| | (% by mass) | | | | | | | | | |
| | Coating kind of particle 1 | Silica | Alumina | Alumina | Alumina | Alumina | Alumina | Alumina | Alumina | Silica |
| | Coating amount of | 5 | 1 | 2 | 3 | 5 | 7 | 8 | 10 | 5 |
| | particle 1 | | | | | | | | | |
| | (% by mass) | | | | | | | | | |
| | Polymerizable dispersing | A | A | A | A | A | A | A | A | A |
| | agent | | | | | | | | | |
| | Particle 1 ratio | 100 | 100 | 100 | 100 | 100 | 100 | 100 | 100 | 100 |
| | (% by mass) | | | | | | | | | |
| | Particle 2 ratio | 0 | 0 | 0 | 0 | 0 | 0 | 0 | 0 | 0 |
| | (% by mass) | | | | | | | | | |
| | Moisture content | 0.1 | 0.1 | 0.1 | 0.1 | 0.1 | 0.1 | 0.1 | 0.1 | 0.1 |
| | (% by mass) | | | | | | | | | |
| Evaluation | Moisture resistance | A | B | B | A | A | A | A | A | B |
| | Dispersibility | B | A | A | A | A | A | A | A | B |
| | Light shielding properties | A | A | A | A | A | A | B | B | B |
| | (against visible light) | | | | | | | | | |
| | Light shielding properties | B | B | B | B | B | B | B | B | B |
| | (940 nm) | | | | | | | | | |
| | Patterning properties | A | A | A | A | A | A | A | A | A |
| | Alignment mark visibility | A | A | A | A | A | A | A | A | A |

TABLE 2

| | | Example | Example | Example | Example | Example | Example | Example | Example | Example |
|---|---|---|---|---|---|---|---|---|---|---|
| | | 10 | 11 | 12 | 13 | 14 | 15 | 16 | 17 | 18 |
| Content of | Resin | 1.48 | 1.48 | 1.48 | 1.48 | 1.48 | 1.48 | 1.48 | 1.48 | 1.48 |
| solid content | Polymerizable compound | 14.49 | 14.49 | 14.49 | 14.49 | 14.49 | 14.49 | 14.49 | 14.49 | 14.49 |
| | Surfactant | 0.02 | 0.02 | 0.02 | 0.02 | 0.02 | 0.02 | 0.02 | 0.02 | 0.02 |
| | Polymerization inhibitor | 0.01 | 0.01 | 0.01 | 0.01 | 0.01 | 0.01 | 0.01 | 0.01 | 0.01 |
| | Polymerization initiator | 6.00 | 6.00 | 6.00 | 6.00 | 6.00 | 6.00 | 6.00 | 6.00 | 6.00 |
| | Particle 1 | 60.00 | 60.00 | 60.00 | 60.00 | 60.00 | 42.00 | 54.00 | 48.00 | 36.00 |
| | Dispersing agent 1 | 18.00 | 18.00 | 18.00 | 18.00 | 18.00 | 12.60 | 16.20 | 14.40 | 10.80 |
| | Particle 2 | | | | | | 18.00 | 6.00 | 12.00 | 24.00 |
| | Dispersing agent 2 | | | | | | 5.40 | 1.80 | 3.60 | 7.20 |
| | Silica particle | | | | | | | | | |
| Total solid content | | 100 | 100 | 100 | 100 | 100 | 100 | 100 | 100 | 100 |
| Kind | Resin | A-1 | A-1 | A-1 | A-1 | A-1 | A-1 | A-1 | A-1 | A-1 |
| | Polymerizable compound | M1 | M1 | M1 | M1 | M1 | M1 | M1 | M1 | M1 |
| | Surfactant | F-1 | F-1 | F-1 | F-1 | F-1 | F-1 | F-1 | F-1 | F-1 |
| | Polymerization inhibitor PI-1 | PI-1 | PI-1 | PI-1 | PI-1 | PI-1 | PI-1 | PI-1 | PI-1 | |
| | Polymerization initiator | I-1 | I-1 | I-1 | I-1 | I-1 | I-1 | I-1 | I-1 | I-1 |
| | Particle 1 | Nbc-1 | Zr-6 | Zr-6 | Zr-6 | Zr-6 | Zr-6 | Zr-6 | Zr-6 | Zr-6 |
| | Dispersing agent 1 | B | B | B | B | B | B | B | B | B |
| | Particle 2 | | | | | | Ti-1 | Ti-1 | Ti-1 | Ti-1 |
| | Dispersing agent 2 | | | | | | B | B | B | B |
| | Silica particle | | | | | | | | | |
| Characteristics | Solid content | 32.5 | 32.5 | 32.5 | 32.5 | 32.5 | 32.5 | 32.5 | 32.5 | 32.5 |
| | concentration | | | | | | | | | |
| | (% by mass) | | | | | | | | | |
| | Polymerizable compound | A | A | A | A | A | A | A | A | A |
| | containing no acid group | | | | | | | | | |
| | Oxime-based | A | A | A | A | A | A | A | A | A |
| | polymerization Initiator | | | | | | | | | |
| | Pigment concentration | 60 | 60 | 60 | 60 | 60 | 60 | 60 | 60 | 60 |
| | (% by mass) | | | | | | | | | |
| | Coating kind of particle 1 | Silica | Alumina | Alumina | Alumina | Alumina | Alumina | Alumina | Alumina | Alumina |
| | Coating amount of | 5 | 5 | 5 | 5 | 5 | 5 | 5 | 5 | 5 |
| | particle 1 | | | | | | | | | |
| | (% by mass) | | | | | | | | | |
| | Polymerizable dispersing | A | A | A | A | A | A | A | A | A |
| | agent | | | | | | | | | |
| | Particle 1 ratio | 100 | 100 | 100 | 100 | 100 | 70 | 90 | 80 | 60 |
| | (% by mass) | | | | | | | | | |
| | Particle 2 ratio | 0 | 0 | 0 | 0 | 0 | 30 | 10 | 20 | 40 |
| | (% by mass) | | | | | | | | | |
| | Moisture content | 0.1 | 0.008 | 0.05 | 2 | 4 | 0.1 | 0.1 | 0.1 | 0.1 |
| | (% by mass) | | | | | | | | | |
| Evaluation | Moisture resistance | B | A | A | A | A | A | A | A | A |
| | Dispersibility | B | B | A | A | B | A | A | A | A |
| | Light shielding properties | B | A | A | A | A | A | A | A | A |
| | (against visible light) | | | | | | | | | |
| | Light shielding properties | B | B | B | B | B | A | A | A | A |
| | (940 nm) | | | | | | | | | |
| | Patterning properties | A | A | A | A | A | A | A | A | A |
| | Alignment mark visibility | A | A | A | A | A | A | A | A | A |

TABLE 3

| | | Example | Example | Example | Example | Example | Example | Example | Example | Example |
|---|---|---|---|---|---|---|---|---|---|---|
| | | 19 | 20 | 21 | 22 | 23 | 24 | 25 | 26 | 27 |
| Content of | Resin | 1.48 | 1.48 | 1.48 | 1.48 | 1.48 | 27.48 | 14.48 | | 1.48 |
| solid content | Polymerizable compound | 14.49 | 14.49 | 14.49 | 14.49 | 14.49 | 14.49 | 14.49 | 2.97 | 14.49 |
| | Surfactant | 0.02 | 0.02 | 0.02 | 0.02 | 0.02 | 0.02 | 0.02 | 0.02 | 0.02 |
| | Polymerization inhibitor | 0.01 | 0.01 | 0.01 | 0.01 | 0.01 | 0.01 | 0.01 | 0.01 | 0.01 |
| | Polymerization initiator | 6.00 | 6.00 | 6.00 | 6.00 | 6.00 | 6.00 | 6.00 | 6.00 | 6.00 |
| | Particle 1 | 30.00 | 24.00 | 18.00 | 12.00 | 6.00 | 28.00 | 35.00 | 49.00 | 42.00 |
| | Dispersing agent 1 | 9.00 | 7.20 | 5.40 | 3.60 | 1.80 | 8.40 | 10.50 | 14.70 | 12.60 |
| | Particle 2 | 30.00 | 36.00 | 42.00 | 48.00 | 54.00 | 12.00 | 15.00 | 21.00 | 18.00 |
| | Dispersing agent 2 | 9.00 | 10.80 | 12.60 | 14.40 | 16.20 | 3.60 | 4.50 | 6.30 | 5.40 |
| | Silica particle | | | | | | | | | |
| Total solid content | | 100 | 100 | 100 | 100 | 100 | 100 | 100 | 100 | 100 |
| Kind | Resin | A-1 | A-1 | A-1 | A-1 | A-1 | A-1 | A-1 | A-1 | A-2 |
| | Polymerizable compound | M1 | M1 | M1 | M1 | M1 | M1 | M1 | M1 | M1 |
| | Surfactant | F-1 | F-1 | F-1 | F-1 | F-1 | F-1 | F-1 | F-1 | F-1 |
| | Polymerization inhibitor | PI-I | PI-1 | PI-1 | PI-1 | PI-1 | PI-1 | PI-1 | PI-I | PI-I |
| | Polymerization initiator I-1 | I-I | I-I | I-1 | I-1 | I-1 | I-1 | I-1 | I-1 | |
| | Particle 1 | Zr-6 | Zr-6 | Zr-6 | Zr-6 | Zr-6 | Zr-6 | Zr-6 | Zr-6 | Zr-6 |
| | Dispersing agent 1 | B | B | B | B | B | B | B | B | B |
| | Particle 2 | Ti-1 | Ti-1 | Ti-1 | Ti-1 | Ti-1 | Ti-1 | Ti-1 | Ti-1 | Ti-1 |
| | Dispersing agent 2 | B | B | B | B | B | B | B | B | B |
| | Silica particle | | | | | | | | | |
| Characteristics | Solid content | 32.5 | 32.5 | 32.5 | 32.5 | 32.5 | 32.5 | 32.5 | 32.5 | 32.5 |
| | concentration | | | | | | | | | |
| | (% by mass) | | | | | | | | | |
| | Polymerizable compound | A | A | A | A | A | A | A | A | A |
| | containing no acid group | | | | | | | | | |
| | Oxime-based | A | A | A | A | A | A | A | A | A |
| | polymerization Initiator | | | | | | | | | |
| | Pigment concentration | 60 | 60 | 60 | 60 | 60 | 40 | 50 | 70 | 60 |
| | (% by mass) | | | | | | | | | |
| | Coating kind of particle 1 | Alumina | Alumina | Alumina | Alumina | Alumina | Alumina | Alumina | Alumina | Alumina |
| | Coating amount of | 5 | 5 | 5 | 5 | 5 | 5 | 5 | 5 | 5 |
| | particle 1 | | | | | | | | | |
| | (% by mass) | | | | | | | | | |
| | Polymerizable dispersing | A | A | A | A | A | A | A | A | A |
| | agent | | | | | | | | | |
| | Particle 1 ratio | 50 | 40 | 30 | 20 | 10 | 70 | 70 | 70 | 70 |
| | (% by mass) | | | | | | | | | |
| | Particle 2 ratio | 50 | 60 | 70 | 80 | 90 | 30 | 30 | 30 | 30 |
| | (% by mass) | | | | | | | | | |
| | Moisture content | 0.1 | 0.1 | 0.1 | 0.1 | 0.1 | 0.1 | 0.1 | 0.1 | 0.1 |
| | (% by mass) | | | | | | | | | |
| Evaluation | Moisture resistance | A | A | A | A | A | A | A | A | A |
| | Dispersibility | A | A | A | A | A | A | A | A | A |
| | Light shielding properties | A | A | A | A | A | B | A | A | A |
| | (against visible light) | | | | | | | | | |
| | Light shielding properties | A | A | A | A | A | B | A | A | A |
| | (940 nm) | | | | | | | | | |
| | Patterning properties | A | B | B | B | B | A | A | B | A |
| | Alignment mark visibility | A | A | A | A | A | B | A | A | A |

TABLE 4

| | | Example | Example | Example | Example | Example | Example | Example | Example | Example |
|---|---|---|---|---|---|---|---|---|---|---|
| | | 28 | 29 | 30 | 31 | 32 | 33 | 34 | 35 | 36 |
| Content of | Resin | 1.48 | 1.48 | 1.48 | 1.48 | 1.48 | 1.48 | 1.48 | 1.48 | 1.48 |
| solid content | Polymerizable compound | 14.49 | 14.49 | 14.49 | 14.49 | 14.49 | 14.49 | 14.49 | 14.49 | 14.49 |
| | Surfactant | 0.02 | 0.02 | 0.02 | 0.02 | 0.02 | 0.02 | 0.02 | 0.02 | 0.02 |
| | Polymerization inhibitor | 0.01 | 0.01 | 0.01 | 0.01 | 0.01 | 0.01 | 0.01 | 0.01 | 0.01 |
| | Polymerization initiator | 6.00 | 6.00 | 6.00 | 6.00 | 6.00 | 6.00 | 6.00 | 6.00 | 6.00 |
| | Particle 1 | 42.00 | 42.00 | 42.00 | 42.00 | 42.00 | 42.00 | 42.00 | 42.00 | 42.00 |
| | Dispersing agent 1 | 12.60 | 12.60 | 12.60 | 12.60 | 12.60 | 12.60 | 12.60 | 12.60 | 12.60 |
| | Particle 2 | 18.00 | 18.00 | 18.00 | 18.00 | 18.00 | 18.00 | 18.00 | 18.00 | 18.00 |
| | Dispersing agent 2 | 5.40 | 5.40 | 5.40 | 5.40 | 5.40 | 5.40 | 5.40 | 5.40 | 5.40 |
| | Silica particle | | | | | | | | | |
| Total solid content | | 100 | 100 | 100 | 100 | 100 | 100 | 100 | 100 | 100 |
| Kind | Resin | A-1 | A-1 | A-1 | A-1 | A-1 | A-1 | A-1 | A-1 | A-1 |
| | Polymerizable compound | M1 | M1 | M1 | M1 | M1 | M1 | M1 | M1 | M1 |
| | Surfactant | F-1 | F-1 | F-1 | F-1 | F-1 | F-1 | F-1 | F-1 | F-1 |
| | Polymerization inhibitor | PI-I | PI-1 | PI-1 | PI-1 | PI-1 | PI-1 | PI-1 | PI-I | PI-I |
| | Polymerization initiator | 1-2 | 1-3 | 1-4 | I-5 | 1-6 | 1-7 | 1-8 | 1-9 | I-1 |
| | Particle 1 | Zr-6 | Zr-6 | Zr-6 | Zr-6 | Zr-6 | Zr-6 | Zr-6 | Zr-6 | Zr-6 |
| | Dispersing agent 1 | B | B | B | B | B | B | B | B | B |
| | Particle 2 | Ti-1 | Ti-1 | Ti-1 | Ti-1 | Ti-1 | Ti-1 | Ti-1 | Ti-1 | V-1 |
| | Dispersing agent 2 | B | B | B | B | B | B | B | B | B |
| | Silica particle | | | | | | | | | |
| Characteristics | Solid content | 32.5 | 32.5 | 32.5 | 32.5 | 32.5 | 32.5 | 32.5 | 32.5 | 32.5 |
| | concentration | | | | | | | | | |
| | (% by mass) | | | | | | | | | |
| | Polymerizable compound | A | A | A | A | A | A | A | A | A |
| | containing no acid group | | | | | | | | | |
| | Oxime-based | A | A | A | A | A | A | A | B | A |
| | polymerization Initiator | | | | | | | | | |
| | Pigment concentration | 60 | 60 | 60 | 60 | 60 | 60 | 60 | 60 | 60 |
| | (% by mass) | | | | | | | | | |
| | Coating kind of particle 1 | Alumina | Alumina | Alumina | Alumina | Alumina | Alumina | Alumina | Alumina | Alumina |
| | Coating amount of | 5 | 5 | 5 | 5 | 5 | 5 | 5 | 5 | 5 |
| | particle 1 | | | | | | | | | |
| | (% by mass) | | | | | | | | | |
| | Polymerizable dispersing | A | A | A | A | A | A | A | A | A |
| | agent | | | | | | | | | |
| | Particle 1 ratio | 70 | 70 | 70 | 70 | 70 | 70 | 70 | 70 | 70 |
| | (% by mass) | | | | | | | | | |
| | Particle 2 ratio | 30 | 30 | 30 | 30 | 30 | 30 | 30 | 30 | 30 |
| | (% by mass) | | | | | | | | | |
| | Moisture content | 0.1 | 0.1 | 0.1 | 0.1 | 0.1 | 0.1 | 0.1 | 0.1 | 0.1 |
| | (% by mass) | | | | | | | | | |
| Evaluation | Moisture resistance | A | A | A | A | A | A | A | A | A |
| | Dispersibility | A | A | A | A | A | A | A | A | A |
| | Light shielding properties | A | A | A | A | A | A | A | A | A |
| | (against visible light) | | | | | | | | | |
| | Light shielding properties | A | A | A | A | A | A | A | A | A |
| | (940 nm) | | | | | | | | | |
| | Patterning properties | A | A | A | A | A | A | A | B | A |
| | Alignment mark visibility | A | A | A | A | A | A | A | A | A |

TABLE 5

| | | Example | Example | Example | Example | Example | Example | Example | Example | Example |
|---|---|---|---|---|---|---|---|---|---|---|
| | | 37 | 38 | 39 | 40 | 41 | 42 | 43 | 44 | 45 |
| Content of | Resin | 1.48 | 1.48 | 1.48 | 1.48 | 1.48 | 1.48 | 1.48 | 1.48 | 1.48 |
| solid content | Polymerizable compound | 14.49 | 14.49 | 14.49 | 14.49 | 14.49 | 14.49 | 14.49 | 14.49 | 14.49 |
| | Surfactant | 0.02 | 0.02 | 0.02 | 0.02 | 0.02 | 0.02 | 0.02 | 0.02 | 0.02 |
| | Polymerization inhibitor | 0.01 | 0.01 | 0.01 | 0.01 | 0.01 | 0.01 | 0.01 | 0.01 | 0.01 |
| | Polymerization initiator | 6.00 | 6.00 | 6.00 | 6.00 | 6.00 | 6.00 | 6.00 | 6.00 | 6.00 |
| | Particle 1 | 42.00 | 42.00 | 42.00 | 42.00 | 42.00 | 42.00 | 42.00 | 42.00 | 42.00 |
| | Dispersing agent 1 | 12.60 | 12.60 | 12.60 | 12.60 | 12.60 | 12.60 | 12.60 | 12.60 | 12.60 |
| | Particle 2 | 18.00 | 18.00 | 18.00 | 18.00 | 18.00 | 18.00 | 18.00 | 18.00 | 18.00 |
| | Dispersing agent 2 | 5.40 | 5.40 | 5.40 | 5.40 | 5.40 | 5.40 | 5.40 | 5.40 | 5.40 |
| | Silica particle | | | | | | | | | |
| Total solid content | | 100 | 100 | 100 | 100 | 100 | 100 | 100 | 100 | 100 |
| Kind | Resin | A-1 | A-1 | A-1 | A-1 | A-1 | A-1 | A-1 | A-1 | A-1 |
| | Polymerizable compound | M1 | M1 | M1 | M1 | M1 | M1 | M1 | M1 | M1 |
| | Surfactant | F-1 | F-1 | F-1 | F-1 | F-1 | F-1 | F-1 | F-1 | F-1 |
| | Polymerization inhibitor | PI-I | PI-1 | PI-1 | PI-1 | PI-1 | PI-1 | PI-1 | PI-I | PI-I |
| | Polymerization initiator | I-1 | I-I | I-I | I-1 | I-1 | I-1 | I-1 | I-1 | I-1 |
| | Particle 1 | Zr-6 | Zr-6 | Zr-6 | Zr-6 | Zr-6 | Zr-6 | Zr-6 | Zr-6 | Zr-6 |
| | Dispersing agent 1 | B | B | A | C | D | E | F | G | H |
| | Particle 2 | Nb-1 | Zr-1 | Ti-1 | Ti-1 | Ti-1 | Ti-1 | Ti-1 | Ti-1 | Ti-1 |
| | Dispersing agent 2 | B | B | A | C | D | E | F | G | H |
| | Silica particle | | | | | | | | | |
| Characteristics | Solid content | 32.5 | 32.5 | 32.5 | 32.5 | 32.5 | 32.5 | 32.5 | 32.5 | 32.5 |
| | concentration | | | | | | | | | |
| | (% by mass) | | | | | | | | | |
| | Polymerizable compound | A | A | A | A | A | A | A | A | A |
| | containing no acid group | | | | | | | | | |
| | Oxime-based | A | A | A | A | A | A | A | A | A |
| | polymerization Initiator | | | | | | | | | |
| | Pigment concentration | 60 | 60 | 60 | 60 | 60 | 60 | 60 | 60 | 60 |
| | (% by mass) | | | | | | | | | |
| | Coating kind of particle 1 | Alumina | Alumina | Alumina | Alumina | Alumina | Alumina | Alumina | Alumina | Alumina |
| | Coating amount of | 5 | 5 | 5 | 5 | 5 | 5 | 5 | 5 | 5 |
| | particle 1 | | | | | | | | | |
| | (% by mass) | | | | | | | | | |
| | Polymerizable dispersing | A | A | B | B | B | B | B | B | B |
| | agent | | | | | | | | | |
| | Particle 1 ratio | 70 | 70 | 70 | 70 | 70 | 70 | 70 | 70 | 70 |
| | (% by mass) | | | | | | | | | |
| | Particle 2 ratio | 30 | 30 | 30 | 30 | 30 | 30 | 30 | 30 | 30 |
| | (% by mass) | | | | | | | | | |
| | Moisture content | 0.1 | 0.1 | 0.1 | 0.1 | 0.1 | 0.1 | 0.1 | 0.1 | 0.1 |
| | (% by mass) | | | | | | | | | |
| Evaluation | Moisture resistance | A | A | A | A | A | A | A | A | A |
| | Dispersibility | B | A | A | A | A | A | A | A | A |
| | Light shielding properties | A | A | A | A | A | A | A | A | A |
| | (against visible light) | | | | | | | | | |
| | Light shielding properties | A | A | A | A | A | A | A | A | A |
| | (940 nm) | | | | | | | | | |
| | Patterning properties | A | A | B | B | B | B | B | B | B |
| | Alignment mark visibility | A | A | A | A | A | A | A | A | A |

TABLE 6

| | | Example | Example | Example | Example | Example | Example | Example | Comparative |
|---|---|---|---|---|---|---|---|---|---|
| | | 46 | 47 | 48 | 49 | 50 | 51 | 52 | Example 1 |
| Content of | Resin | 1.48 | 1.48 | 1.48 | 1.48 | 1.48 | 1.48 | 1.48 | 1.48 |
| solid content | Polymerizable compound | 14.49 | 14.49 | 14.49 | 14.49 | 14.49 | 9.49 | 9.49 | 14.49 |
| | Surfactant | 0.02 | 0.02 | 0.02 | 0.02 | 0.02 | 0.02 | 0.02 | 0.02 |
| | Polymerization inhibitor | 0.01 | 0.01 | 0.01 | 0.01 | 0.01 | 0.01 | 0.01 | 0.01 |
| | Polymerization initiator | 6.00 | 6.00 | 6.00 | 6.00 | 6.00 | 6.00 | 6.00 | 6.00 |
| | Particle 1 | 42.00 | 42.00 | 42.00 | 42.00 | 42.00 | 60.00 | 60.00 | |
| | Dispersing agent 1 | 12.60 | 12.60 | 12.60 | 12.60 | 12.60 | 18.00 | 18.00 | |
| | Particle 2 | 18.00 | 18.00 | 18.00 | 18.00 | 18.00 | | | 60.00 |
| | Dispersing agent 2 | 5.40 | 5.40 | 5.40 | 5.40 | 5.40 | | | 18.00 |
| | Silica particle | | | | | | 5.00 | 5.00 | |
| Total solid content | | 100 | 100 | 100 | 100 | 100 | 100 | 100 | 100 |
| Kind | Resin | A-1 | A-1 | A-1 | A-1 | A-1 | A-1 | A-1 | A-1 |
| | Polymerizable compound | M1 | M2 | M3 | M4 | M2/M4 = | M1 | M1 | M1 |
| | | | | | | 83/17 | | | |
| | Surfactant | F-1 | F-1 | F-1 | F-1 | F-1 | F-1 | F-1 | F-1 |
| | Polymerization inhibitor | PI-I | PI-1 | PI-1 | PI-1 | PI-I | PI-1 | PI-1 | PI-1 |
| | Polymerization initiator | I-I | I-I | I-1 | I-1 | I-1 | I-I | I-I | I-1 |
| | Particle 1 | Zr-6 | Zr-6 | Zr-6 | Zr-6 | Zr-6 | Zr-2 | Zr-2 | |
| | Dispersing agent 1 | I | B | B | B | B | B | B | |
| | Particle 2 | Ti-1 | Ti-1 | Ti-1 | Ti-1 | Ti-1 | | | V-1 |
| | Dispersing agent 2 | I | B | B | B | B | | | B |
| | Silica particle | | | | | | S-1 | S-2 | |
| Characteristics | Solid content | 32.5 | 32.5 | 32.5 | 32.5 | 32.5 | 32.5 | 32.5 | 32.5 |
| | concentration | | | | | | | | |
| | (% by mass) | | | | | | | | |
| | Polymerizable compound | A | A | A | B | A/B | A | A | A |
| | containing no acid group | | | | | | | | |
| | Oxime-based | A | A | A | A | A | A | A | A |
| | polymerization Initiator | | | | | | | | |
| | Pigment concentration | 60 | 60 | 60 | 60 | 60 | 60 | 60 | 60 |
| | (% by mass) | | | | | | | | |
| | Coating kind of particle 1 | Alumina | Alumina | Alumina | Alumina | Alumina | Silica | Silica | — |
| | Coating amount of | 5 | 5 | 5 | 5 | 5 | 5 | 5 | — |
| | particle 1 | | | | | | | | |
| | (% by mass) | | | | | | | | |
| | Polymerizable dispersing | B | A | A | A | A | A | A | A |
| | agent | | | | | | | | |
| | Particle 1 ratio | 70 | 70 | 70 | 70 | 70 | 100 | 100 | 0 |
| | (% by mass) | | | | | | | | |
| | Particle 2 ratio | 30 | 30 | 30 | 30 | 30 | 0 | 0 | 100 |
| | (% by mass) | | | | | | | | |
| | Moisture content | 0.1 | 0.1 | 0.1 | 0.1 | 0.1 | 0.1 | 0.1 | 0.1 |
| | (% by mass) | | | | | | | | |
| Evaluation | Moisture resistance | A | A | A | A | A | A | A | C |
| | Dispersibility | B | A | A | A | A | B | B | B |
| | Light shielding properties | A | A | A | A | A | A | A | B |
| | (against visible light) | | | | | | | | |
| | Light shielding properties | A | A | A | A | A | B | B | B |
| | (940 nm) | | | | | | | | |
| | Patterning properties | B | A | A | B | A | A | A | A |
| | Alignment mark visibility | A | A | A | A | A | A | A | A |

It was confirmed that the light shielding film (the cured film) formed from the composition according to the embodiment of the present invention has excellent moisture resistance. It was also confirmed that the composition according to the embodiment of the present invention has good dispersibility and good patterning properties. Further, it was confirmed that the light shielding film (the cured film) formed from the composition according to the embodiment of the present invention has good light shielding properties against visible light and infrared light, and also has good alignment mark visibility.

It was confirmed that the metal oxide in the metal oxide coating layer preferably contains alumina (see the comparison between Examples 1 and 5, and the like) in that the dispersibility of the composition is more excellent.

It was confirmed that the content of the metal oxide coating layer is preferably 3% to 7% by mass with respect to the total mass of the coated particle in that the moisture resistance and/or the light shielding properties of the cured film against visible light is more excellent (see the comparison between Examples 2 to 8, and the like).

It was confirmed that the water content is preferably 0.01% to 3.0% by mass with respect to the total mass of the composition in that the dispersibility of the composition is more excellent (see the comparison between Examples 11 to 14, and the like).

It was confirmed that it is preferable that the black pigment is a black pigment different from the coated particle and contains a pigment which is a nitride or oxynitride of one or more metals selected from the group consisting of titanium, vanadium, and niobium in that the cured film has a better light shielding properties against infrared light (see the comparison between Examples 1, 15 to 23, 36, 37, and 38, and the like).

Further, it was confirmed that the content of the coated particle with respect to the total mass of the black pigment is preferably 50% to 90% by mass in that patterning properties are more excellent (see the comparison between Examples 15 to 23, and the like).

It was confirmed that the content of the black pigment is preferably 40% to 70% by mass (more preferably more than 40% by mass and less than 70% by mass) with respect to the total solid content of the composition in that the light shielding properties against visible light, the light shielding properties against infrared light, the patterning properties, and/or the alignment mark visibility is more excellent (see the comparison between Examples 15 and 24 to 26, and the like).

It was confirmed that it is preferable to contain an oxime compound as the photopolymerization initiator in that patterning properties are more excellent (see the comparison between Examples 15 and 28 to 35, and the like).

It was confirmed that the dispersing agent preferably contains a polymerizable group (a curable group) in that patterning properties are more excellent (see the comparison between Examples 15 and 39 to 46, and the like).

It was confirmed that the dispersing agent preferably contains an acid group in that dispersibility is more excellent (see the comparison between Examples 15 and 39 to 46, and the like).

It was confirmed that the content of the polymerizable compound containing no acid group is preferably 50% to 100% by mass with respect to the total mass of the polymerizable compound in that patterning properties are more excellent (see the comparison between Examples 15 and 47 to 50, and the like).

As a result of carrying out the same evaluation in Example 13 without adding a surfactant, the same result was obtained. As a result of carrying out the same evaluation in Example 13 without adding a polymerization inhibitor, the same result was obtained.

<<Test Y>>

[Application to Various Use Applications]

By the method described below, the applicability of the compositions of Examples (Examples 1 to 11 and Examples 13 to 49) used in <<Test X>> described above to various use applications was checked.

[Production and Evaluation of Light Shielding Film for Wafer-Level Lens]

A lens film was formed by the following operations.

1. Formation of Thermosetting Cured Film

A curable composition for a lens (composition obtained by adding 1% by mass of an aryl sulfonium salt derivative (manufactured by ADEKA CORPORATION, SP-172) to an alicyclic epoxy resin (produced by Daicel Corporation, EHPE-3150)) (2 mL) was applied onto a glass substrate (thickness of 1 mm, manufactured by SCHOTT AG, BK7) of 5×5 cm, and the coating film was cured by heating at 200° C. for 1 minute to form a film with which residues on the lens could be evaluated.

2. Evaluation on Lens

The composition of Example used in <<Test X>> described above was applied onto the glass wafer [the support] on which the lens film had been formed, and the support onto which the composition had been applied was heated for 120 seconds with a hot plate having a surface temperature of 120° C. In this manner, a coating film [a composition layer] having a film thickness of 2.0 μm was obtained.

<Exposure Step>

Next, using a high-pressure mercury lamp, the obtained composition layer was exposed at an exposure amount of 500 mJ/cm² through a photo mask having a hole pattern of 10 mm.

<Development Step>

The composition layer after exposure was subjected to puddle development at a temperature of 23° C. for 60 seconds using an aqueous solution of 0.3% of tetramethylammonium hydroxide. Then, the composition layer subjected to the development treatment was rinsed with a spin shower, and the composition layer subjected to the rinse treatment with pure water was further washed with water to obtain a patterned light shielding film (a cured film).

[Production and Evaluation of Solid-State Imaging Device]

On the substrate on which the patterned light shielding film formed as described above had been formed, a curable resin layer was formed using a curable composition for a lens (a composition obtained by adding 1% by mass of an aryl sulfonium salt derivative (manufactured by ADEKA CORPORATION, SP-172) to an alicyclic epoxy resin (manufactured by Daicel Corporation, EHPE-3150)), a shape was transferred with a quartz mold having a lens shape, and the curable resin layer was cured at an exposure amount of 400 mJ/cm² with a high-pressure mercury lamp, whereby a wafer-level lens array having a plurality of wafer-level lenses was produced.

The produced wafer-level lens array was cut, a lens module was produced using the obtained wafer-level lens, and then an imaging element and a sensor substrate were attached thereto to produce an imaging unit.

The obtained wafer-level lens was such a lens in which residues were not present in the lens opening portion, transmittance was good, and the light shielding layer had high uniformity of the coated surface and high light shielding properties.

[Production of Color Filter Having Black Matrix]

<Formation of Black Matrix>

The composition of Example used in <<Test X>> described above, obtained as above, was applied onto a glass wafer by a spin coating method, and then the glass wafer was heated at 120° C. for 2 minutes on a hot plate to obtain a coating film [a composition layer]. The rotation speed by spin coating was adjusted so that the film thickness of the coating film was 2.0 μm.

Next, the obtained composition layer was exposed through a photo mask of which the pattern had an island pattern of 0.1 mm at an exposure amount of 500 mJ/cm² using an i-line stepper.

The composition layer after exposure was subjected to puddle development at 23° C. for 60 seconds using an aqueous solution of 0.3% of tetramethylammonium hydroxide. Then, the composition layer subjected to the development treatment was rinsed with a spin shower, and the composition layer subjected to the rinse treatment with pure water was further washed with water to obtain a patterned light shielding film (a black matrix).

<Preparation of Chromatic Curable Composition>

Each of a curable coloration composition R-1 for red (R), a curable coloration composition G-1 for green (G), and a curable coloration composition B-1 for blue (B) was prepared in the same manner except that in the composition of Example 1 in <<Test X>> described above, Zr-2 in the dispersion liquid 1 was replaced with the following chromatic pigment.
A chromatic pigment for forming colored pixel of each RGB color
   Pigment for red (R)

C. I. Pigment Red 254
Pigment for green (G)

A 30/70 [in terms of mass ratio] mixture of C. I. Pigment Green 36 and C. I. Pigment Yellow 219
Pigment for blue (B)

A 30/70 [in terms of mass ratio] mixture of C. I. Pigment Blue 15:6 and C. I. Pigment Violet 23

<Production of Color Filter>

In the black matrix produced as described above, the curable coloration composition R-1 for red (R) was used to form a red (R) coloration pattern of 80×80 μm in the same manner as in the method of producing the black matrix produced as described above. Further, similarly, the curable coloration composition G-1 for green (G) was used to form a green (G) chromatic coloration pattern, and sequentially the curable coloration composition B-1 for blue (B) was used to form a blue (B) chromatic coloration pattern, whereby a color filter having a black matrix for a liquid crystal display device was produced.

It was confirmed that the composition according to the embodiment of the present invention can also be applied to a black matrix for a color filter.

### EXPLANATION OF REFERENCES

10: headlight unit
12: light source
14: light shielding unit
16: lens
20: base body
22: light shielding film
23: opening portion
30: light distribution pattern
30a: edge
31: region
32: light distribution pattern
32a: edge
33: notched portion
34: region
100: solid-state imaging device
101: solid-state imaging element
102: imaging unit
103: cover glass
104: spacer
105: laminated substrate
106: chip substrate
107: circuit board
108: electrode pad
109: external connection terminal
110: through-electrode
111: lens layer
112: lens material
113: support
114, 115: light shielding film
201: light-receiving element
202: color filter
203: micro lens
204: substrate
205b: blue pixel
205r: red pixel
205g: green pixel
205bm: black matrix
206: p-well layer
207: reading gate part
208: vertical electric charge transfer path
209: element separation region
210: gate insulating film
211: vertical electric charge transfer electrode
212: light shielding film
213, 214: insulating film
215: planarization film
300: infrared sensor
310: solid-state imaging element
311: infrared absorption filter
312: color filter
313: infrared transmitting filter
314: resin film
315: micro lens
316: planarization film

What is claimed is:

1. A photosensitive composition comprising:
a black pigment;
a resin;
a polymerizable compound; and
a photopolymerization initiator,
wherein the black pigment includes a coated particle, and
the coated particle includes a metal-containing particle consisting of a nitride or oxynitride of one or more metals selected from the group consisting of zirconium, vanadium, and niobium, and a metal oxide coating layer consisting of a metal oxide, with which the metal-containing particle is coated.

2. The photosensitive composition according to claim 1,
wherein the metal oxide includes silica or alumina.

3. The photosensitive composition according to claim 1,
wherein the metal oxide includes alumina.

4. The photosensitive composition according to claim 1,
wherein the black pigment is a black pigment different from the coated particle and includes a pigment that is a nitride or oxynitride of one or more metals selected from the group consisting of titanium, zirconium, vanadium, and niobium.

5. The photosensitive composition according to claim 1,
wherein the photopolymerization initiator includes an oxime compound.

6. The photosensitive composition according to claim 1,
wherein a content of the black pigment is 40% to 70% by mass with respect to a total solid content of the photosensitive composition.

7. The photosensitive composition according to claim 1,
wherein the resin includes at least one of a resin that contains a structural unit containing a graft chain and contains an acid group or a resin that contains a radial structure and contains an acid group.

8. The photosensitive composition according to claim 1,
wherein a content of the metal oxide coating layer is 3% to 7% by mass with respect to a total mass of the coated particle.

9. The photosensitive composition according to claim 1, further comprising:
water,
wherein a content of the water is 0.01% to 3.0% by mass with respect to a total mass of the photosensitive composition.

10. The photosensitive composition according to claim 1, further comprising a silica particle.

11. A cured film that is formed from the photosensitive composition according to claim 1.

12. A light shielding film that is the cured film according to claim 11.

13. A color filter comprising the cured film according to claim 11.

14. An optical element comprising the cured film according to claim 11.

15. A solid-state imaging element comprising the cured film according to claim 11.

16. An infrared sensor comprising the cured film according to claim 11.

17. A headlight unit for a vehicle, comprising:
a light source; and
a light shielding unit that shields at least a part of light emitted from the light source,
wherein the light shielding unit includes the cured film according to claim 11.
